(19) United States
(12) Patent Application Publication
(10) Pub. No.: US 2010/0230136 A1
(43) Pub. Date: Sep. 16, 2010

(54) METHOD FOR PRODUCING RESIST PATTERN

(75) Inventors: Koji ICHIKAWA, Osaka (JP); Masako Sugihara, Nishinomiya-shi (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Tokyo (JP)

(21) Appl. No.: 12/720,419

(22) Filed: Mar. 9, 2010

(30) Foreign Application Priority Data
Mar. 12, 2009 (JP) P2009-059974

(51) Int. Cl. H05K 1/00; G03F 7/20; G03F 7/004; B32B 3/30

(52) U.S. Cl. 174/250; 430/325; 430/270.1; 428/156

(57) ABSTRACT

The present invention provides a method for producing a resist pattern sufficiently miniaturized having an excellent shape including: repeating a process of forming a patterned resist film comprising the following step (1):

(1) forming a resist film, and exposing the formed resist film, and the like to form a patterned resist film by n cycles to obtain a resist pattern, wherein the resist film exposed in the step (1) in at least one cycle of the n cycles of the process of forming the patterned resist film is a film formed by layering a resist composition containing a resin (B) that becomes soluble in an alkali aqueous solution by an action of an acid and has a weight-average molecular weight of 7,000 to 10,000 and a glass transition temperature of 150 to 200° C., a photoacid generator (A) and a crosslinking agent (C).

### BACKGROUND OF THE INVENTION

1. Field of the Invention

The present invention relates to a method for producing a resist pattern.

2. Related Background Art

When a semiconductor is micromachined, a lithography technology is in general use. FIG. 1 is a process diagram showing an existing method for producing a resist pattern. According to the method shown in FIG. 1, actinic rays 7 are exposed through a mask 4 having a light-transmitting portion 6 to a resist film 30 formed on a base material 10 having a silicon substrate 1 and an antireflection film 2, followed by developing, and thereby a resist pattern 30′ is formed.

In recent years, when a semiconductor is micromachined with a lithography technology, a more miniaturized resist pattern is furthermore demanded to produce. In order to respond to such demands, as a process realizing to form a resist pattern having a line width of 32 nm or less, a double-patterning method has been proposed (for example, see Japanese Patent Laid-Open No. 2007-311508). The double-patterning method is a method in which a target resist pattern is formed by performing twice a pattern transfer step. According to the double-patterning method, for example, a first resist pattern is formed at a pitch twice a target pitch via ordinary exposure and development, and thereafter, in a space between lines of the first resist pattern, a second resist pattern having the same pitch is formed by performing exposure and development again, and a target fine resist pattern is thereby formed.

On the other hand, recently, a chemical amplification positive resist composition including: a resin that is formed by charging and polymerizing 2-ethyl-2-adamantyl methacrylate, 3-hydroxy-1-adamantyl methacrylate and α-methacryloyloxy-γ-butyrolactone at a molar ratio of 50:25:25; an acid generator comprising triphenylsulfonium 1-((3-hydroxyadamantyl)methoxycarbonyl)difluoromethane sulfonate; a quencher comprising 2,6-diisopropyl aniline; and a solvent has been proposed (Japanese Patent Laid-Open No. 2006-257078).

### SUMMARY OF THE INVENTION

According to a method where a pattern is transferred by dividing into a plurality of times, like in a double patterning method, while a miniaturized resist pattern can be formed, a further improvement in a pattern shape is in demand. For example, as miniaturization is forwarded, a cross-section of a resist pattern is demanded to maintain a shape more precisely closer to a rectangle. However, according to a conventional method, it was difficult to achieve, simultaneously with the miniaturization, a sufficient level also in the point of a shape of a cross-section of a pattern.

In this connection, the present invention intends to provide a method for producing a resist pattern, which enables to obtain a resist pattern that can be sufficiently miniaturized and has an excellent shape.

The present invention provides a method for producing a resist pattern, by repeating a process of forming a patterned resist film comprising, in this order, the following steps (1), (2) and (3):

(1) forming a resist film and exposing the formed resist film,
(2) heating the exposed resist film, and
(3) patterning the resist film by an alkali development,
wherein the process is repeated by n cycles (n is an integer of 2 or more) to obtain a resist pattern,

wherein in at least from the first cycle to the (n−1)th cycle of the n cycles of the process of forming a patterned resist film, after the step (3), the step (4):

(4) heating the patterned resist film
is further performed; and

wherein the resist film exposed in the step (1) in at least one cycle of the n cycles of the process of forming a patterned resist film is a film formed by layering a resist composition containing a resin (B) that becomes soluble in an alkali aqueous solution by an action of an acid and has a weight-average molecular weight of 7,000 to 10,000 and a glass transition temperature of 150 to 200° C., a photoacid generator (A) and a crosslinking agent (C).

In a method for producing a resist pattern of the present invention, by dividing pattern formation into n cycles, a pattern can be miniaturized. When at least at the first cycle to the (n−1)th cycle of the n cycles of the process of forming a resist film, the step (4) is further performed after the step (3), solvent resistance of a resulting patterned resist film is heightened; accordingly, when a resist composition is coated to form a next resist film, a resist film is inhibited from deforming in shape. Furthermore, when a resist film made of the resin (B) having a weight average molecular weight and the glass transition temperature in the specified ranges is used at least once, an excellent rectangular pattern shape can be obtained.

In the producing method of the present invention, also in the n-th cycles of the process of forming a patterned resist film, the step (4) is preferably performed after the step (3).

In the producing method, when also in the n-th cycle, the step (4) is performed after the step (3), solvent resistance of a resist film formed at the n-th time can be more heightened. Furthermore, since etching rates of n patterned resist films are uniformized, machining with a resulting resist patter as a mask becomes easier.

In the producing method of the present invention, in order to obtain a resist pattern having an excellent shape, the resist film exposed in the step (1) in at least one cycle selected from the first cycle to the (n−1)th cycle of the n cycles of the process of forming a patterned resist film is preferable to be a film formed by layering the resist composition.

In the producing method, when the resist film exposed in the step (1) in at least one cycle selected from the first cycle to the (n−1)th cycle of the n cycles is a film formed by layering the resist composition, in the step (4), the resin (B) is crosslinked owing to an action of a crosslinking agent (C), and thereby a patterned resist film is further improved in the solvent resistance.

In the producing method of the present invention, the resist film exposed in the step (1) in the n-th cycle of the process of forming a patterned resist film is preferable to be a film formed by layering the resist composition.

In the producing method, when the resist film exposed in the step (1) in the n-th cycle is a film formed by layering the resist composition, in the n-th fine pattern formation, a more excellent rectangular pattern shape can be obtained.

In the producing method of the present invention, n may be 2 or 3 or more.

In the producing method of the present invention, the resist film exposed in the step (1) in all of the first cycle to the (n−1)th cycle of the n cycles of the process of forming a patterned resist film is preferable to be a film formed by layering the resist composition.

In the producing method, when the resist film exposed in the step (1) in all of the first cycle to the (n−1)th cycle of the n cycles is a film formed by layering the resist composition, machinability when used as a mask is further heightened.

The crosslinking agent (C) is preferable to be at least one selected from the group consisting of a urea crosslinking agent, an alkylene urea crosslinking agent and a glycoluril crosslinking agent. When the crosslinking agent (C) is at least one thereof, the resin (B) is sufficiently crosslinked and solvent resistance of the patterned resist film is further heightened.

The resist composition preferably contains 0.5 to 35 parts by weight of the crosslinking agent (C) with respect to 100 parts by weight of the resin (B). When the content of the crosslinking agent (C) is in this range, crosslink formation is sufficiently forwarded, and thereby a resist pattern having a more excellent shape can be obtained. Furthermore, storage stability of a resist coating solution is improved and thereby time lapse deterioration of sensitivity can be suppressed.

The resist composition preferably further contains a thermal acid generator (D).

It is preferable that the resin (B) has an alkyl ester group and a carbon atom adjacent to an oxy group in the alkyl ester group is a tertiary carbon atom.

This is because the resin (B) is, so as to be soluble in an alkali aqueous solution after exposure, preferable to be a group readily cleavable by an acid generated from a photoacid generator (A).

Furthermore, the present invention provides a resist composition that contains: a resin (B) that becomes soluble in an alkali aqueous solution by an action of an acid and has a weight-average molecular weight of 7,000 to 10,000 and a glass transition temperature of 150 to 200° C.; a photoacid generator (A); and a crosslinking agent (C) and is used, in a method for producing a resist pattern, by repeating a process of forming a patterned resist film comprising, in this order, the following steps (1), (2) and (3):

(1) forming a resist film and exposing the formed resist film,
(2) heating the exposed resist film, and
(3) patterning the resist film by an alkali development,
wherein the process is repeated by n cycles (n is an integer of 2 or more) to obtain a resist pattern,

wherein in at least from the first cycle to the (n−1)th cycle of the n cycles of the process of forming a patterned resist film, after the step (3), the step (4):

(4) heating the patterned resist film
is further performed,
for forming a resist film exposed in the step (1) in at least one cycle of the n cycles of the process of forming a patterned resist film.

When the resist composition having the composition is used in the above-mentioned producing method, a pattern can be miniaturized and an excellent rectangular pattern shape can be obtained.

The present invention provides a resist pattern obtainable by the above-mentioned producing method. The resist pattern obtained by the producing method can be miniaturized and achieve an excellent shape.

Furthermore, the present invention provides a wiring board provided with a wiring formed by etching a metal layer with the resist pattern as a mask. The wiring board is formed by etching a metal layer with the resist pattern as a mask and thereby can have a miniaturized wiring.

According to the present invention, a method for producing a resist pattern that can be sufficiently miniaturized and has an excellent shape is provided.

### BRIEF DESCRIPTION OF THE DRAWINGS

FIG. 1 is a flow chart showing a method for producing a conventional resist pattern; and

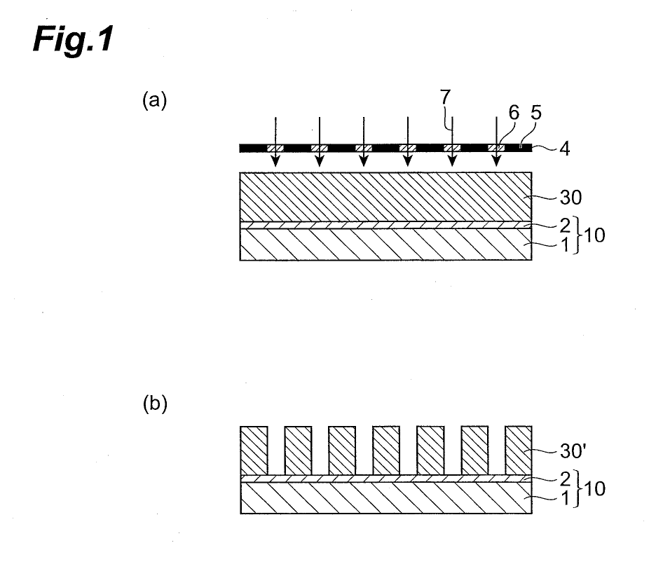

FIG. 2 is a flow chart showing one exemplary embodiment of a method for producing a resist pattern.

### DESCRIPTION OF THE PREFERRED EMBODIMENTS

In what follows, preferred embodiments of a method for producing a resist pattern, a resist composition, a resist pattern and a wiring board according to the present invention will be described. However, the present invention is not restricted to the following embodiments.

According to a method for producing a resist pattern of the embodiment, a process of forming a patterned resist film comprising, in this order, the following steps (1), (2) and (3):

(1) fanning a resist film and exposing the formed resist film,
(2) heating the exposed resist film, and
(3) patterning the resist film by an alkali development,
is repeated by n cycles (n is an integer of 2 or more) to obtain a resist pattern.

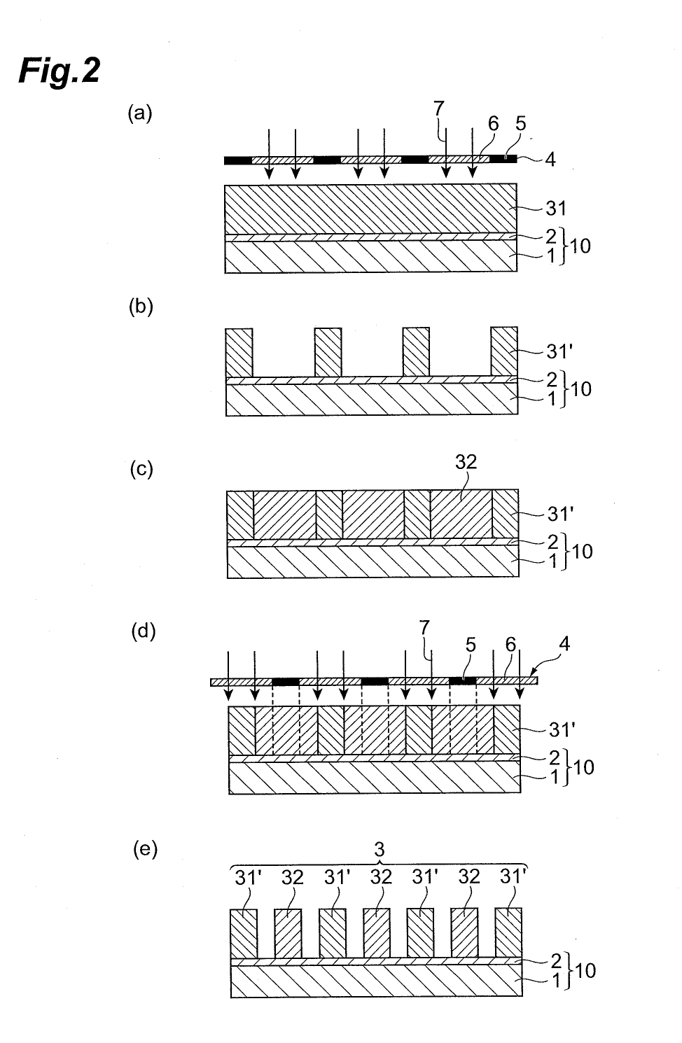

FIG. 2 is a flow chart showing one embodiment of a method for producing a resist pattern. In an embodiment of FIG. 2, a process of fowling a patterned resist film is repeated by 2 times to obtain a resist pattern 3.

A resist composition is coated on a base material 10 and the coated resist composition is dried to obtain a first resist film 31 ((a) of FIG. 2). The base material 10 has a substrate 1 and an antireflection film 2 disposed on the substrate 1 and a resist pattern 3 is formed on the antireflection film 2. The resist composition will be detailed later.

A film thickness of the first resist film 31 is not particularly restricted. However, the film thickness thereof is suitably set equal to or less than an extent by which, in a film thickness direction, exposure and development in a subsequent step can be sufficiently performed, for example, about several tens nm to several mm.

The substrate 1 is not particularly restricted. Examples thereof include various kinds such as a semiconductor substrate such as a silicon wafer, a plastic, a metal or ceramic substrate, or a substrate on which an insulating film, a conductive film or the like are formed.

A resist composition, usually containing a solvent, is coated on a base material 10. As a coating method of the resist composition, a method that is usually industrially used such as a spin coating method can be used without restricting to a particular method.

The coated resist composition is dried to remove a solvent. Examples of a drying method for forming a resist film 31 before exposure include natural drying, air blow drying or a reduced pressure drying. A specific heating temperature is suitably about 10 to 120° C. and preferably about 25 to 80° C. A heating period is suitably about 10 sec to 60 min and preferably about 30 sec to 30 min.

A dried resist film 31 may be pre-baked. As the pre-baking condition, a temperature range of, for example, about 80 to 140° C., and a range of, for example, 30 to 600 sec, and preferably 30 to 180 sec are cited.

Subsequently, an exposure treatment for patterning is performed via a mask 4. It is preferable to perform the exposure treatment with an exposure device usually used in the art such as a scanning stepper type projection exposure device (exposure unit) that is a scanning exposure type. As an exposure light source, various light sources including a light source radiating laser light in a UV-region such as a KrF excimer laser (wavelength: 248 nm), an ArF excimer laser (wavelength: 193 nm) or a F₂ laser (wavelength: 157 nm); and a light source radiating harmonic laser light in a far UV region or a vacuum UV region by wavelength conversion of laser light from a solid laser light source (such as YAG or semiconductor laser) can be used. The mask 4 has a light-shielding portion 5 and a light-transmitting portion 6, and the light-shielding portions 5 are disposed at a predetermined pitch with the light-transmitting portion 6 interposed therebetween. Laser light 7 transmitted through the light-transmitting portion 6 is illuminated to the resist film 31.

An exposed resist film 31 is heated. In other words, a first resist film 31 is post-exposure baked. According to the heat treatment, a deprotection reaction can be forwarded. As the heat treatment conditions here, a temperature range of, for example, about 70 to 140° C., and a range of, for example, 30 to 600 sec, and preferably 30 to 180 sec are cited.

Subsequently, a patterned first resist film 31′ is formed by development with an alkali development solution ((b) in FIG. 2). As an alkali development solution, various kinds of alkali aqueous solutions used in the art can be used. Usually, an aqueous solution of tetramethyl ammonium hydroxide or (2-hydroxyethyl)trimethyl ammonium hydroxide (so-called choline) is used.

Thereafter, a patterned first resist film 31′ is heated. In other words, the patterned first resist film 31′ is hard-baked. By the heat treatment, a crosslinking reaction can be promoted. As heat treatment conditions here, a temperature range of relatively high temperature, for example, about 120 to 250° C., preferably 140 to 220° C., and more preferably 150 to 200° C. and a range of, for example, 10 to 600 sec, and preferably 30 to 180 sec are cited.

Subsequently, a resist composition is coated on a base material 10 and the coated resist composition is dried to form a second resist film 32 on the base material 10 ((c) in FIG. 2).

With respect to the second resist film 32, pre-baking, exposure and post-exposure are performed in a manner similar to those for the first resist film 31 ((d) in FIG. 2). Thereafter, a patterned second resist film 32′ is formed by development with an alkali development solution. The second resist film 32′ is composed of lines arranged at a pitch the same as that of the first resist film 31′. When the two resist films formed divided in two times are combined, a resist pattern 3 having lines arranged with a fine pitch is composed.

Resist compositions used to form a first resist film and a second resist film may be the same or different from each other. However, from the viewpoint of uniformizing the etching rate, the same resist composition is preferable.

In the embodiment shown in FIG. 2, formation of a patterned resist film is repeated twice. However, formation of a patterned resist film may be repeated three times or more. When formation of a resist film at a predetermined pitch is repeated by n cycles, a resist pattern composed of a resist film arranged at a very fine pitch of 1/n the predetermined pitch can be obtained. Although there is no particular upper limit of n, usually, it is about 2 to 4 and preferably 2 to 3.

A formed resist pattern can be preferably used as a mask for forming a wiring having a predetermined pattern by etching a metal layer. Thereby, a wiring board having a fine wiring can be readily produced.

A resist composition may be either a negative or positive resist composition. However, a positive resist composition at least containing a resin (B) soluble in an alkali aqueous solution owing to an action of an acid and a photoacid generator (A) is preferable. A resist composition may further contain a crosslinking agent (C), as required. In particular, a resist composition for forming a resist film that is hard baked after development is preferable to further contain a crosslinking agent (C).

The resin (B) has a group unstable to an acid and is insoluble or difficult to dissolve in an alkali aqueous solution before exposure. An acid generated from the photoacid generator (A) by exposure works catalytically to a group unstable to an acid in the resin (B) to cleave and thereby the resin (B) becomes soluble in an alkali aqueous solution. On the other hand, in an unexposed portion, the resin (B) remains insoluble or difficult to dissolve in an alkali aqueous solution. Thereby, when the resist composition is developed with an alkali aqueous solution after exposure, a positive resist pattern can be formed. Here, that the resin (B) is insoluble or difficult to dissolve in an alkali aqueous solution, though variable depending on a kind and a concentration of an alkali aqueous solution, generally means solubility that necessitates about 100 mL or more of an alkali aqueous solution that is generally used as a development solution for dissolving 1 g or 1 mL of the resist composition, and that the resin (B) is soluble means such solubility that necessitates less than 100 mL of the alkali aqueous solution to dissolve 1 g or 1 mL of the resist composition.

A group unstable to an acid in a resin (B) is, as is described above, a group cleavable by an acid generated from a photoacid generator (A) described later. Preferably, a resin (B) has an alkyl ester group represented by a formula: —C(═O)—O—R (R represents an alkyl group that may have a substituent.) as a group unstable to an acid. Among carbon atoms constituting R, a carbon atom adjacent to an oxy group of an ester bond is preferable to be a tertiary carbon atom. R may be either an alicyclic hydrocarbon group or a lactone ring containing a carbon atom adjacent to an oxy group in an ester bond. Furthermore, R may be an alkoxyalkyl group. In other words, the resin (B) may have an acetal ester group as a group unstable to an acid. The ester group readily cleaves by an action of an acid to generate a carboxyl group. A “tertiary carbon atom” means a carbon atom bonding with three carbon atoms and an atom other than a hydrogen atom.

When an ester that is one of the groups unstable to an acid is illustrated as [R ester of —COOR], alkyl esters where a carbon atom adjacent to an oxygen atom is a tertiary carbon atom represented by tert-butyl ester (that is, —COO—C(CH₃)₃); acetal ester groups such as methoxymethyl ester, ethoxymethyl ester, 1-ethoxyethyl ester, 1-isobutoxyethyl ester, 1-isopropoxyethyl ester, 1-ethoxypropyl ester, 1-(2-methoxyethoxy)ethyl ester, 1-(2-acetoxyethoxy)ethyl ester, 1-[2-(1-adamantyloxy)ethoxy]ethyl ester, 1-[2-(1-adamantanecarbonyloxy)ethoxy]ethyl ester, tetrahydro-2-furyl ester or tetrahydro-2-pyranyl ester; and alicyclic ester groups where a carbon atom adjacent to an oxygen atom is a tertiary carbon atom such as isobornyl ester, 1-alkylcycloalkyl ester, 2-alkyl-2-adamantyl ester or 1-(1-adamantyl)-1-alkylalkyl ester are cited.

As a group having carboxylic acid ester like this, groups having (meth)acrylate ester, norbornene carboxylic acid ester, tricyclodecene carboxylic acid ester or tetracyclodecene carboxylic acid ester can be cited.

In the present specification, (meth)acrylate represents acrylate and/or methacrylate, (meth)acrylonitrile represents acrylonitrile and/or methacrylonitrile and (meth)acryloyloxy- represents acryloyloxy- and/or methacryloyloxy-.

The resin (B) can be produced by addition-polymerizing a monomer having a group unstable to an acid and an olefinic double bond. As a monomer used here, a monomer containing, as a group unstable to an acid, a voluminous group such as an alicyclic structure, in particular, a bridged structure (for example, 2-alkyl-2-adamantyl group and 1-(1-adamantyl)-1-alkylalkyl group) is preferable from the viewpoint of having tendency excelling in resolution of a resulting resist. Examples of monomer containing a voluminous group include 2-alkyl-2-adamantyl(meth)acrylate, 1-(1-adamantyl)-1-alkylalkyl (meth)acrylate, 2-alkyl-2-adamantyl 5-norbornene-2-carboxylate and 1-(1-adamantyl)-1-alkylalkyl 5-norbornene-2-carboxylate.

In particular, when 2-alkyl-2-adamantyl(meth)acrylate is used as a monomer, there is preferable tendency of excelling in resolution of a resulting resist.

Examples of 2-alkyl-2-adamantyl(meth)acrylate include 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate, 2-isopropyl-2-adamantyl methacrylate and 2-n-butyl-2-adamantyl acrylate.

Among these, 2-ethyl-2-adamantyl(meth)acrylate or 2-isopropyl-2-adamantyl(meth)acrylate is preferably used, because there is tendency of excelling in sensitivity and heat resistance of a resulting resist.

2-Alkyl-2-adamantyl(meth)acrylate can be produced usually by reacting 2-alkyl-2-adamantanol or a metal salt thereof and acrylate halide or methacrylate halide.

The resin (B) is characterized by containing a structural unit having a substituent having high polarity. Examples of such structural unit include a structural unit derived from 2-norbornene to which one or more hydroxyl group are bonded, a structural unit derived from (meth)acrylonitrile, a structural unit derived from alkyl ester of which carbon atom adjacent to an oxygen atom is a secondary carbon atom or a tertiary carbon atom, a structural unit derived from (meth)acrylate ester that is 1-adamantyl ester to which one or more hydroxyl groups are bonded, a structural unit derived from a styrenic monomer such as p- or m-hydroxystyrene and a structural unit derived from (meth)acryloyloxy-γ-butyrolactone of which lactone ring may be substituted by an alkyl group. Here, 1-adamantyl ester of which a carbon atom adjacent to an oxygen atom is a quaternary carbon atom is a group stable to an acid.

Specifically, examples of a monomer having a substituent having high polarity include 3-hydroxy-1-adamantyl(meth)acrylate, 3,5-dihydroxy-1-adamantyl(meth)acrylate, α-(meth)acryloyloxy-γ-butyrolactone, β-(meth)acryloyloxy-γ-butyrolactone, a monomer represented by a following formula (a), a monomer represented by (b) and hydroxystyrene.

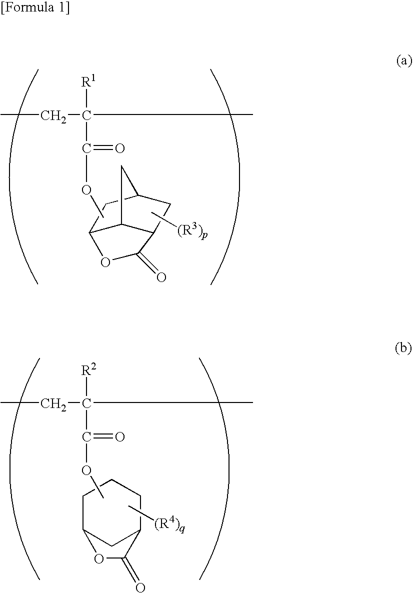

(In the formula, R¹ and R² respectively and independently represent a hydrogen atom or a methyl group, R³ and R⁴ respectively and independently represent a hydrogen atom, a methyl group or a trifluoromethyl group or a halogen atom, and p and q represent an integer of 1 to 3. When p is 2 or 3, R³s may be groups different from each other and when q is 2 or 3, R⁴s may be groups different from each other.)

Among these, a resist obtained from a resin containing a structural unit derived from 3-hydroxy-1-adamantyl(meth)acrylate, a structural unit derived from 3,5-dihydroxy-1-adamantyl(meth)acrylate, a structural unit derived from α-(meth)acryloyloxy-γ-butyrolactone, a structural unit derived from β-(meth)acryloyloxy-γ-butyrolactone, a structural unit derived from a monomer represented by a formula (a) or a structural unit derived from a monomer represented by a formula (b) is preferable because adhesiveness to a substrate and resolution of a resist tend to improve.

The resin (B) may contain other structural units. Examples thereof include a structural unit derived from a monomer having a free carboxylic acid group such as acrylate or methacrylate, a structural unit derived from an aliphatic unsaturated dicarboxylic anhydride such as maleic anhydride or itaconic anhydride, a structural unit derived from 2-norbornene, a structural unit derived from an alkyl ester of which carbon atom adjacent to an oxygen atom is secondary carbon atom or a tertiary carbon atom, and a structural unit derived from (meth)acrylate ester that is a 1-adamantyl ester.

A monomer such as 3-hydroxy-1-adamantyl(meth)acrylate or 3,5-dihydroxy-1-adamantyl(meth)acrylate is commercially available. However, these can be produced as well by reacting corresponding hydroxy adamantane with (meth)acrylate or a halide thereof.

A monomer such as (meth)acryloyloxy-γ-butyrolactone can be produced by reacting α- or β-bromo-γ-butyrolactone whose lactone ring may be substituted by an alkyl group with acrylate or methacrylate, or by reacting α- or β-hydroxy-γ-butyrolactone whose lactone ring may be substituted by an alkyl group with acrylate halide or methacrylate halide.

Examples of monomers giving structural units represented by a formula (a) and a formula (b) include (meth)acrylate esters of alicyclic lactone having a hydroxyl group such as those shown below and mixtures thereof. The esters can be produced by reacting, for example, alicyclic lactone having a corresponding hydroxyl group and (meth)acrylates (see, for example, Japanese Patent Laid-Open No. 2000-26446).

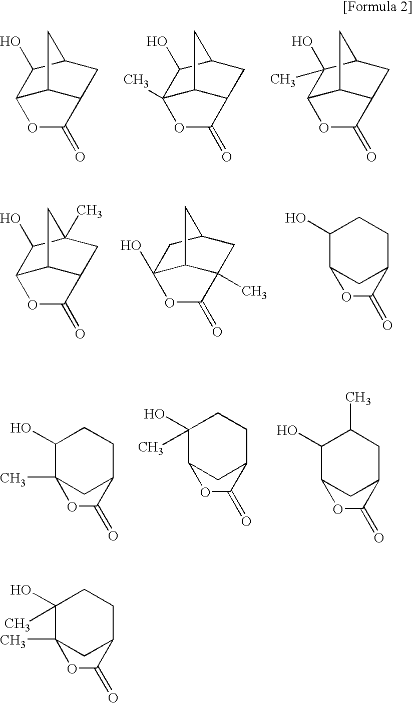

Here, examples of (meth)acryloyloxy-γ-butyrolactone include α-acryloyloxy-γ-butyrolactone, α-methacryloyloxy-γ-butyrolactone, α-acryloyloxy-β,β-dimethyl-γ-butyrolactone, α-methacryloyloxy-β,β-dimethyl-γ-butyrolactone, α-acryloyloxy-α-methyl-γ-butyrolactone, α-methacryloyloxy-α-methyl-γ-butyrolactone, β-acryloyloxy-γ-butyrolactone, β-methacryloyloxy-γ-butyrolactone and β-methacryloyloxy-α-methyl-γ-butyrolactone.

In the case of KrF excimer laser exposure, even when a structural unit derived from a styrenic monomer such as p- or m-hydroxystyrene is used as a structural unit of a resin, sufficient light transmittance can be obtained. Such a copolymer resin can be obtained by radical polymerizing a corresponding (meth)acrylate ester monomer, acetoxystyrene and styrene, followed by deacetylating with an acid.

Furthermore, a resin containing a structural unit derived from 2-norbornene has an alicyclic skeleton direct to a main chain thereof; accordingly, a sturdy structure is obtained and characteristics excellent in dry etching resistance are obtained. A structural unit derived from 2-norbornene can be introduced into a main chain by radical polymerization that uses, for example, other than corresponding 2-norbornene, an aliphatic unsaturated dicarboxylic anhydride such as maleic anhydride or itaconic anhydride. Accordingly, what is formed by opening a double bond of a norbornene structure can be represented by a formula (c), and what are formed by opening a double bond of maleic anhydride and itaconic anhydride, respectively, are represented by a formula (d) and a formula (e).

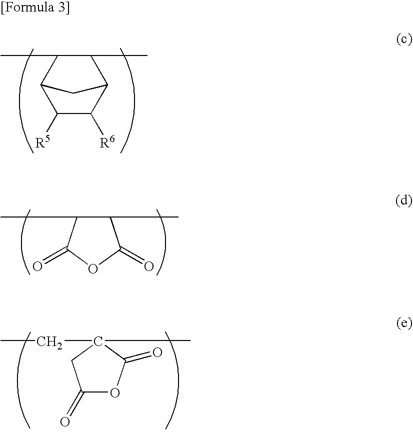

[In the formula (c), R⁵ and/or R⁶, respectively and independently, represent a hydrogen atom, an alkyl group having 1 to 3 carbon atoms, a carboxyl group, a cyano group or —COOU (U represents an alcohol residue), or R⁵ and R⁶ bond each other to represent a carboxylic anhydride residue represented by —C(═O)OC(═O)—.]

In the case where R⁵ and/or R⁶ are —COOU, a carboxyl group is esterized, and examples of alcohol residue corresponding to U include an optionally substituted alkyl group having about 1 to 8 carbon atoms, a 2-oxooxolane-3- or -4-yl group. Here, the alkyl group may be substituted by a hydroxyl group and an alicyclic hydrocarbon group.

Examples of an alkyl group include a methyl group, an ethyl group, an n-propyl group, an isopropyl group, an n-butyl group, a sec-butyl group, a tert-butyl group, a pentyl group, a hexyl group, an octyl group and a 2-ethylhexyl group.

Examples of a hydroxyl group-bonded alkyl group, namely, a hydroxylalkyl group include a hydroxymethyl group and a 2-hydroxyethyl group.

As an alicyclic hydrocarbon group, an alicyclic hydrocarbon group having about 3 to 30 carbon atoms is cited, and examples thereof include a cyclopropyl group, a cyclobutyl group, a cyclopentyl group, a cyclohexyl group, a cycloheptyl group, a cyclodecyl group, a cyclohexenyl group, a bicyclobutyl group, a bicyclohexyl group, a bicyclooctyl group and a 2-norbornyl group.

In the specification, in all chemical formulas, though different depending on the number of carbon atoms, unless stated clearly, as the above-mentioned groups such as an alkyl group and the like, the same as those mentioned above are illustrated. A group that can take both of a straight chain and a branched chain includes both thereof (the same in what follows).

Specific examples of a norbornene structure that is a monomer imparting a structural unit stable to an acid and represented by a formula (c) include following compounds such as 2-norbornene, 2-hydroxy-5-norbornene, 5-norbornene-2-carboxylate, 5-norbornene-2-methyl carboxylate, 2-hydroxy-1-ethyl 5-norbornene-2-carboxylate, 5-norbornene-2-methanol and 5-norbornene-2,3-dicarboxylic anhydride.

When —COOU of R⁵ and/or R⁶ in the formula (c) is a group unstable to an acid such as alicyclic ester where a carbon atom adjacent to an oxygen atom is a tertiary carbon atom, a structural unit has a norbornene structure but a group unstable to an acid.

Examples of the monomer containing a norbornene structure and a group unstable to an acid include tert-butyl 5-norbornene-2-carboxylate, 1-cyclohexyl-1-methylethyl 5-norbornene-2-carboxylate, 1-methylcyclohexyl 5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxycyclohexyl)-1-methyl ethyl 5-norbornene-2-carboxylate, 1-methyl-1-(4-oxocyclohexyl)ethyl 5-norbornene-2-carboxylate, and 1-(1-adamantyl)-1-methylethyl 5-norbornene-2-carboxylate.

In the resin (B) of a resist composition used in the present invention, though varying depending on a kind of radiation for patterning exposure and a kind of a group unstable to an acid, usually, it is preferable that the content of a structural unit derived from a monomer having a group unstable to an acid in a resin is controlled in the range of 10 to 80% by mole.

In the case where a structural unit derived in particular from 2-alkyl-2-adamantyl(meth)acrylate or 1-(1-adamantyl)-1-alkylalkyl (meth)acrylate is contained as a structural unit derived from a monomer having a group unstable to an acid, when the structural unit is set to 15% by mole or more of the whole structural unit constituting a resin, a resin becomes a sturdy structure owing to possession of an alicyclic group and a resulting resist is advantageous from the viewpoint of the dry etching resistance.

When an alicyclic compound having an olefinic double bond in a molecule or an aliphatic unsaturated dicarboxylic anhydride is used as a monomer, these are prone to be difficult to addition polymerize. Accordingly, by considering this point, these are preferable to be used in excess.

Furthermore, as a monomer used, monomers that have the same olefinic double bond and are different in a group unstable to an acid may be used in combination, monomers that have the same group unstable to an acid and are different in the olefinic double bond may be used in combination, or monomers where a combination of a group unstable to an acid and an olefinic double bond is different may be used in combination.

A weight average molecular weight of the resin (B) is preferable to be 7,000 to 10,000. The weight average molecular weight of the resin (B) is more preferable to be 7,200 or more, still more preferable to be 7,600 or more, and particularly preferable to be 8,800 or more. Furthermore, the weight average molecular weight of the resin (B) is more preferable to be 9,800 or less, still more preferable to be 9,500 or less and particularly preferable to be 9,000 or less. The weight average molecular weight in this case is obtained, as is described later, by gel permeation chromatography in terms of standard polyethylene.

A glass transition temperature (Tg) of the resin (B) is preferable to be 150 to 200° C. Tg of the resin (B) is more preferable to be 165 to 200° C. When Tg is in the range of 150 to 200° C., during hard bake, a pattern is not likely to collapse. The glass transition temperature (Tg) is a value measured with a DSC such as a temperature modulation DSC (trade name: DSC Q1000(TA), manufactured by TA Instruments).

At least one of the respective resist compositions for forming n patterned resist films is preferable to contain a resin having a weight average molecular weight of 7,000 to 10,000 and a glass transition temperature of 150 to 200° C. as the resin (B). Thereby, even when a resist pattern is formed via a plurality of times of pattern transfer, a resist pattern having an excellent shape can be formed. From such the viewpoints, all the resist compositions for forming a plurality of resist films constituting a resist pattern are preferable to contain a resin having a weight average molecular weight of 7,000 to 10,000 and a glass transition temperature of 150 to 200° C. as the resin (B).

A photoacid generator (A) in a resist composition is not particularly restricted as long as it can generate an acid by exposure. A photoacid generator used in the art can be used.

For example, as a photoacid generator (A), compounds represented by a formula (I) can be cited.

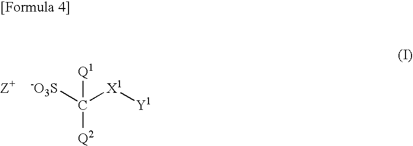

(In the formula (I), Q¹ and Q², respectively and independently, represent a fluorine atom or a perfluoroalkyl group having 1 to 6 carbon atoms. X¹ represents a single bond or —[CH₂]ₖ—, a methylene group contained in the —[CH₂]ₖ— may be substituted by an oxygen atom and/or a carbonyl group, a hydrogen atom contained in the —[CH₂]ₖ— may be substituted by a straight or branched aliphatic hydrocarbon group having 1 to 4 carbon atoms. k represents an integer of 1 to 17. Y¹ represents an alicyclic hydrocarbon group having 4 to 36 carbon atoms, which may have a substituent. Z⁺ represents an organic cation.)

Here, as a hydrocarbon, the same as the alkyl group mentioned above (including a straight chain and a branched chain) or an alkyl group obtained by introducing one or more double bond or triple bond in any one of positions of the alkyl group may be used. Among these, alkyl groups are preferable.

A cyclic hydrocarbon group having 3 to 30 carbon atoms may be or may not be an aromatic group. Examples thereof include an alicyclic group, an aromatic group, a monocyclic group, a condensed ring group having two or more rings, a bridged ring group, and a cyclic hydrocarbon group where a plurality of cyclic hydrocarbons is linked via or not via a carbon atom. Specific examples thereof include, in addition to above-mentioned alicyclic hydrocarbon groups such as a cycloalkyl group having 4 to 8 carbon atoms and a norbornyl group, a phenyl group, an indenyl group, a naphthyl group, an adamantyl group, a norbornyl group, a tolyl group and a benzyl group.

As a ring of a cyclic hydrocarbon containing an oxygen atom, what are shown below are illustrated. A bonding hand may take an arbitrary position.

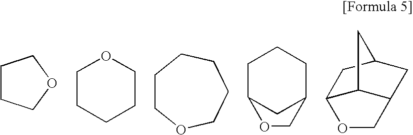

Examples of an alkoxy group include a methoxy group, an ethoxy group, an n-propoxy group, an isopropoxy group, an n-butoxy group, a sec-butoxy group, a tert-butoxy group, a pentoxy group, a hexoxy group, an octyloxy group and a 2-ethylhexyloxy group.

Examples of perfluoroalkyl group include a trifluoromethyl group, a perfluoroethyl group, a perfluoropropyl group and a perfluorobutyl group.

A photoacid generator (A) may be a compound represented by, for example, a formula (V) or a formula (VI) shown below.

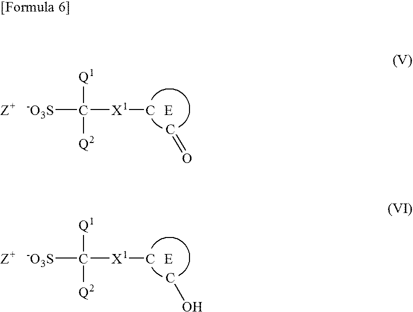

(In the formulas (V) and (VI), a ring E represents a cyclic hydrocarbon group having 3 to 30 carbon atoms, and the ring E may be substituted by at least one selected from the group consisting of an alkyl group having 1 to 6 carbon atoms, an alkoxy group having 1 to 6 carbon atoms, a perfluoroalkyl group having 1 to 4 carbon atoms, a hydroxyalkyl group having 1 to 6 carbon atoms, a hydroxyl group and a cyano group. X¹, Z⁺, Q¹ and Q² are the same as those mentioned above.)

As an alkylene group, (Y-1) to (Y-12) shown below are illustrated.

Furthermore, a photoacid generator (A) may be a compound represented by a formula (III) shown below.

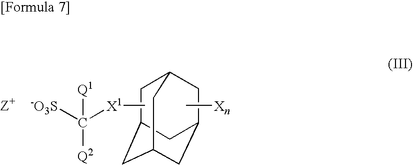

(In the formula, X represents —OH or -Xa-OH (here, Xa represents a straight or branched alkylene group having 1 to 6 carbon atoms), n represents an integer of 1 to 9 and Z⁺, Q¹ and Q² are the same as those mentioned above.)

As Q¹ and Q², in particular, a fluorine atom is preferable.

Furthermore, n is preferable to be 1 to 2.

As Xa, for example, (Y-1) to (Y-12) shown below are cited and, among these, (Y-1) and (Y-2) are preferable because these can be readily produced.

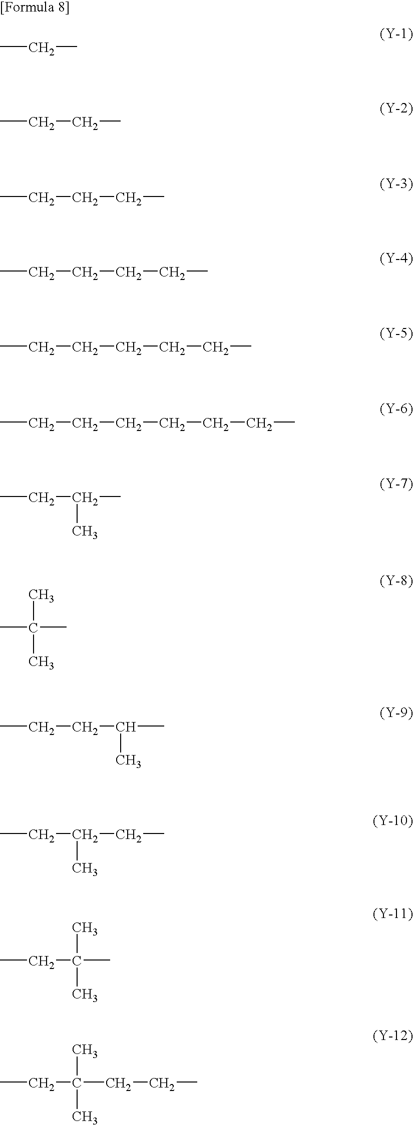

As an anion in a compound represented by a formula (I), (III), (V) or (VI), for example, a compound shown below is cited.

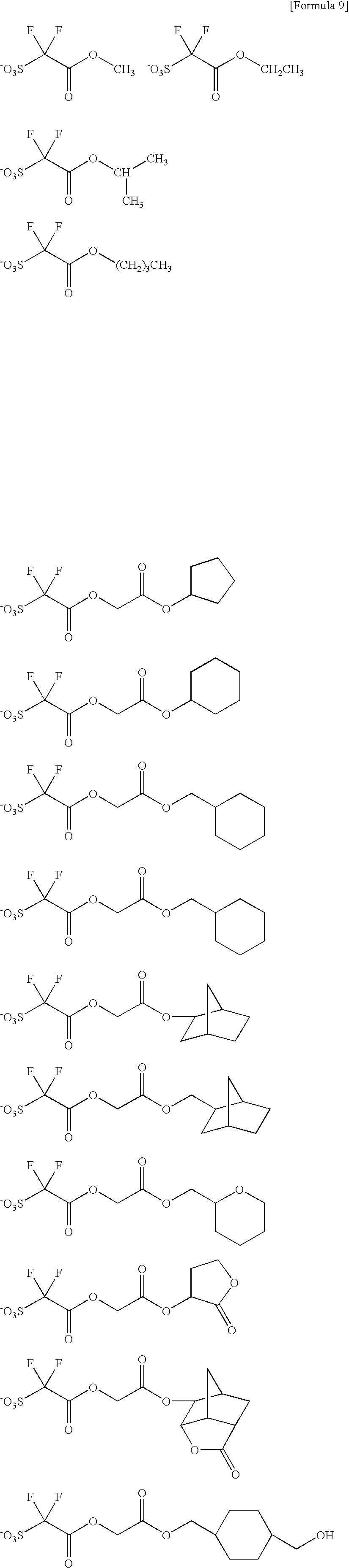

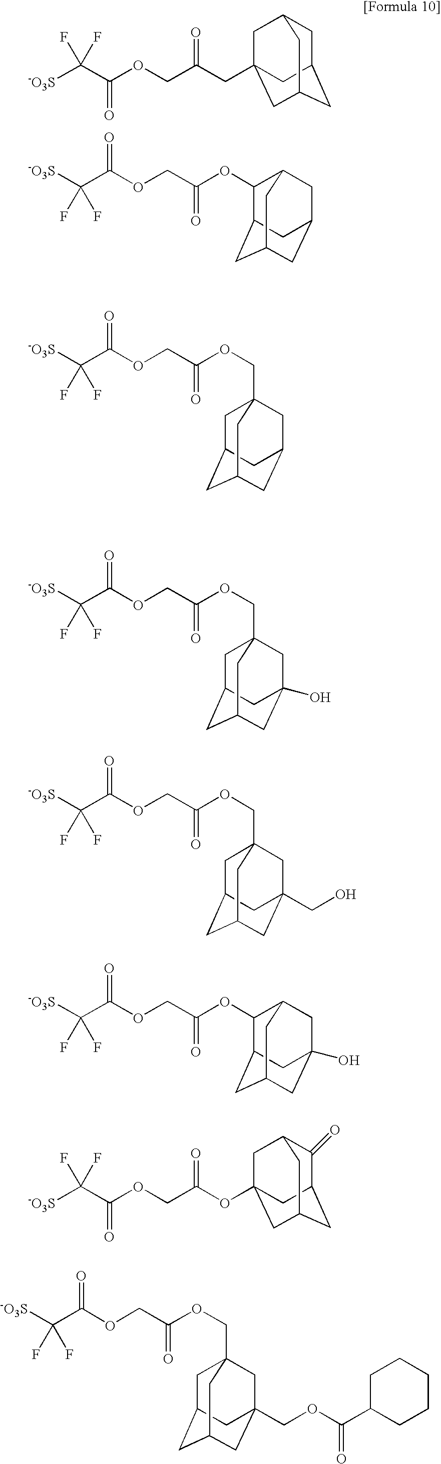

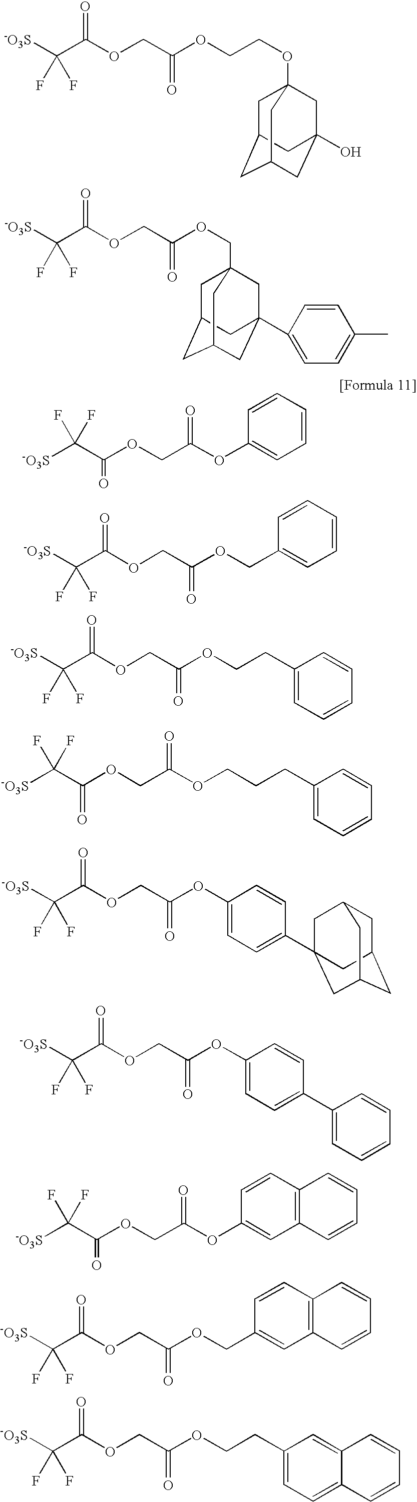

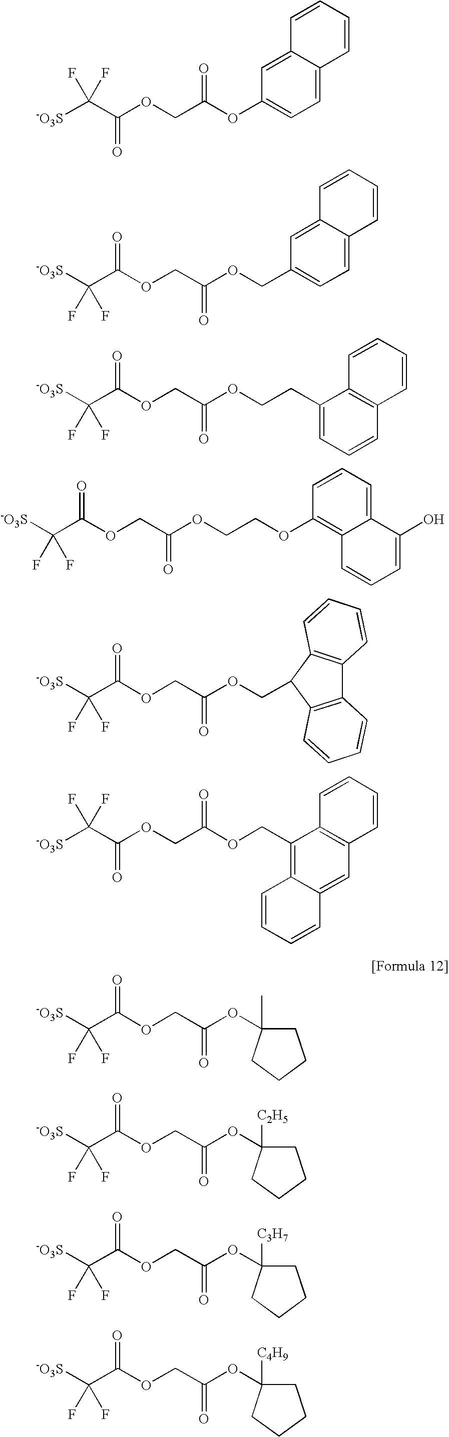

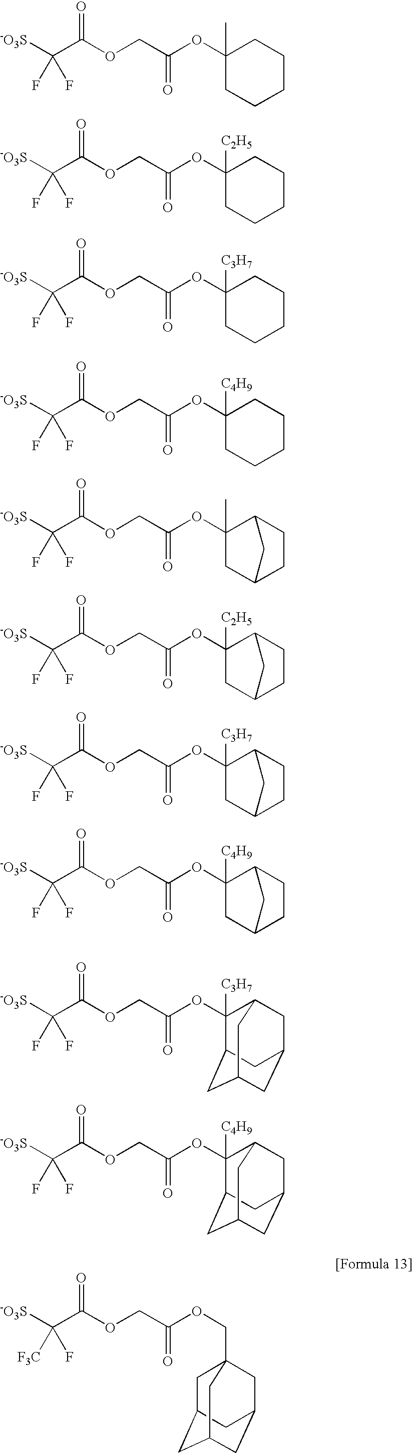

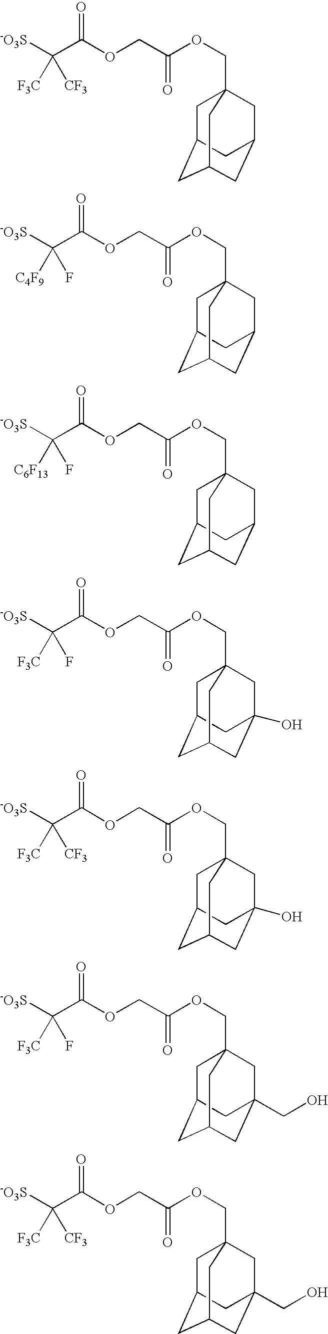

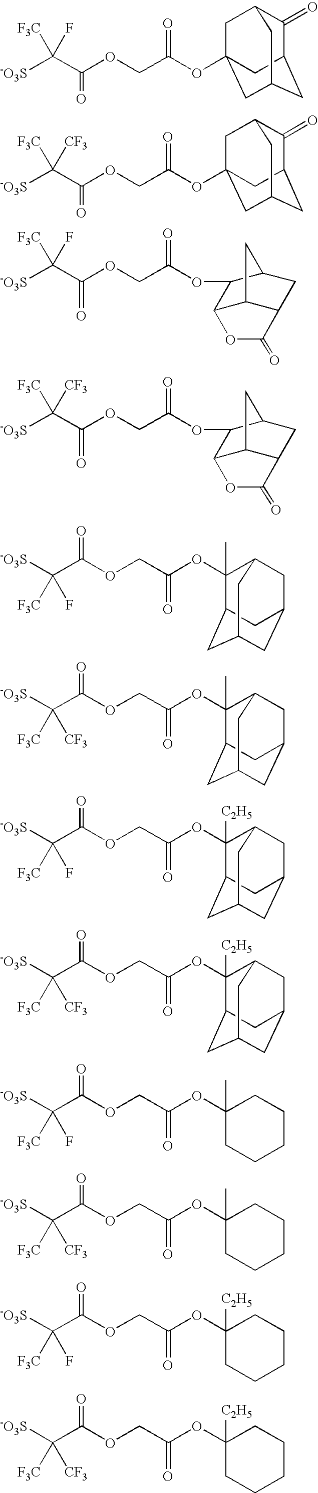

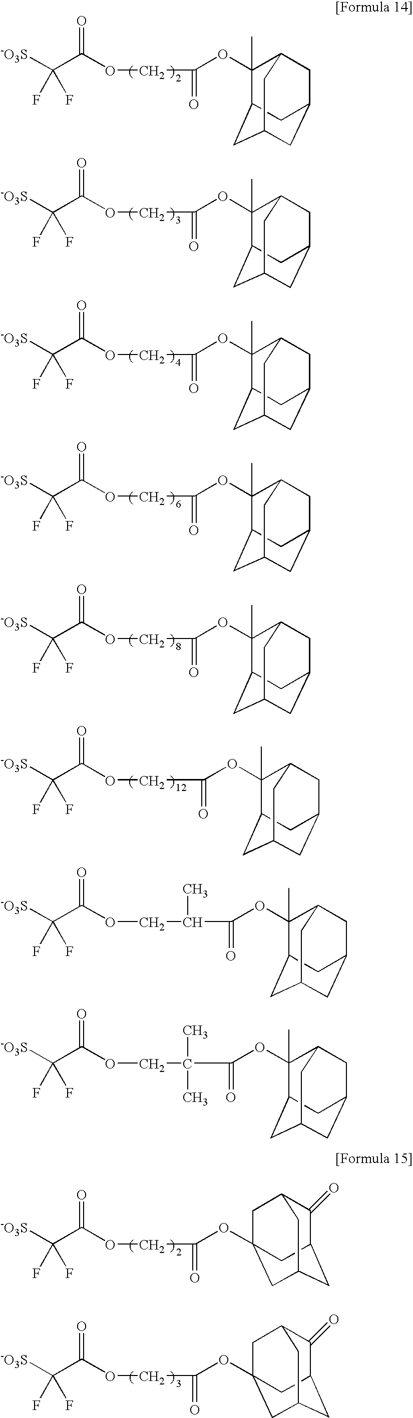

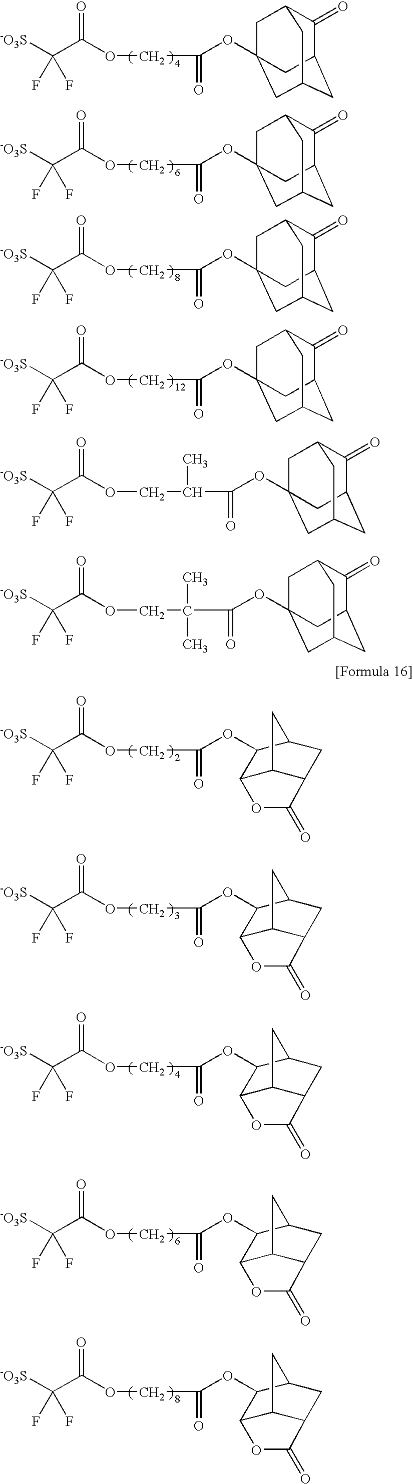

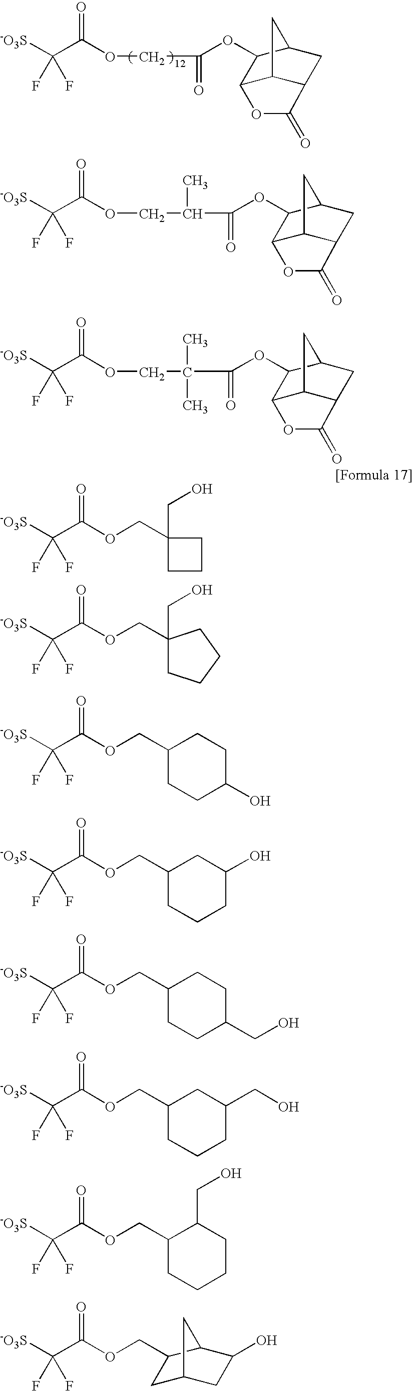

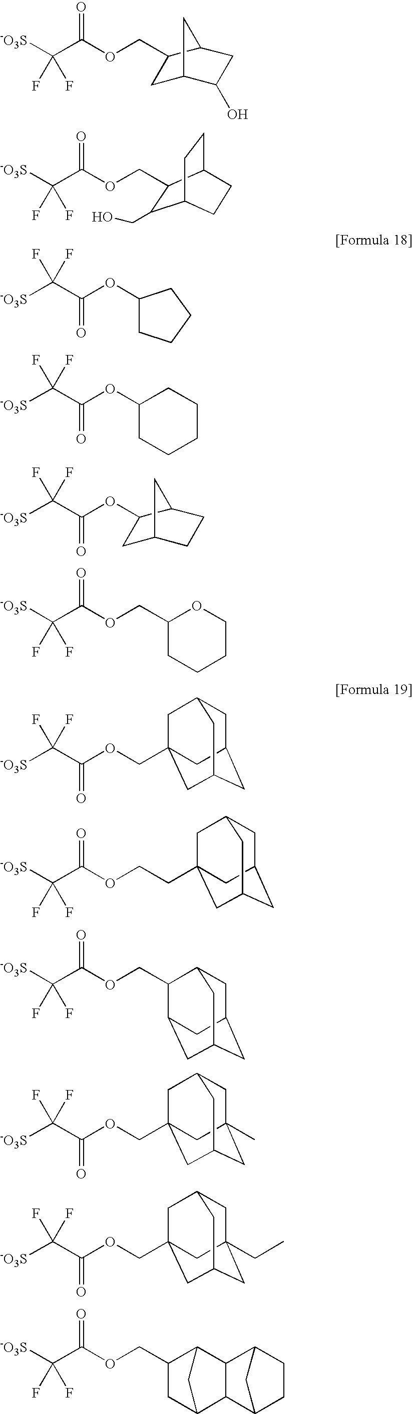

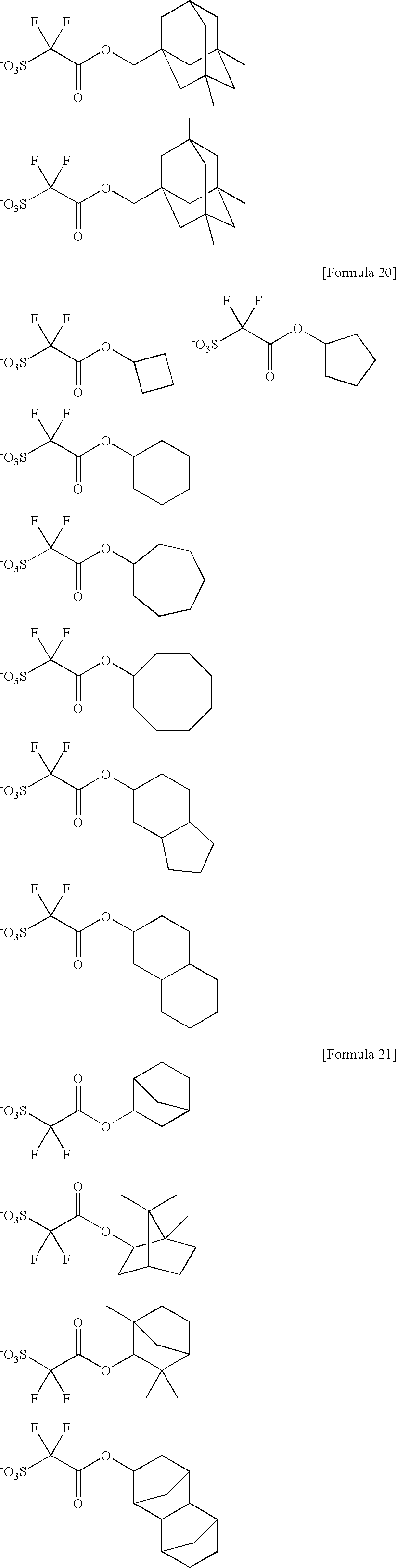

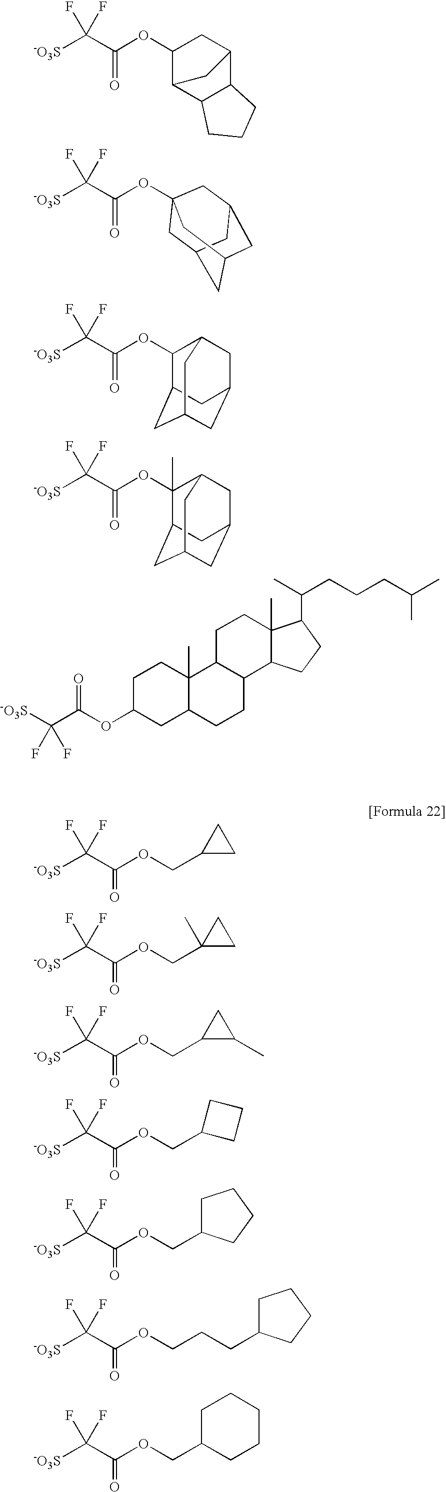

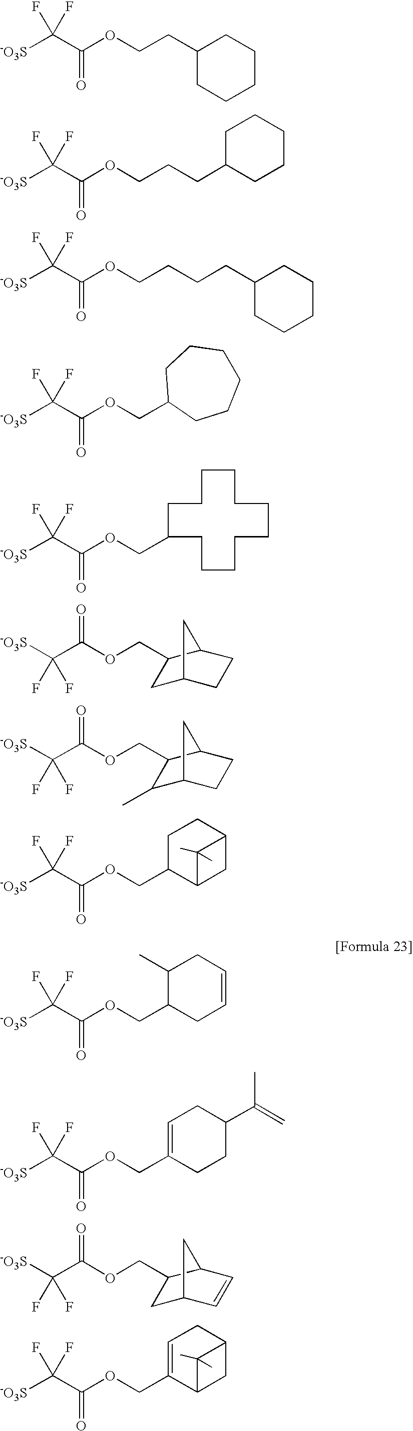

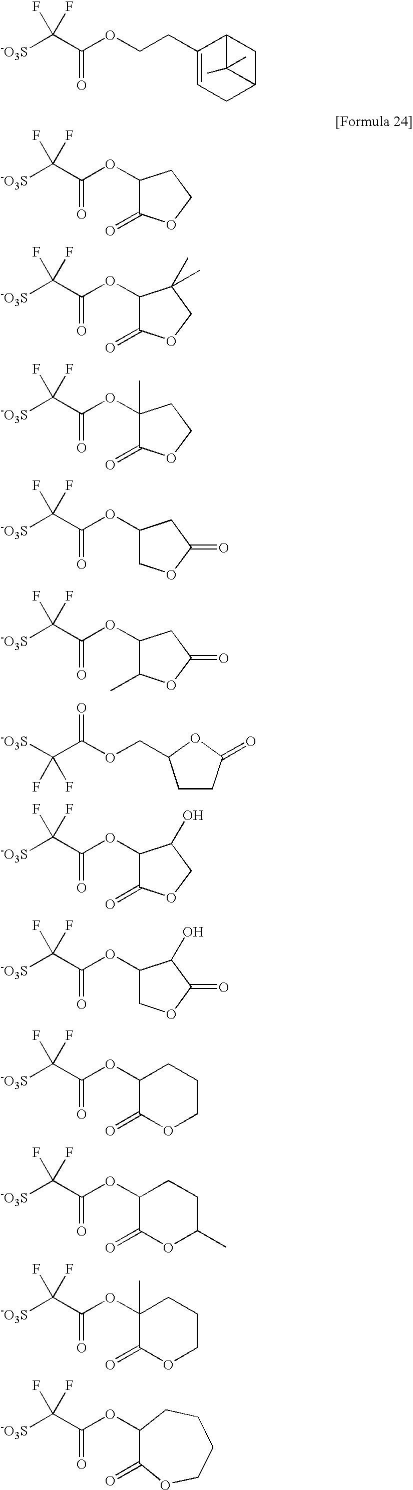

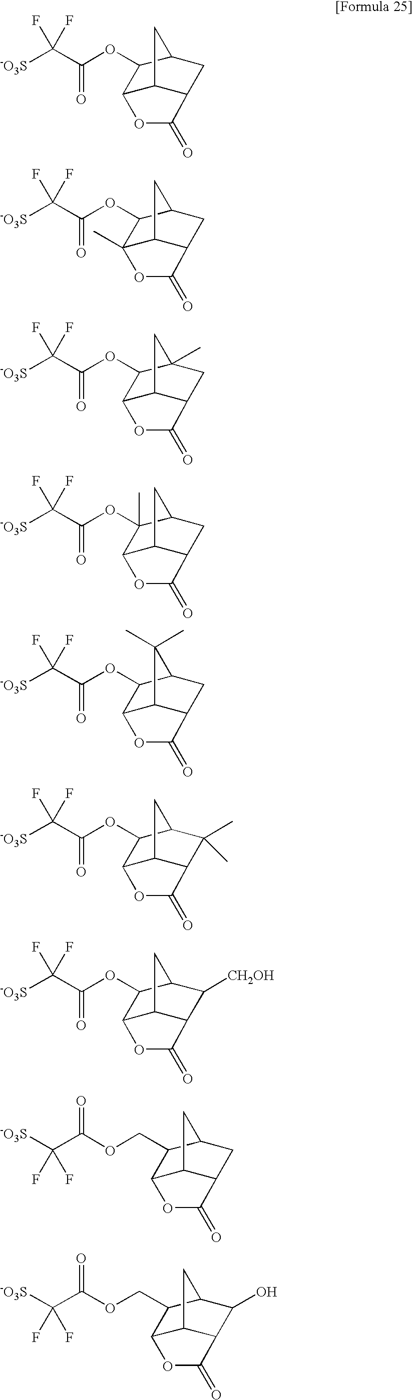

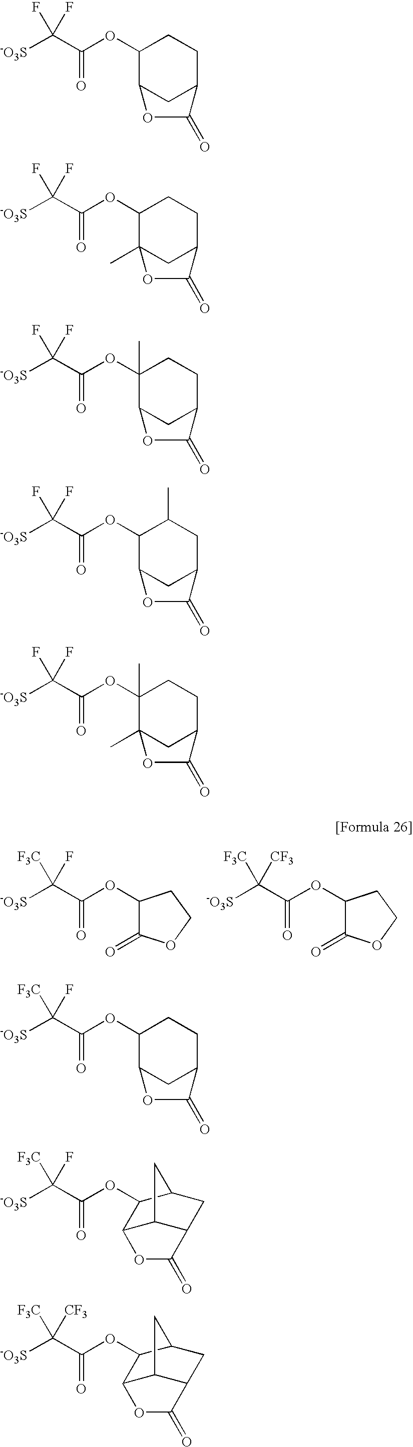

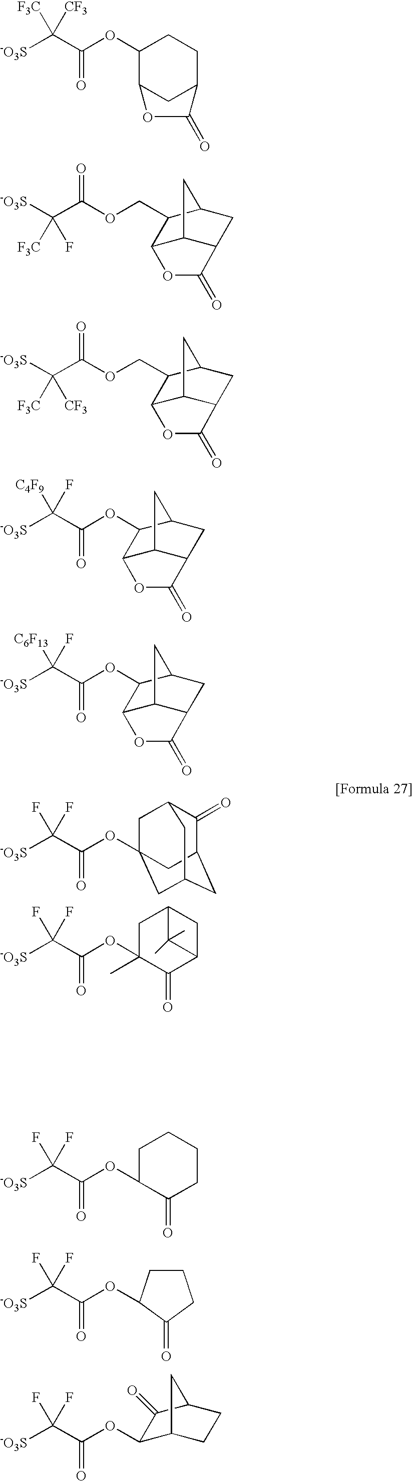

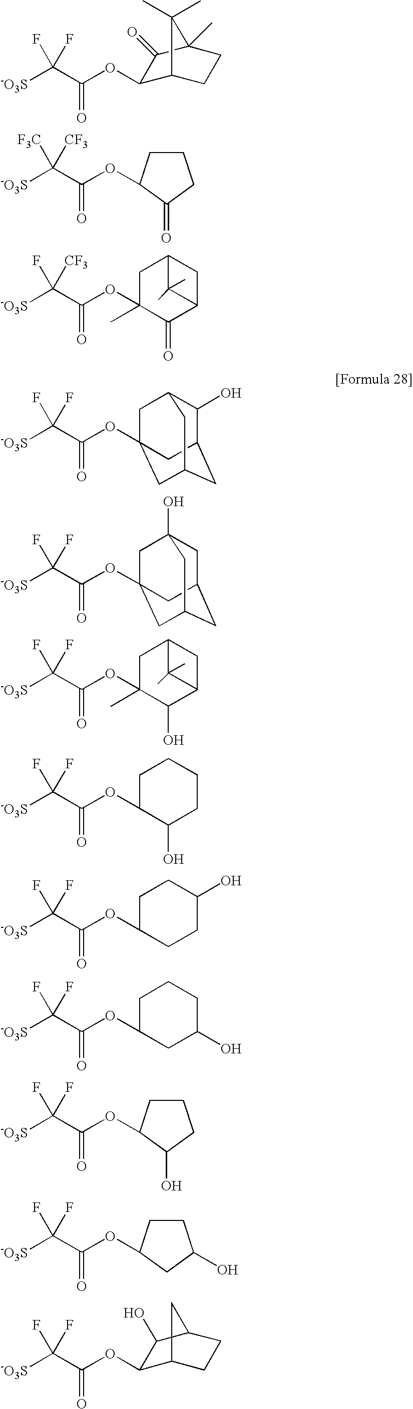

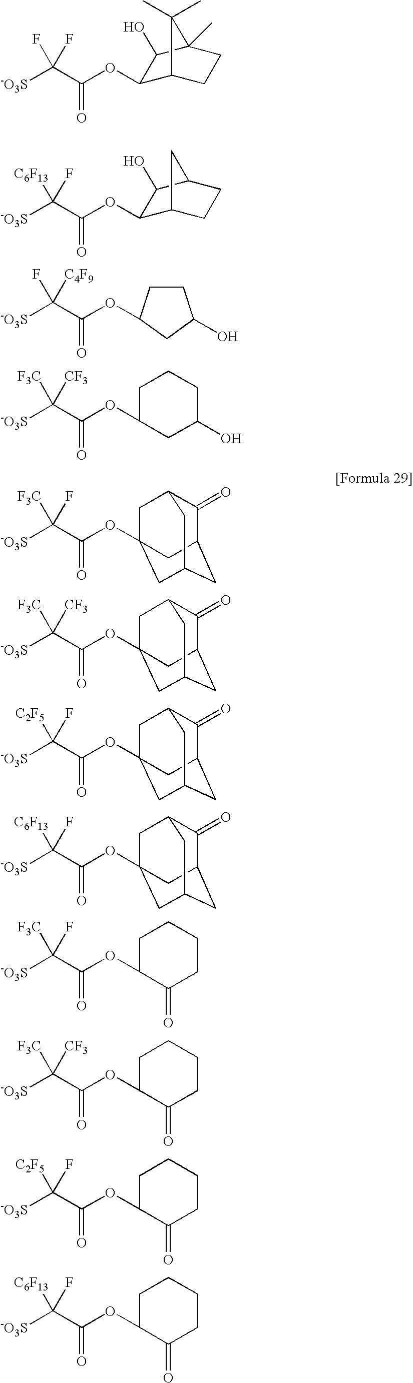

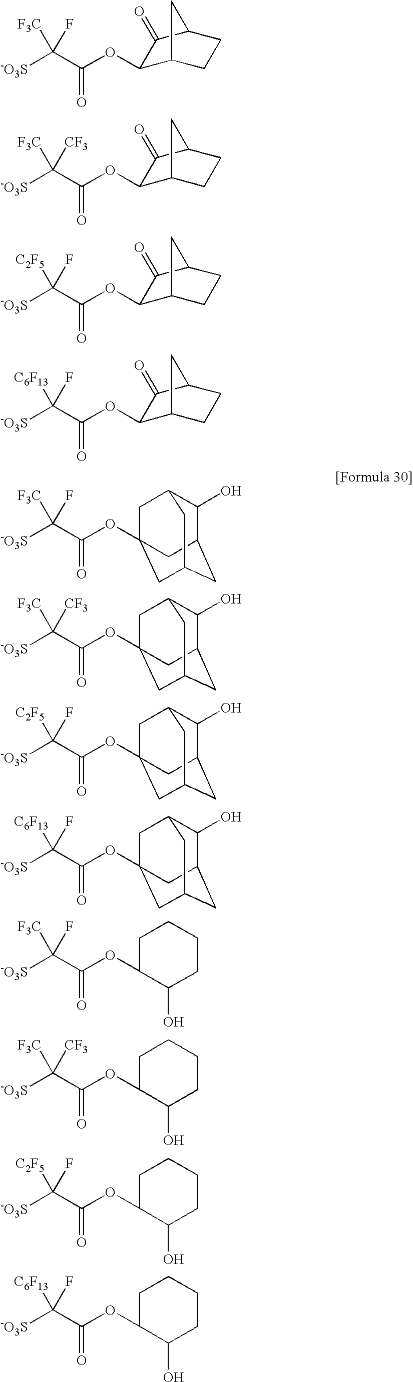

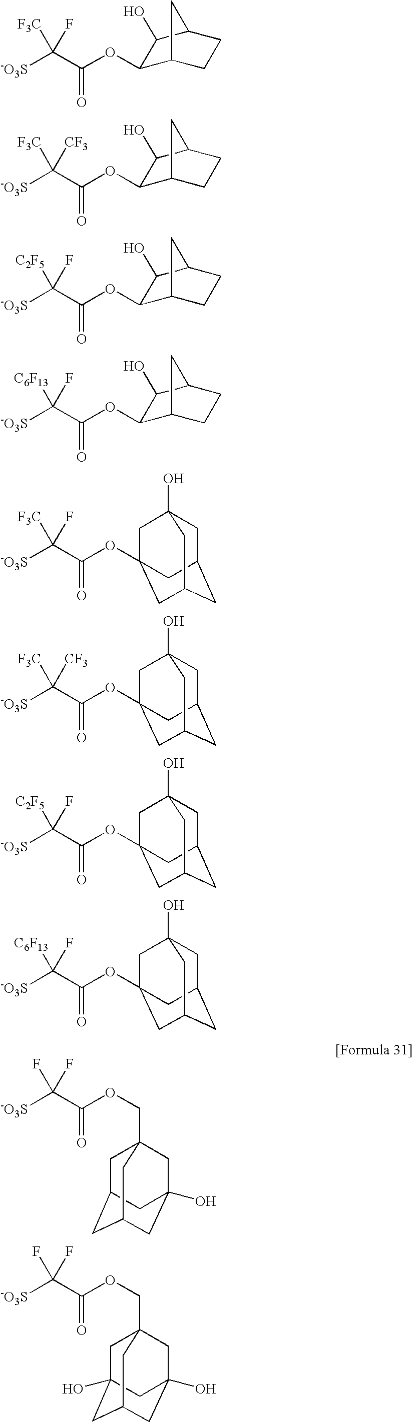

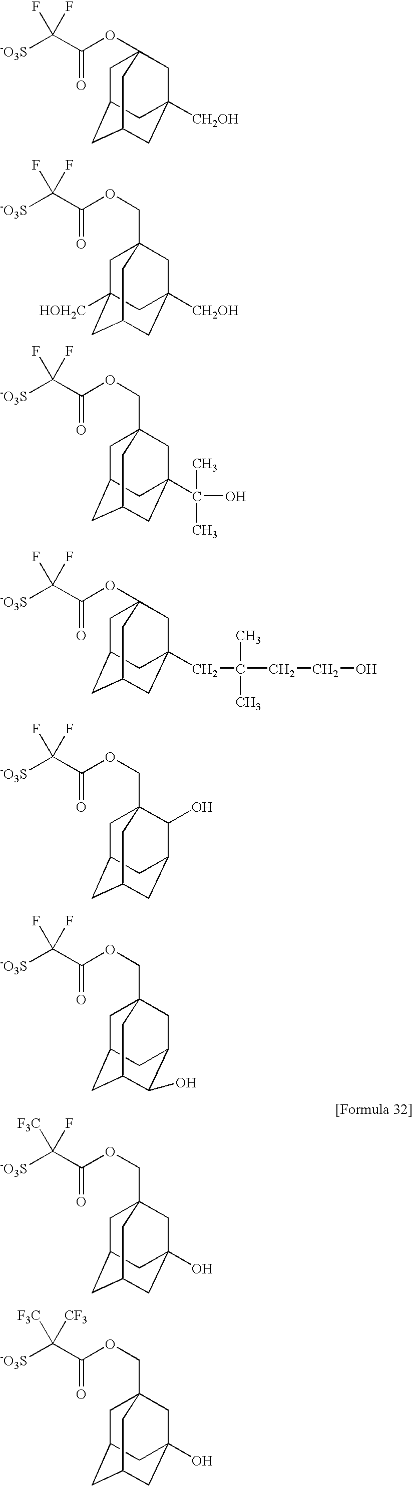

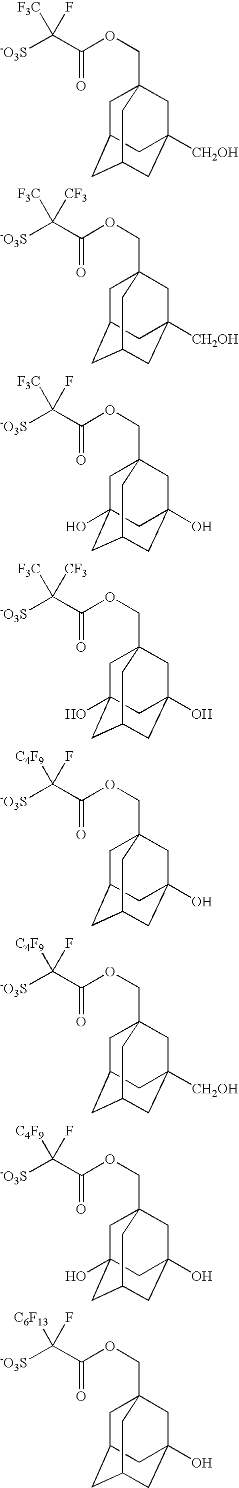

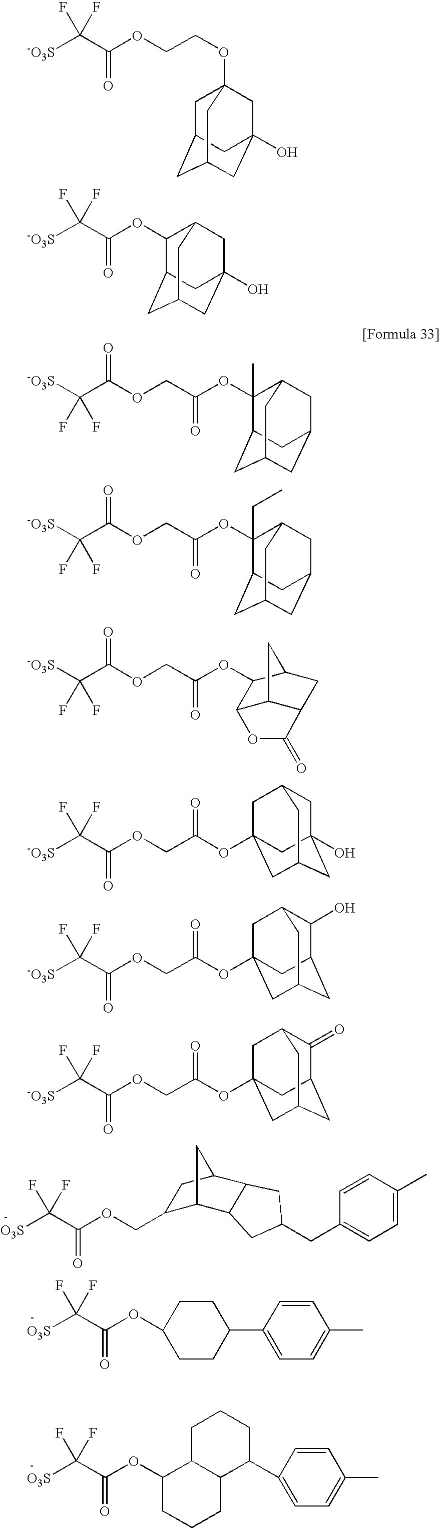

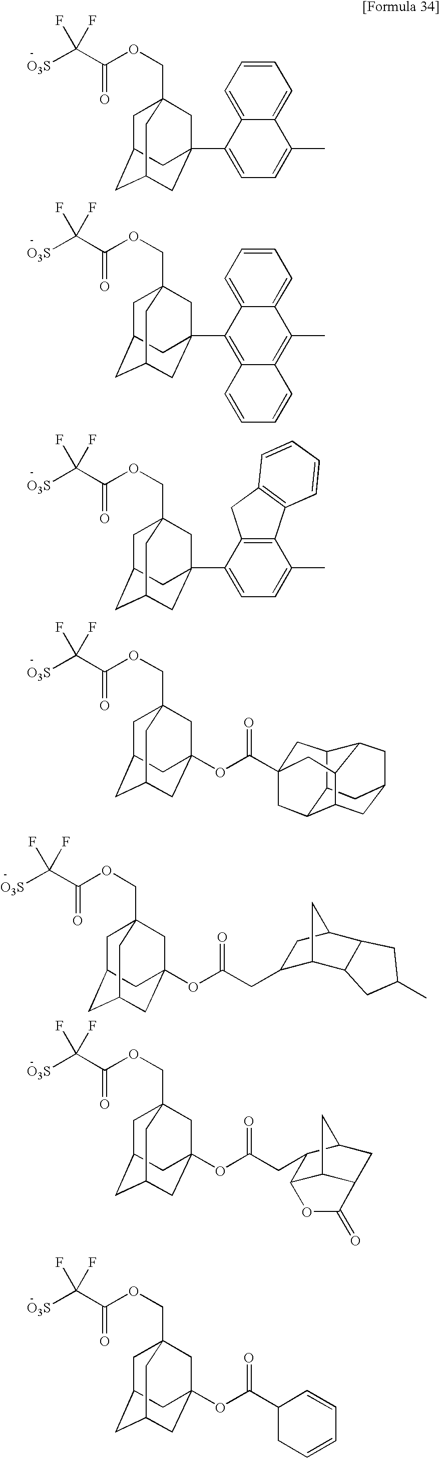

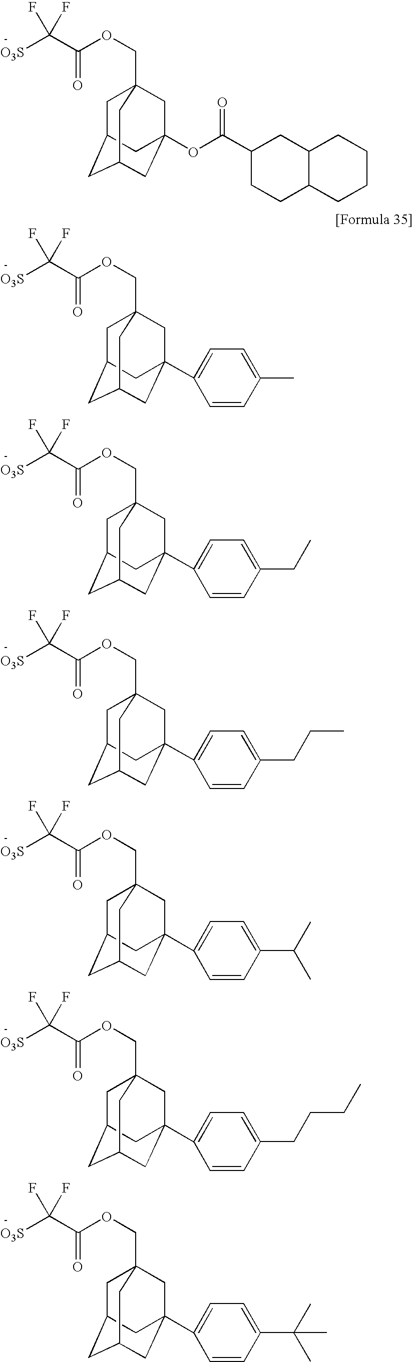

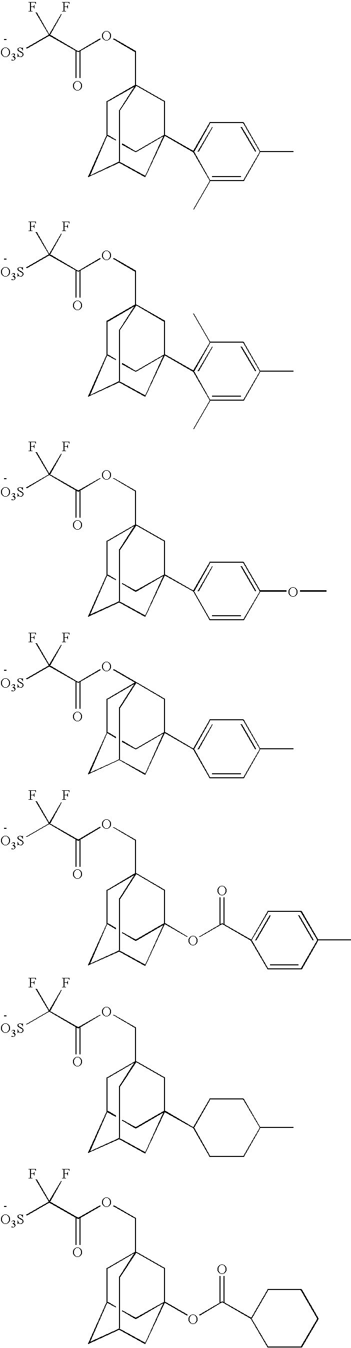

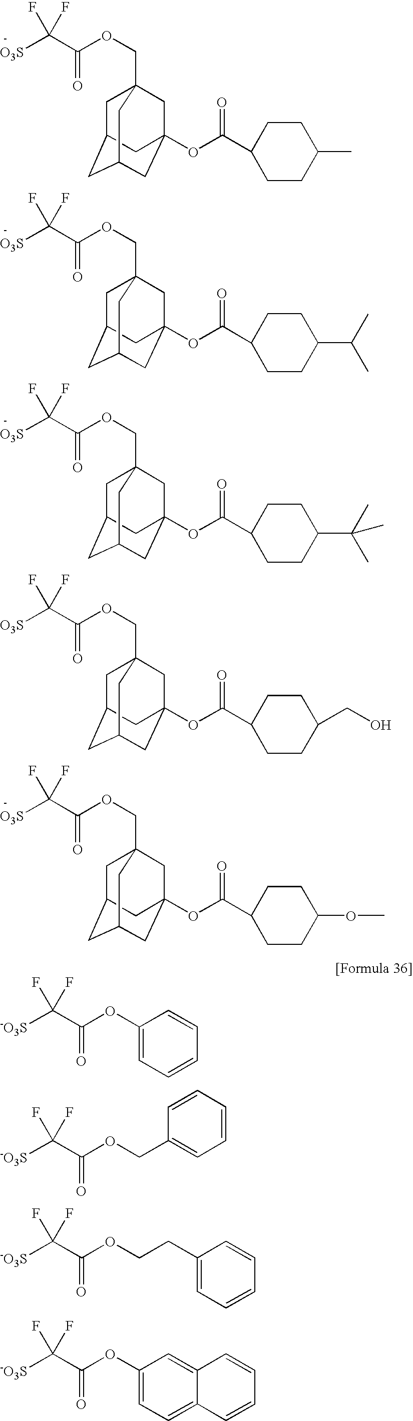

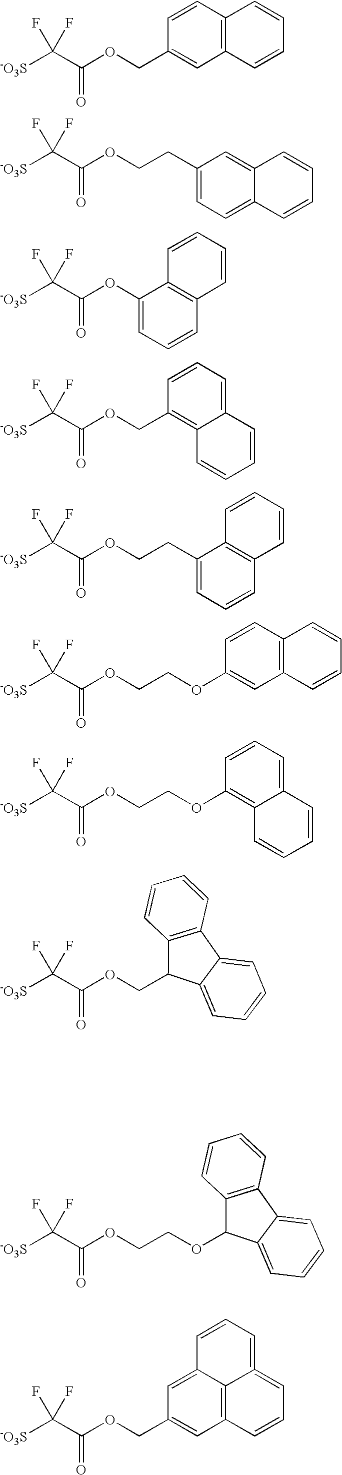

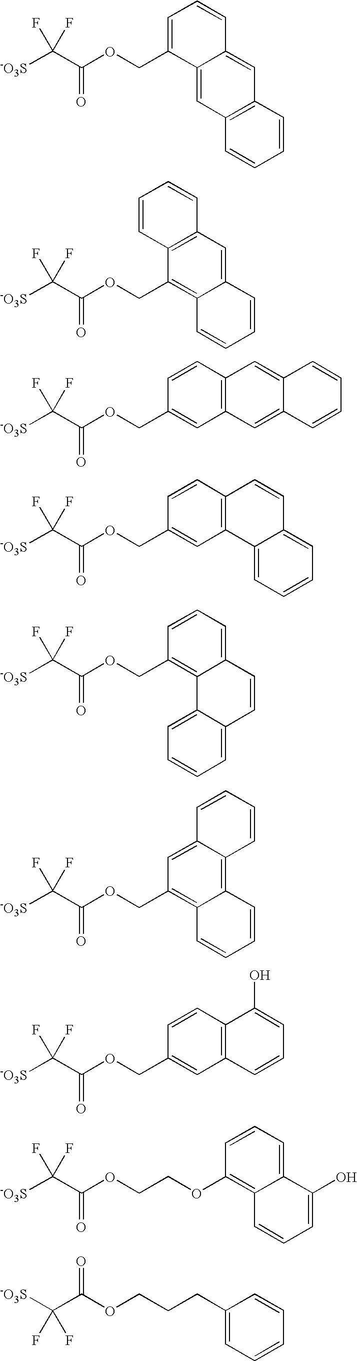

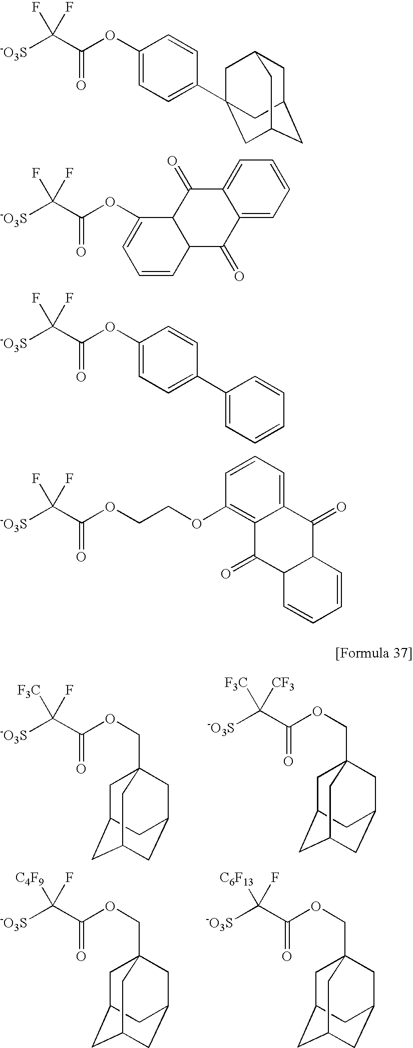

Furthermore, a photoacid generator may be a compound represented by a formula (VII) shown below.

Z⁺—O₃S—R^{b} (VII)

(In the formula, R^{b} represents a straight or branched alkyl group or a perfluoroalkyl group having 1 to 6 carbon atoms, and Z⁺ has the same meaning as that mentioned above.)

As the R^{b}, a perfluoroalkyl group having 1 to 6 carbon atoms is particularly preferable.

Specific examples of anion of a formula (VII) include ions of trifluoromethane sulfonate, pentafluoroethane sulfonate, heptafluoropropane sulfonate and perfluorobutane sulfonate.

In compounds represented by formulas (I), (III) and (V) to (VII), as an organic counter ion of Z⁺, a cation represented by a formula (VIII) is cited.

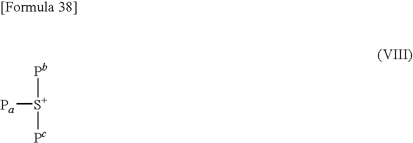

(In the formula (VIII), P^{a} to P^{c}, respectively and independently, represent a straight or branched alkyl group having 1 to 30 carbon atoms or a cyclic hydrocarbon group having 3 to 30 carbon atoms. When P^{a} to P^{c} each are an alkyl group, the alkyl group may be substituted by at least one selected from the group consisting of a hydroxyl group, an alkoxy group having 1 to 12 carbon atoms, a cyclic hydrocarbon group having 3 to 12 carbon atoms, an ester group, an oxo group, a cyano group, an amino group, an amino group substituted by an alkyl group having 1 to 4 carbon atoms and a carbamoyl group, or at least one methylene group of the alkyl group may be substituted by an oxygen atom. When P^{a} to P^{c} each are a cyclic hydrocarbon group, the cyclic hydrocarbon group may be substituted by at least one selected from the group consisting of a hydroxyl group, an alkyl group having 1 to 12 carbon atoms or an alkoxy group having 1 to 12 carbon atoms, an ester group, an oxo group, a cyano group, an amino group, an amino group substituted by an alkyl group having 1 to 4 carbon atoms and a carbamoyl group, or at least one methylene group of the cyclic hydrocarbon group may be substituted by an oxygen atom.)

In particular, cations represented by a formula (IIa), a formula (IIb), a formula (IIc) and a formula (IId) are illustrated.

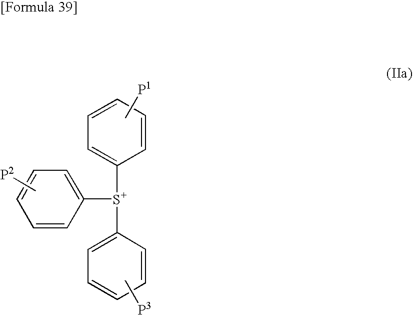

In the formula (IIa), P¹ to P³, respectively and independently, represent a hydrogen atom, a hydroxyl group, an alkyl group having 1 to 12 carbon atoms or an alkoxy group having 1 to 12 carbon atoms.

As the alkyl group and alkoxy group, the same as those mentioned above are cited.

Among cations represented by a formula (IIa), a cation represented by a formula (IIe) is preferable because it can be readily produced.

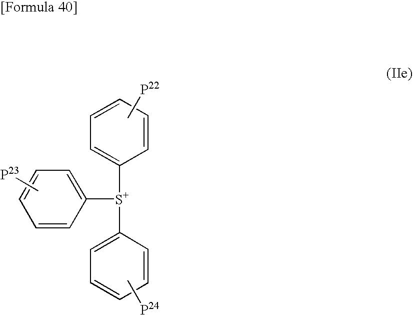

In the formula (IIe), P²² to P²⁴, respectively and independently, represent a hydrogen atom or an alkyl group having 1 to 4 carbon atoms, and the alkyl group may be either a straight chain or a branched chain.

Furthermore, an organic counter ion of Z⁺ may be a cation represented by a formula (IIb) including an iodine cation.

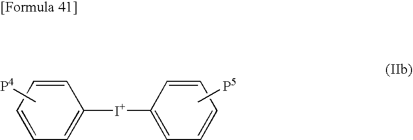

In the formula (IIb), P⁴ and P⁵, respectively and independently, represent a hydrogen atom, a hydroxyl group, and an alkyl group having 1 to 12 carbon atoms or an alkoxy group having 1 to 12 carbon atoms.

Furthermore, an organic counter ion of Z⁺ may be a cation represented by a formula (IIc).

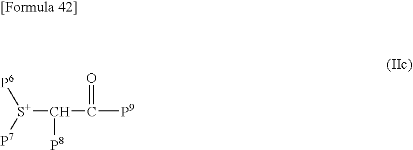

(In the formula (IIe), P⁶ and P⁷, respectively and independently, represent an alkyl group having 1 to 12 carbon atoms or a cycloalkyl group having 3 to 12 carbon atoms and the alkyl group may be either a straight chain or a branched chain.)

Examples of a cycloalkyl group include what are mentioned below.

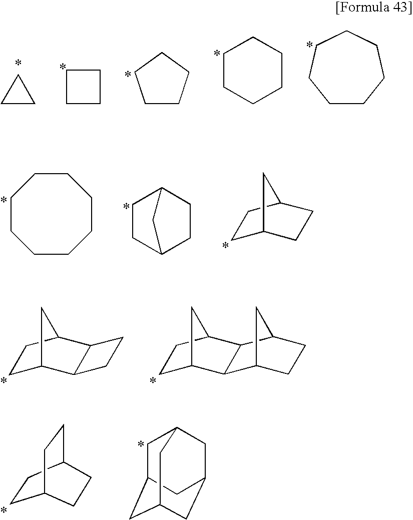

A bond is present at a position of * (an asterisk).

Furthermore, P⁶ and P⁷ may bond each other to form a divalent hydrocarbon group having 3 to 12 carbon atoms. A carbon atom contained in a divalent hydrocarbon group may be arbitrarily substituted by a carbonyl group, an oxygen atom, or a sulfur atom.

A divalent hydrocarbon group may be any one of saturated, unsaturated, chained and ring hydrocarbon groups. Among these, a chained saturated hydrocarbon group, in particular, an alkylene group is preferable. Examples of the alkylene group include a trimethylene group, a tetramethylene group, a pentamethylene group and a hexamethylene group.

In the formula (IIc), P⁸ represents a hydrogen atom, P⁹ represents an alkyl group having 1 to 12 carbon atoms, a cycloalkyl group having 3 to 12 carbon atoms or an optionally substituted aromatic group or P⁸ and P⁹ bond each other to represent a divalent hydrocarbon group having 3 to 12 carbon atoms.

As the alkyl group, cycloalkyl group and divalent hydrocarbon group, the same as those mentioned above are cited.

As an aromatic group, an aromatic group having 6 to 20 carbon atoms such as an aryl group or an aralkyl group is preferable. Specific examples thereof include a phenyl group, a tolyl group, a xylyl group, a biphenyl group, a naphthyl group, a benzyl group, a phenetyl group and an anthracenyl group. Among these, a phenyl group and a benzyl group are preferable. Examples of a group that may be a substituent on an aromatic group include a hydroxyl group, an alkyl group having 1 to 6 carbon atoms and a hydroxyalkyl group having 1 to 6 carbon atoms.

Furthermore, an organic counter ion of Z⁺ may be a cation represented by a formula (IId).

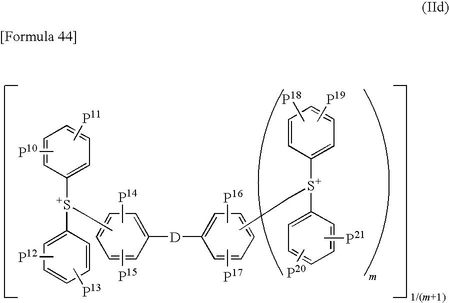

In the formula (Id), P¹⁰ to P²¹, respectively and independently, represent a hydrogen atom, a hydroxyl group, and an alkyl group having 1 to 12 carbon atoms or an alkoxy group having 1 to 12 carbon atoms. The alkyl group and the alkoxy group are the same as those mentioned above. D represents a sulfur atom or an oxygen atom. m represents 0 or 1.

As a specific example of a cation Z⁺ represented by the formula (IIa), cations represented by formulas shown below can be cited.

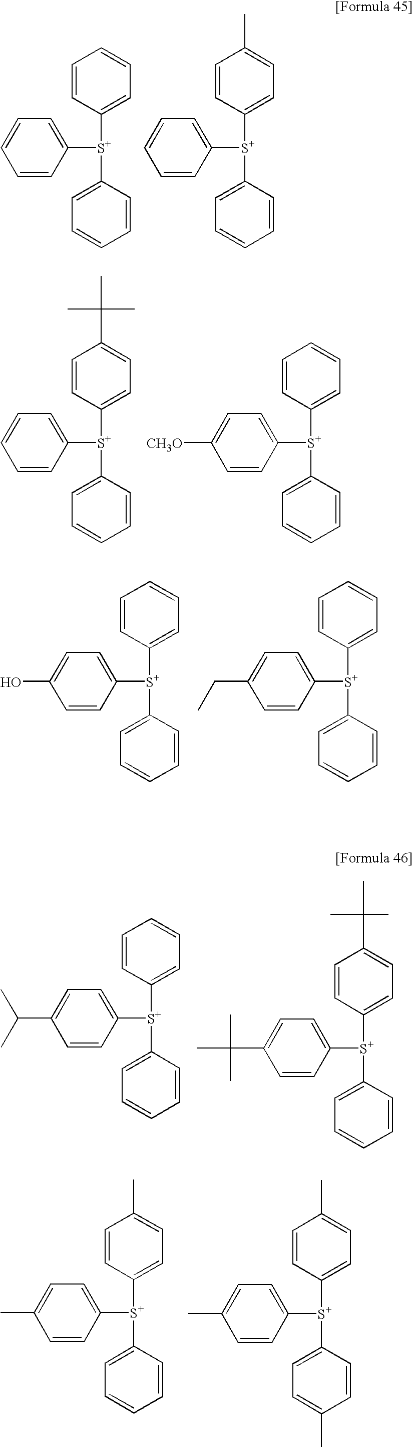

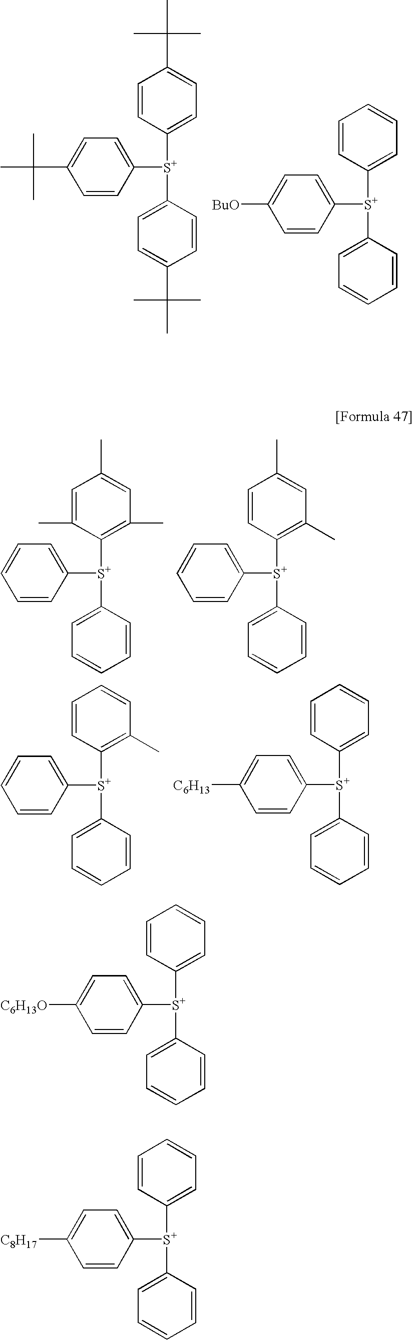

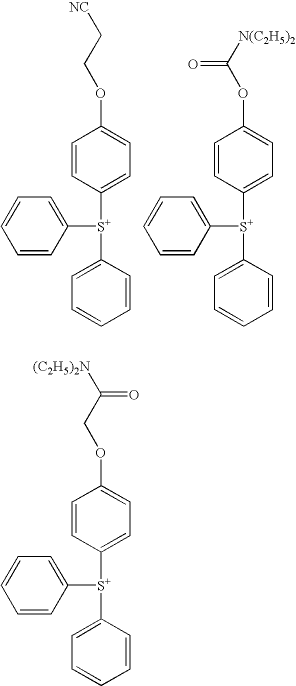

As a specific example of a cation Z⁺ represented by the formula (IIb), cations represented by formulas shown below can be cited.

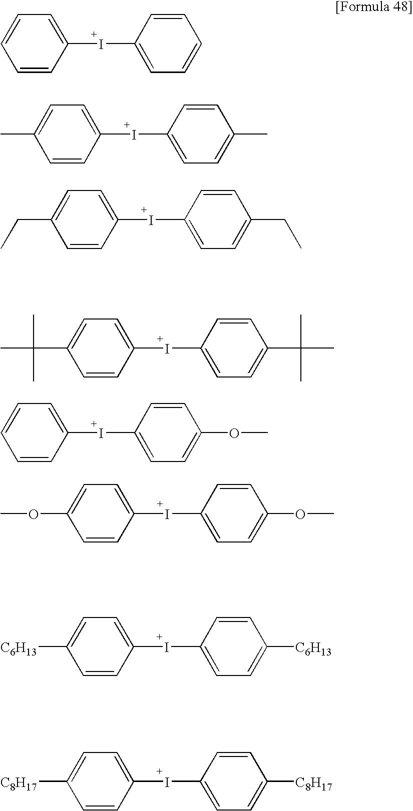

As a specific example of a cation Z⁺ represented by the formula (IIc), cations represented by formulas shown below can be cited.

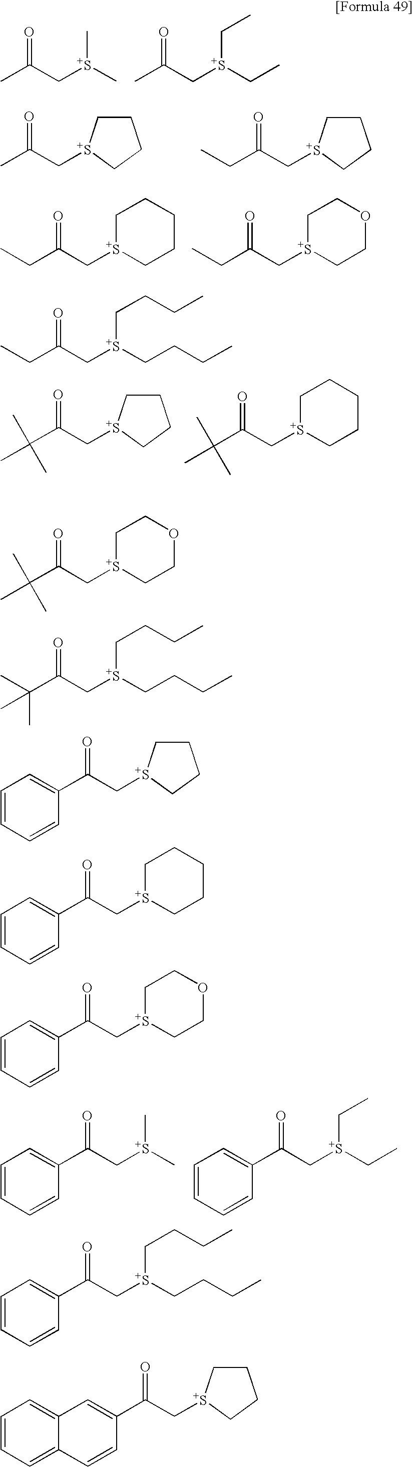

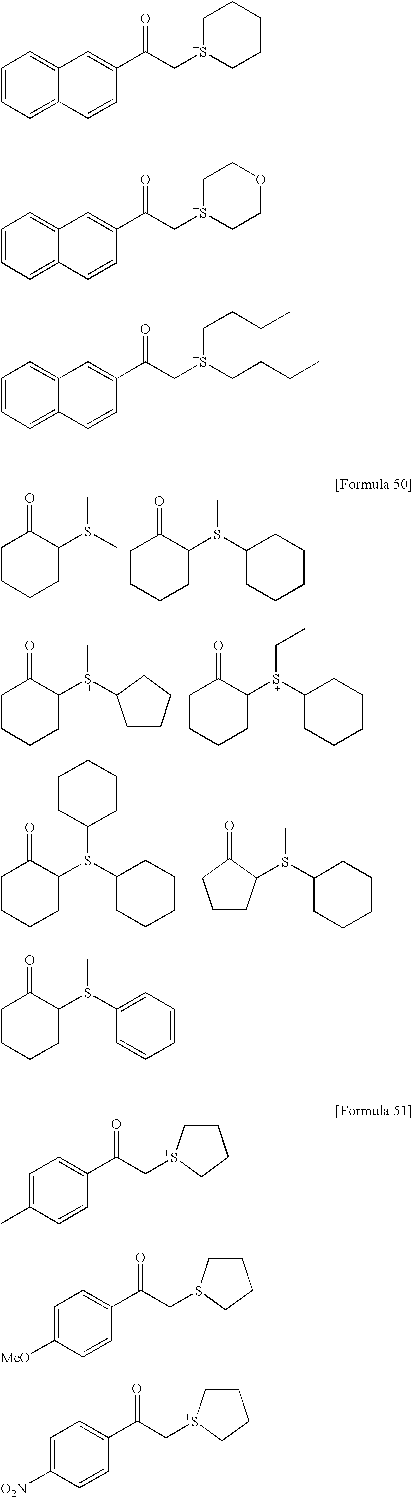

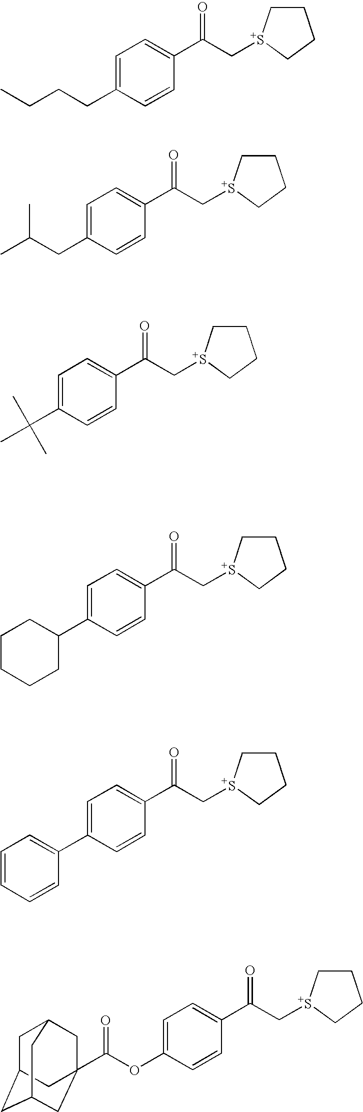

As a specific example of a cation Z⁺ represented by the formula (IId), cations represented by formulas shown below can be cited.

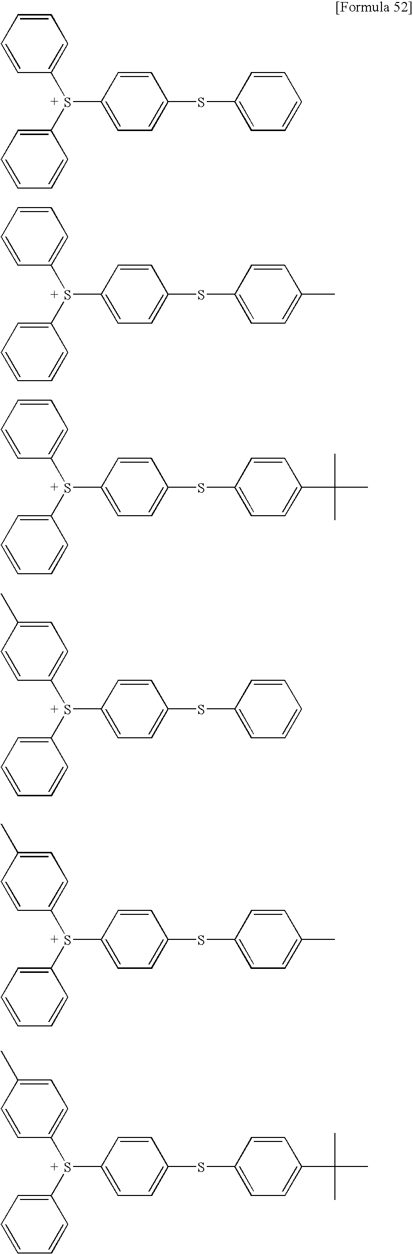

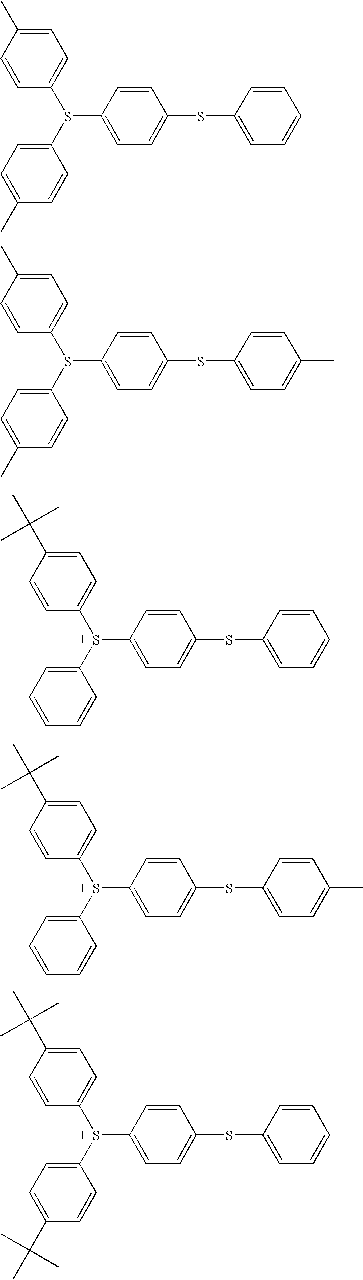

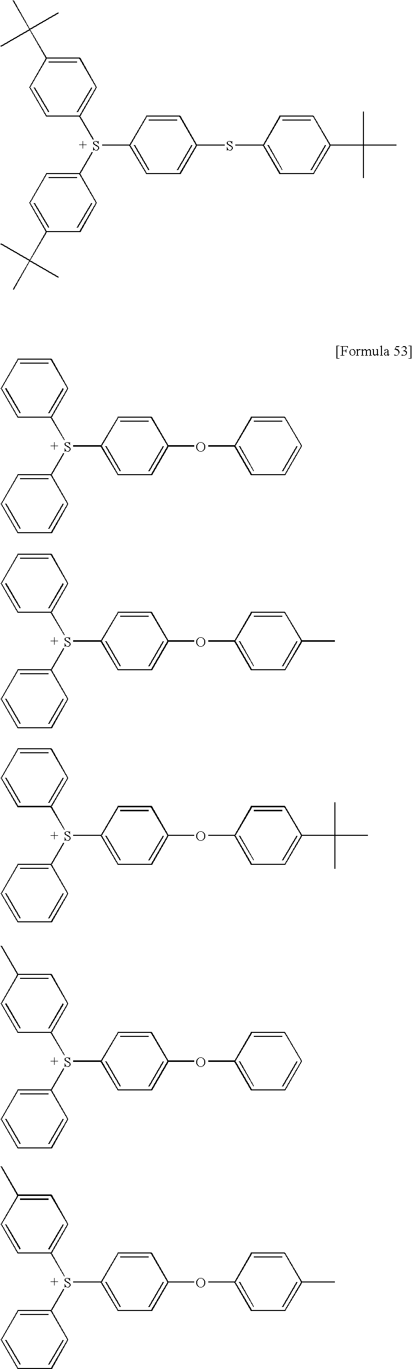

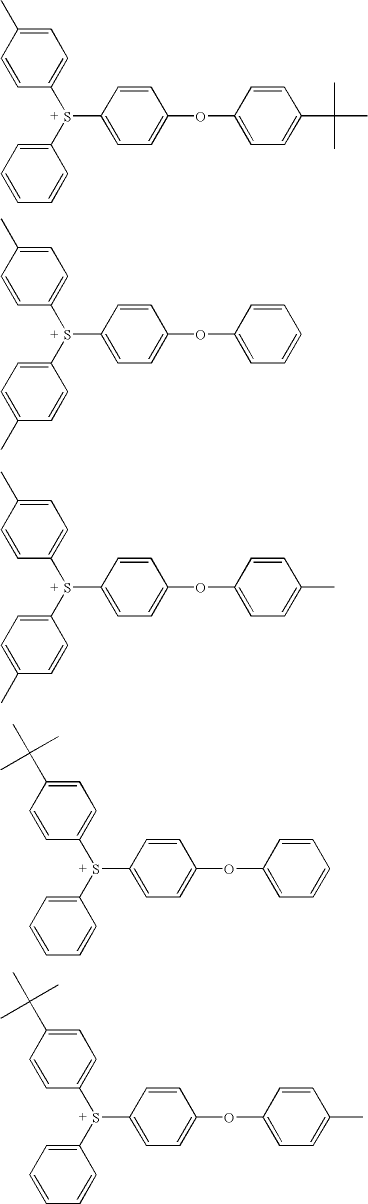

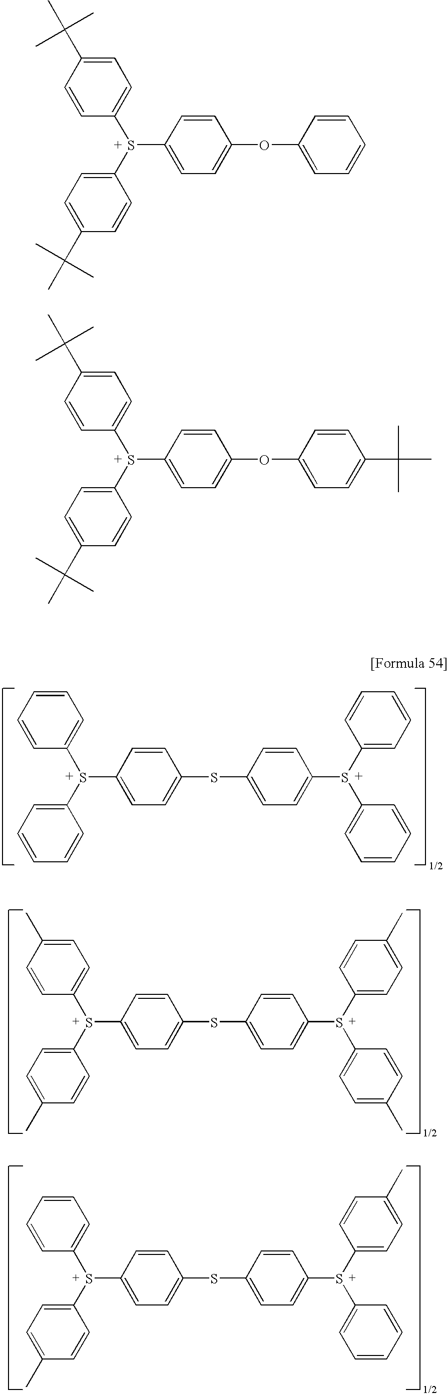

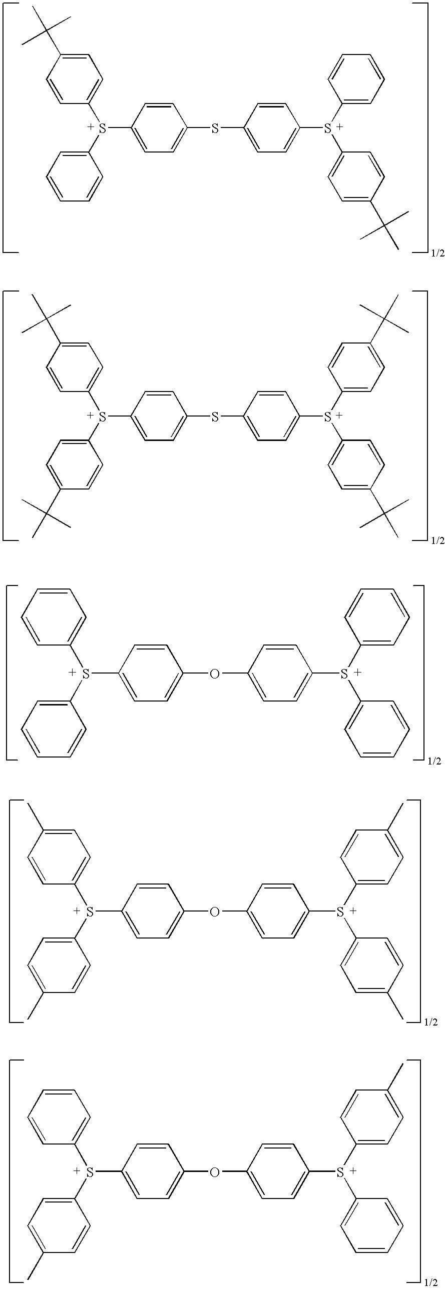

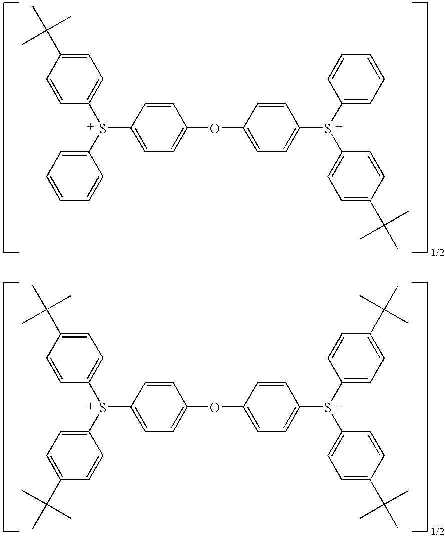

Furthermore, in compounds represented by formulas (I), (III) and (V) to (VII), Z⁺ may be a cation represented by a formula (IV).

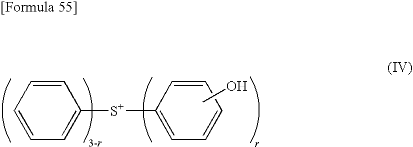

(In the formula, r represents an integer of 1 to 3.)

In the formula (IV), in particular, r is preferable to be 1 to 2 and most preferable to be 2.

A bonding position of a hydroxyl group is not particularly restricted. However, from the viewpoints of easy availability and low cost, a 4 position is preferable.

Specific examples of a cation represented by a formula (IV) include what are represented by formulas shown below.

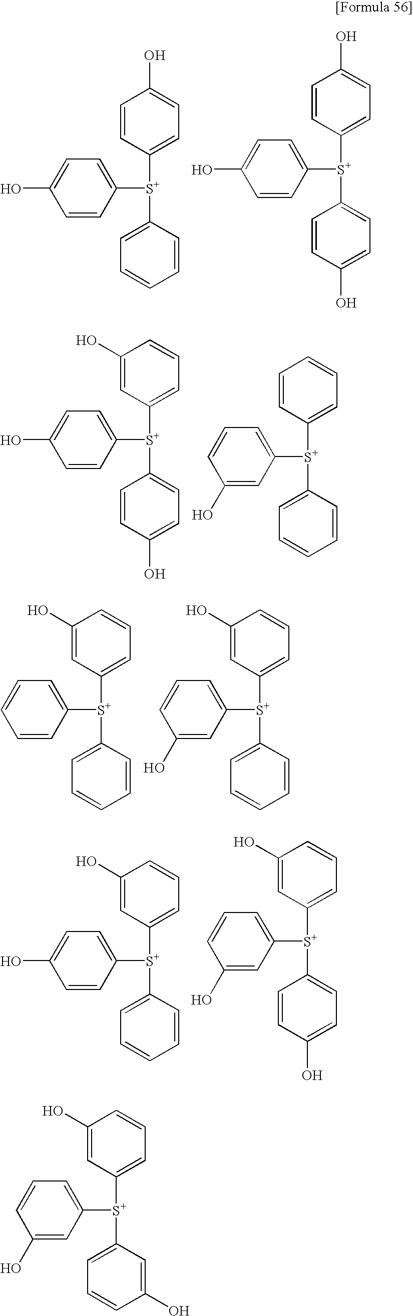

In particular, among compounds represented by a formula (I) or a formula (III) of the present invention, what are represented by formulas (IXa) to (IXe) are preferable because a photoacid generator that imparts a chemical amplification resist composition showing excellent resolution and pattern shape is obtained.

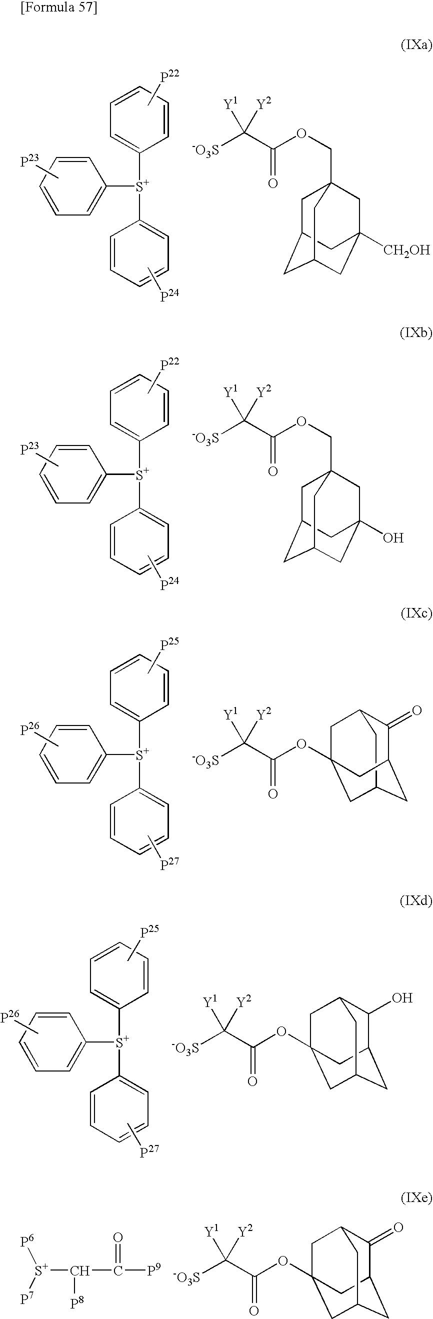

(In the formula, P⁶ to P⁹ and P²² to P²⁴, Y¹ and Y² each are the same as those mentioned above, and P²⁵ to P²⁷, respectively and independently, represent a hydrogen atom or an alkyl group having 1 to 4 carbon atoms.)

Among these, compounds shown below are preferably used because these compounds can be readily produced.

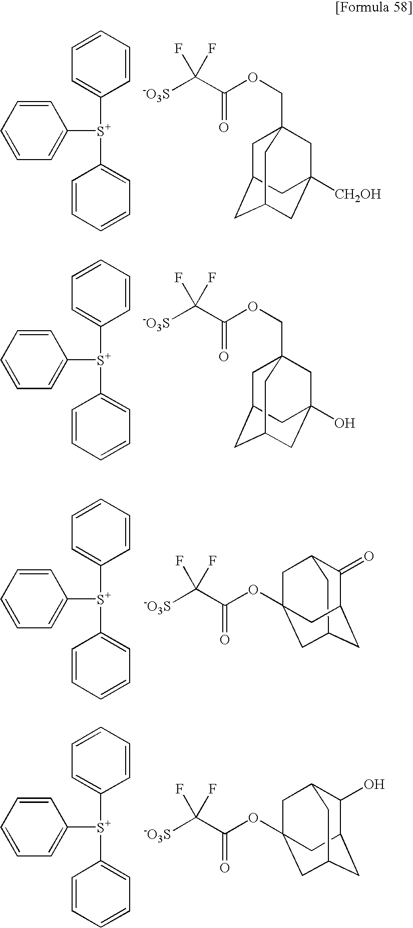

Compounds of formulas (I), (III), and (V) to (VII) can be produced according to a method described in, for example, Japanese Patent Laid-Open No. 2006-257078 and a method in accordance therewith.

In particular, as a method for producing a formula (V) or a formula (VI), for example, a method where a salt represented by a formula (1) or a formula (2) and an onium salt represented by a formula (3), respectively, are reacted by stirring in an inactive solvent such as acetonitrile, water or methanol in the temperature range of about 0° C. to 150° C. and preferably in the temperature range of about 0° C. to 100° C. can be cited.

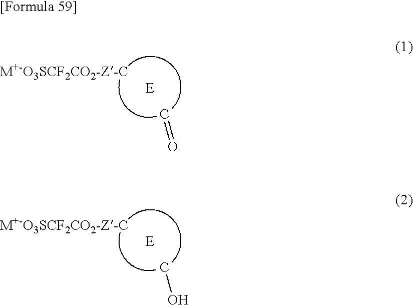

(In the formula, Z′ and E are the same as those mentioned above and M represents Li, Na, K or Ag.)

Z⁺D⁻ (3)

(In the formula, Z⁺ is the same as that mentioned above and D represents F, Cl, Br, I, BF₄, AsF₆, SbF₆, PF₆ or ClO₄)

A usage amount of an onium salt of the formula (3) is usually about 0.5 to 2 mole to 1 mole of a salt represented by a formula (1) or a formula (2). These compounds (V) or (VI) may be taken out by recrystallization or purified by washing with water.

As a method for producing a salt represented by a formula (1) or a formula (2) used in production of a formula (V) or a formula (VI), for example, a method where, in the beginning, alcohol represented by a formula (4) or a formula (5) and carboxylic acid represented by a formula (6), respectively, are esterified is cited.

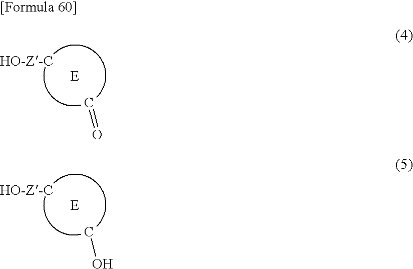

(In the formula (4) and formula (5), E and Z′ are the same as those mentioned above.)

M⁺-O₃SCF₂COOH (6)

(In the formula (6), M is the same as that mentioned above.)

As another method, there is also a method where alcohol represented by a formula (4) or a formula (5) and carboxylic acid represented by a formula (7), respectively, are esterified, followed by hydrolyzing with MOH (M is the same as that mentioned above) to obtain a salt represented by a formula (1) or a formula (2).

FO₂SCF₂COOH (7)

The esterification reaction may be performed usually by stirring in a nonprotonic solvent such as dichloroethane, toluene, ethyl benzene, monochlorobenzene, or acetonitrile in the temperature range of about 20° C. to 200° C. and preferably in the temperature range of about 50° C. to 150° C. In the esterification reaction, usually, as an acid catalyst, an organic acid such as p-toluenesulfonic acid and/or an inorganic acid such as sulfuric acid are added.

Furthermore, it is preferable to perform the esterification while dewatering by the use of a dean stark device because a reaction time is prone to be shortened.

A usage amount of carboxylic acid represented by a formula (6) in the esterification reaction is about 0.2 to 3 mole and preferably about 0.5 to 2 mole to 1 mole of alcohol represented by a formula (4) or a formula (5). An acid catalyst in the esterification reaction may be a catalyst amount or an amount corresponding to a solvent and usually about 0.001 mole to about 5 mole.

Furthermore, there is a method for obtaining a salt represented by a formula (VI) or a formula (2) by reducing a salt represented by a formula (V) or a formula (1).

A reducing reaction like this can be performed in a solvent such as water, alcohol, acetonitrile, N,N-dimethylformaldehyde, digrime, tetrahydrofuran, diethyl ether, dichloromethane, 1,2-dimethoxyethane or benzene, with a reducing agent such as a boron hydride compound such as sodium borohydride, zinc borohydride, tri-sec-butyl lithium borohydride or borane, an aluminum hydride compound such as lithium tri-tert-butoxy aluminum hydride or diisobutyl aluminum hydride, an organic silicon hydride such as Et₃SiH or Ph₂SiH₂, or an organic tin hydride compound such as Bu₃SnH. The reducing reaction can be performed under stirring in the temperature range of about −80° C. to 100° C. and preferably in the temperature range of about −10° C. to 60° C.

Furthermore, as a photoacid generator (A), photoacid generators shown in (A1) and (A2) shown below may be used.

A (A1) is not particularly restricted as long as it has at least one hydroxyl group in a cation and generates an acid by exposure. As such a cation, for example, cations represented by the formula (IV) can be cited.

An anion in the (A1) is not particularly restricted. For example, anions known as an anion of an onium salt acid generator can be appropriately used.

For example, an anion represented by a formula (X-1) and an anion represented by a formula (X-2), (X-3) or (X-4) can be used.

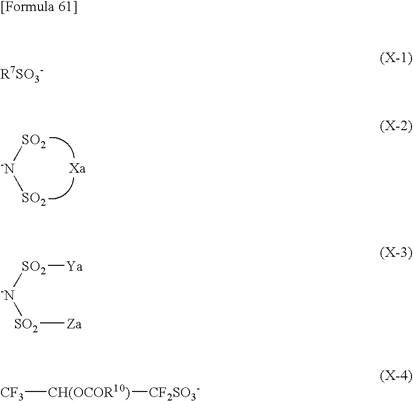

(In the formula, R⁷ represents a straight, branched or cyclic alkyl group or a fluorinated alkyl group. Xa represents an alkylene group having 2 to 6 carbon atoms, in which at least one of hydrogen atoms is replaced by a fluorine atom; and Ya and Za, respectively and independently, represent an alkyl group having 1 to 10 carbon atoms, in which at least one of hydrogen atoms is replaced by a fluorine atom. R¹⁰ represents a substituted or non-substituted straight, branched or cyclic alkyl group having 1 to 20 carbon atoms or a substituted or non-substituted aryl group having 6 to 14 carbon atoms.)

A straight or branched alkyl group has preferably 1 to 10 carbon atoms, more preferably 1 to 8 carbon atoms and most preferably 1 to 4 carbon atoms.

R⁷ as a cyclic alkyl group preferably has 4 to 15 carbon atoms, more preferably 4 to 12 carbon atoms, and more preferably 4 to 10 carbon atoms, 5 to 10 carbon atoms and 6 to 10 carbon atoms.

A fluorinated alkyl group has preferably 1 to 10 carbon atoms, more preferably 1 to 8 carbon atoms and most preferably 1 to 4 carbon atoms.

A rate of fluorination of a fluorinated alkyl group (a ratio of the number of fluorine atoms substituted by fluorination to the total number of hydrogen atoms in an alkyl group before fluorination, the same in the following.) is preferably 10 to 100% and more preferably 50 to 100%. In particular, it is preferable to replace all hydrogen atoms by fluorine atoms because acid strength becomes stronger.

R⁷ is more preferable to be a straight or cyclic alkyl group or a fluorinated alkyl group.

In the formula (X-2), Xa is a straight or branched alkylene group in which at least one hydrogen atom is substituted by a fluorine atom, and the number of carbon atoms of the alkylene group is preferably 2 to 6, more preferably 3 to 5 and most preferably 3.

In the formula (X-3), Ya and Za, respectively and independently, represent a straight or branched alkyl group in which at least one of hydrogen atoms is replaced by a fluorine atom and the number of carbon atoms of the alkyl group is preferably 1 to 10, more preferably 1 to 7 and most preferably 1 to 3.

The number of carbon atoms of the alkylene group of Xa or the number of carbon atoms of the alkyl group of Ya or Za is desirably as small as possible in each of the ranges of the numbers of carbon atoms, from the viewpoint of excellent solubility in a resist solvent.

Furthermore, in an alkylene group of Xa or an alkyl group of Ya or Za, the number of hydrogen atoms replaced by a fluorine atom is desirably as many as possible, because the acid strength becomes stronger and transparency to high energy light of 200 nm or less and an electron beam is improved. A rate of fluorination of the alkylene group or alkyl group is preferably 70 to 100%, more preferably 90 to 100%, and most preferably a perfluoroalkylene group or a perfluoroalkyl group where all hydrogen atoms are substituted by a fluorine atom.

Examples of aryl groups include a phenyl group, a tolyl group, a xylyl group, a cumenyl group, a mesityl group, a naphthyl group, a biphenyl group, an anthryl group and a phenanthryl group.

As a substituent that may substitute an alkyl group and an aryl group, one or more substituents of, for example, a hydroxyl group, an alkyl group having 1 to 12 carbon atoms, an alkoxy group having 1 to 12 carbon atoms, an ester group, a carbonyl group, a cyano group, an amino group, an alkyl-substituted amino group having 1 to 4 carbon atoms and a carbamoyl group can be cited.

As an anion of the (A1), anions in the formula (I) and the like can be cited.

The (A1) where an anion is represented by the formula (X-1) is preferable and, in particular, the (A1) where R⁷ is a fluorinated alkyl group is preferable.

For example, as the (A1), the photoacid generators shown below are illustrated.

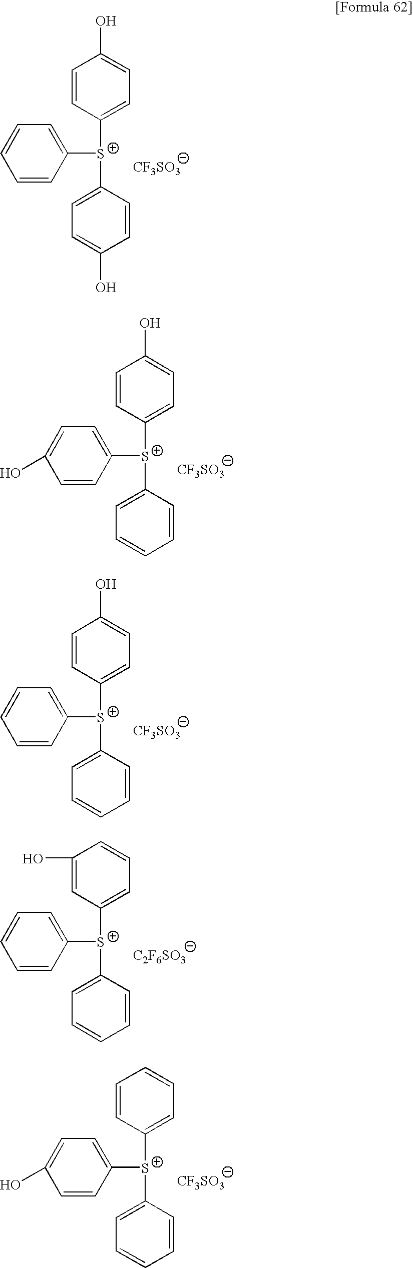

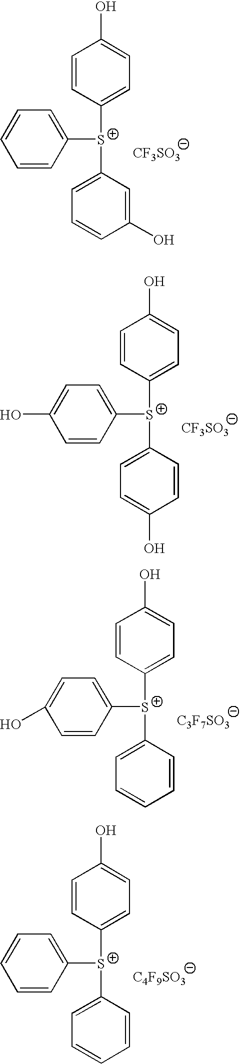

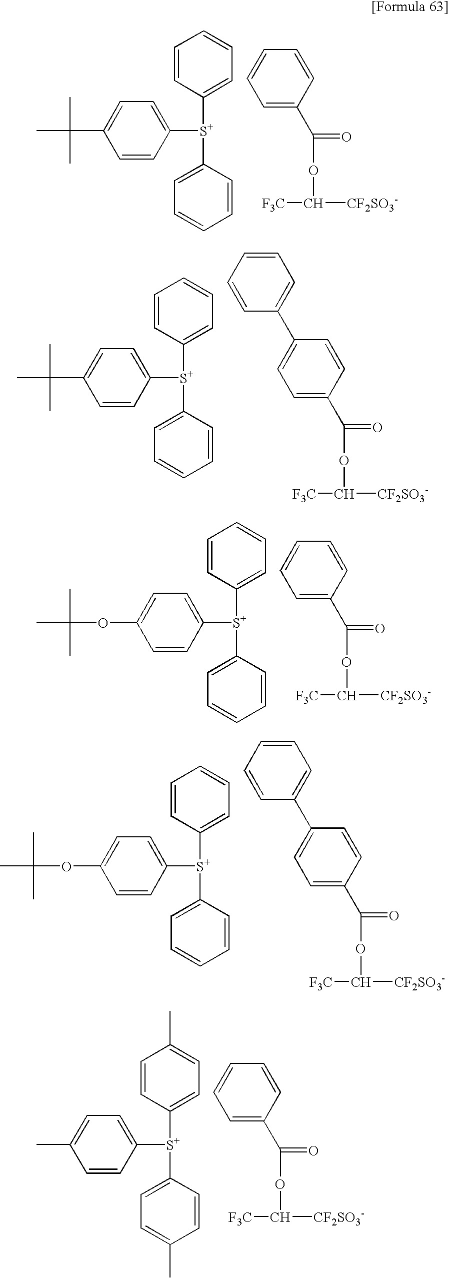

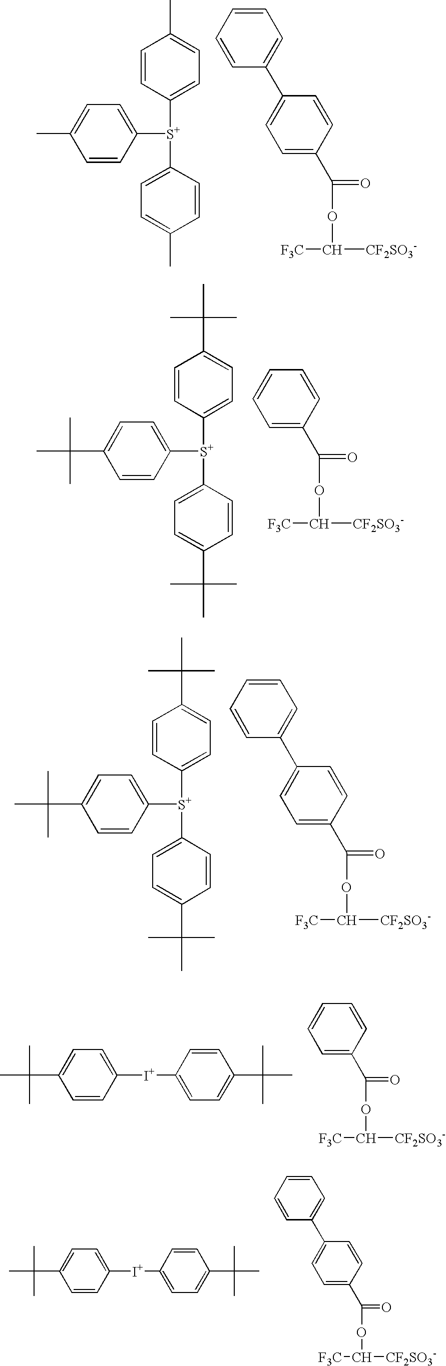

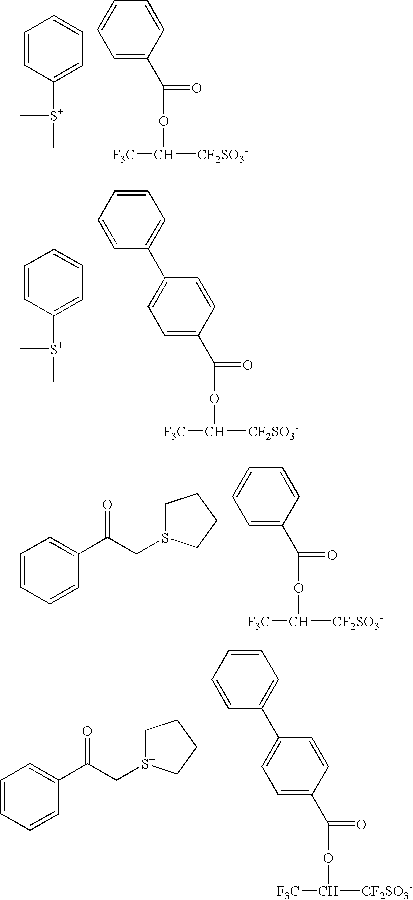

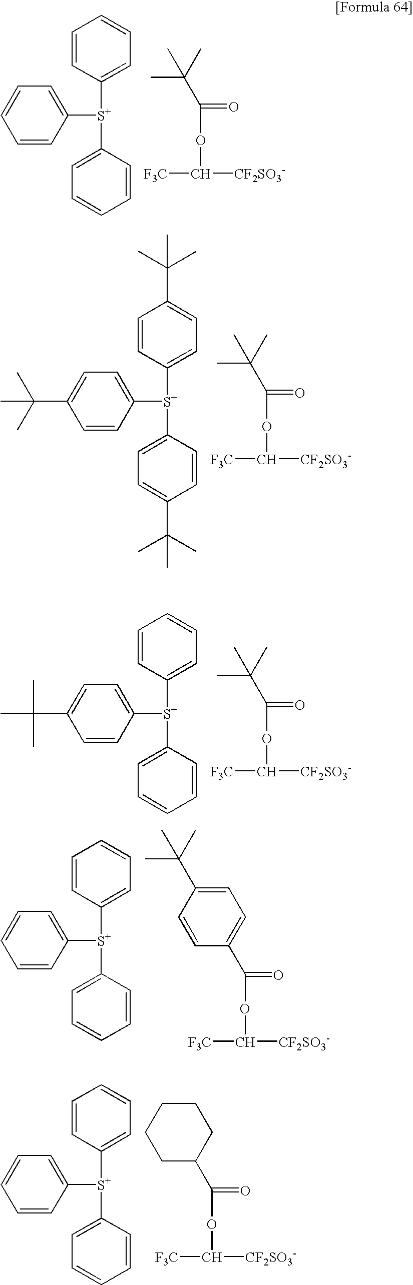

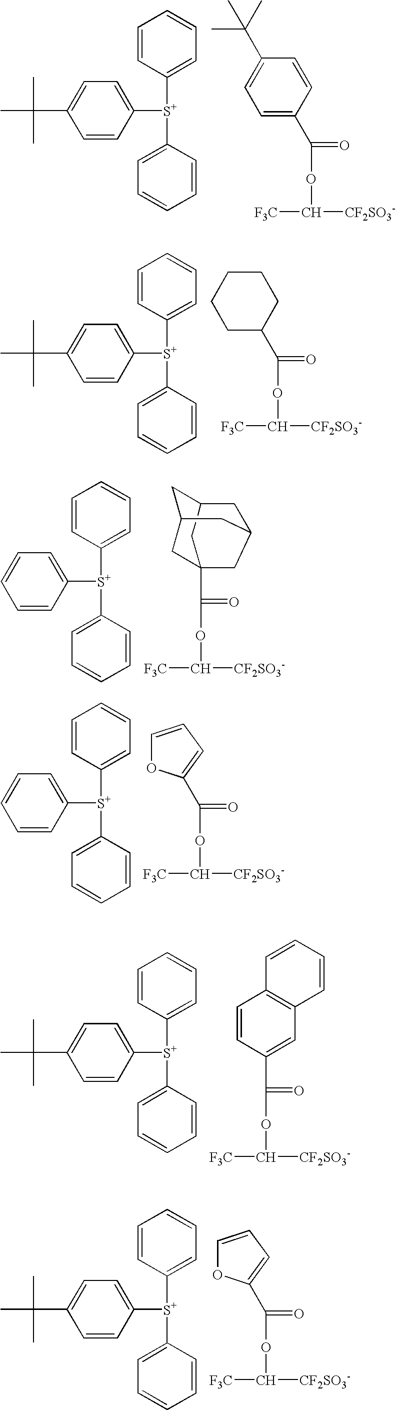

The (A2) is not particularly restricted as long as a cation does not have a hydroxyl group, and the acid generators that have been proposed as an acid generator for use in a chemical amplification resist can be used.

As such acid generators, various kinds of acid generators, such as an onium salt acid generator such as an iodonium salt or a sulfonium salt, an oxime sulfonate acid generator, a diazomethane acid generator such as bisalkyl or bisarylsulfonyl diazomethanes, and poly(bis-sulfonyl)diazomethanes, a nitrobenzilsulfonate acid generator, an iminosulfonate acid generator and a disulfone acid generator can be cited.

As the onium salt acid generator, acid generators represented by, for example, a formula (XI) can be preferably used.

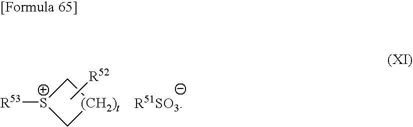

(In the formula (XI), R⁵¹ represents a straight, branched or cyclic alkyl group, or a straight, branched or cyclic fluorinated alkyl group; R⁵² represents a hydrogen atom, a hydroxyl group, a halogen atom, a straight or branched alkyl group, a straight or branched halogenated alkyl group, or a straight or branched alkoxy group; R⁵³ represents an optionally substituted aryl group; and t represents an integer of 1 to 3.)

In the formula (XI), for R⁵¹, the number of carbon atoms and the rate of fluorination the same as those of the substituent R⁷ can be illustrated.

R⁵¹ is most preferable to be a straight alkyl group or a fluorinated alkyl group.

Examples of the halogen atom include a fluorine atom, a bromine atom, a chlorine atom and an iodine atom and a fluorine atom is preferable.

In R⁵², an alkyl group is a straight chain or a branched chain and the number of carbon atoms thereof is preferably 1 to 5, particularly preferably 1 to 4 and more preferably 1 to 3.

In R⁵², a halogenated alkyl group is a group obtained by partially or completely substituting hydrogen atoms in the alkyl group with a halogen atom. The alkyl group and the halogen atom as a substituent here are the same as those mentioned above. In the halogenated alkyl group, it is preferable to substitute 50 to 100% of a total number of hydrogen atoms with a halogen atom and more preferable to substitute all hydrogen atoms.

In R⁵², an alkoxy group is a straight chain or a branched chain, and the number of carbon atoms thereof is preferably 1 to 5, particularly preferably 1 to 4 and further preferably 1 to 3.

R⁵² is preferable to be a hydrogen atom among these.

R⁵³ is preferable to be a phenyl group from the viewpoint of absorbance of exposure light such as an ArF excimer laser.

Examples of substituents in an aryl group include a hydroxyl group, a lower alkyl group (straight chain or branched chain preferably having 1 to 6 carbon atoms and more preferably 1 to 4 carbon atoms, and a methyl group being particularly preferable) and a lower alkoxy group.

An aryl group of R⁵³ is more preferable not to have a substituent.

t is an integer of 1 to 3, preferably 2 or 3 and particularly preferably 3.

Examples of the acid generators represented by a formula (XI) include the compounds shown below.

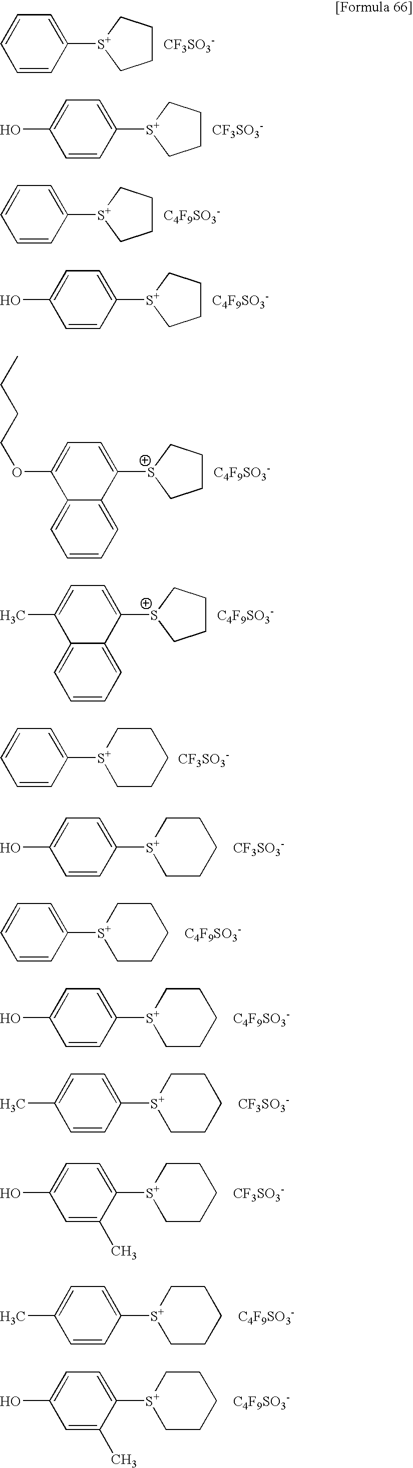

Furthermore, as an onium salt acid generator, acid generators represented by, for example, formulas (XII) and (XIII) may be used.

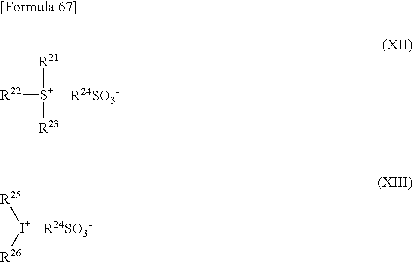

(In the formulas (XII) and (XIII), R²¹ to R²³ and R²⁵ to R²⁶, respectively and independently, represent an aryl group or an alkyl group; R²⁴ represents a straight, branched or cyclic alkyl group or a fluorinated alkyl group; at least one of R²¹ to R²³ represents an aryl group and at least one of R²⁵ to R²⁶ represents an aryl group.)

Two or more of R²¹ to R²³ are preferable to be an aryl group and all of R²¹ to R²³ are most preferable to be an aryl group.

As an aryl group of R²¹ to R²³, for example, an aryl group having 6 to 20 carbon atoms is cited, and in the aryl group, hydrogen atoms thereof may be partially or completely substituted by an alkyl group, an alkoxy group or a halogen atom. The aryl group is preferably an aryl group having 6 to 10 carbon atoms because it can be cheaply synthesized. Specifically, a phenyl group and a naphthyl group are cited.

As an alkyl group that may replace a hydrogen atom of an aryl group, an alkyl group having 1 to 5 carbon atoms is preferable, and a methyl group, an ethyl group, a propyl group, an n-butyl group, and a tert-butyl group are most preferable.

An alkoxy group that may replace a hydrogen atom of an aryl group is preferably an alkoxy group having 1 to 5 carbon atoms, and a methoxy group and an ethoxy group are most preferable.

A halogen atom that may replace a hydrogen atom of an aryl group is preferable to be a fluorine atom.

As an alkyl group of R²¹ to R²³, for example, a straight, branched or cyclic alkyl group having 1 to 10 carbon atoms is cited. From the viewpoint of excellent resolution, the number of carbon atoms is preferable to be 1 to 5. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group and a decanyl group and, among these, a methyl group is preferably cited because it is excellent in resolution and can be cheaply synthesized.

Among these, R²¹ to R²³, respectively, are most preferable to be a phenyl group or a naphthyl group.

As R²⁴, the same as the R⁷ can be illustrated.

Preferably, all of the R²⁵ to R²⁶ are an aryl group.

Among these, most preferably, all of the R²⁵ to R²⁶ are a phenyl group.

Specific examples of the onium salt acid generators represented by formulas (XII) and (XIII) include trifluoromethanesulfonate or nonafluorobutanesulfonate of diphenyliodonium, trifluoromethanesulfonate or nonafluorobutanesulfonate of bis(4-tert-butylphenyl)iodonium, trifluoromethanesulfonate of triphenylsulfonium, heptafluoropropanesulfonate thereof or nonafluorobutanesulfonate thereof,

trifluoromethanesulfonate of tri(4-methylphenyl)sulfonium, heptafluoropropanesulfonate thereof or nonafluorobutanesulfonate thereof,

trifluoromethanesulfonate of dimethyl(4-hydroxynaphthyl)sulfonium, heptafluoropropane sulfonate thereof or nonafluorobutanesulfonate thereof,

trifluoromethanesulfonate of monophenyldimethylsulfonium, heptafluoropropane sulfonate thereof or nonafluorobutanesulfonate thereof,

trifluoromethanesulfonate of diphenylmonomethylsulfonium, heptafluoropropanesulfonate thereof or nonafluorobutanesulfonate thereof,

trifluoromethanesulfonate of (4-methylphenyl)diphenylsulfonium, heptafluoropropanesulfonate thereof or nonafluorobutanesulfonate thereof,

trifluoromethanesulfonate of (4-methoxyphenyl)diphenylsulfonium, heptafluoropropane sulfonate thereof or nonafluorobutanesulfonate thereof,

trifluoromethanesulfonate of tri(4-tert-butyl)phenylsulfonium, heptafluoropropane sulfonate thereof or nonafluorobutanesulfonate thereof,

trifluoromethanesulfonate of diphenyl(1-(4-methoxy)naphthyl)sulfonium, heptafluoropropanesulfonate thereof or nonafluorobutanesulfonate thereof,

trifluoromethanesulfonate of di(1-naphthyl)phenylsulfonium, heptafluoropropane sulfonate thereof or nonafluorobutanesulfonate thereof,

perfluoroocranesulfonate of 1-(4-n-butoxynaphthyl)tetrahydrothiophenium, 2-bicyclo[2.2.1]hepto-2-yl-1,1,2,2-tetrafluoroethanesulfonate thereof, and

N-nonafluorobutanesulfonyloxybicyclo[2.2.1]hepto-5-ene-2,3-dicarboxyimide.

Furthermore, onium salts where an anion of each of the onium salts is replaced by methanesulfonate, n-propanesulfonate, n-butanesulfonate or n-octanesulfonate may be used.

Furthermore, in a formula (XII) or (XIII), an onium salt generator obtained by replacing an anion by an anion represented by formulas (X-1) to (X-3) can be used as well.

Moreover, compounds shown below may be used.

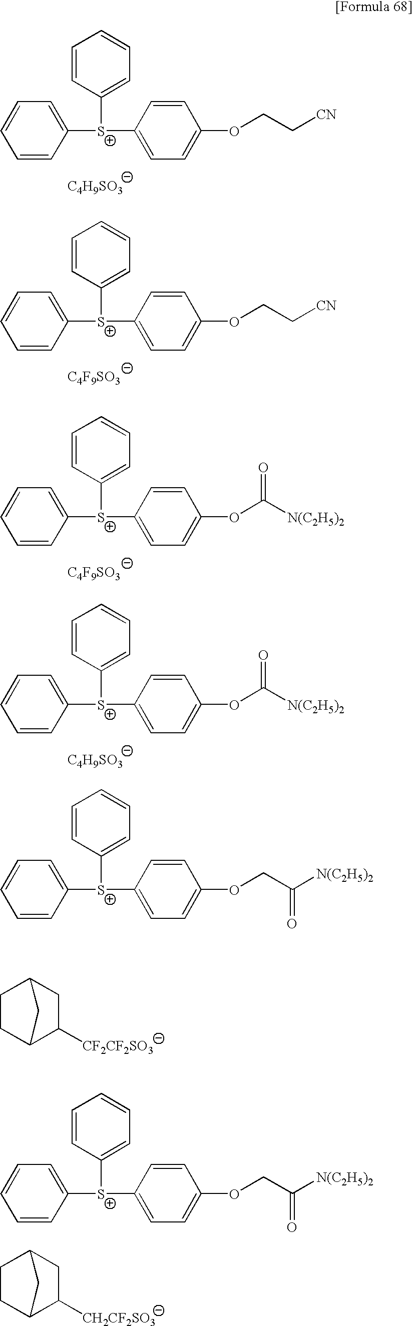

An oxime sulfonate acid generator is a compound having at least one group represented by a formula (XIV), and has a feature of generating acid by irradiation of radiation. Such oxime sulfonate acid generators are widely used for chemically amplified resist compositions and can be appropriately selected and used.

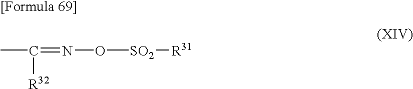

(In the formula, each of R³¹ and R³², respectively and independently, represents an organic group.)

The organic groups of R³¹ and R³² are a group containing a carbon atom and may include an atom other than a carbon atom (for example, a hydrogen atom, an oxygen atom, a nitrogen atom, a sulfur atom or a halogen atom).

As the organic group for R³¹, a straight, branched, or cyclic alkyl group or aryl group is preferable. The alkyl group or the aryl group may have a substituent. The substituent is not particularly restricted, and examples thereof include a fluorine atom and a straight, branched or cyclic alkyl group having 1 to 6 carbon atoms.

The alkyl group preferably has 1 to 20 carbon atoms, more preferably 1 to 10 carbon atoms, still more preferably 1 to 8 carbon atoms, particularly preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly preferable. The “partially halogenated alkyl group” refers to an alkyl group in which part of the hydrogen atoms is substituted by a halogen atom, and the “completely halogenated alkyl group” refers to an alkyl group in which all of the hydrogen atoms are substituted by a halogen atom. Examples of the halogen atom include a fluorine atom, a chlorine atom, a bromine atom and an iodine atom, and a fluorine atom is particularly preferable. That is, the halogenated alkyl group is preferable to be a fluorinated alkyl group.

The aryl group preferably has 4 to 20 carbon atoms, more preferably 4 to 10 carbon atoms, and most preferably 6 to 10 carbon atoms. As the aryl group, a partially or completely halogenated aryl group is particularly preferable.

As R³¹, an alkyl group having 1 to 4 carbon atoms and no substituent or a fluorinated alkyl group having 1 to 4 carbon atoms is particularly preferable.

As an organic group for R³², a straight, branched or cyclic alkyl group, an aryl group, or a cyano group is preferable. As the alkyl group and the aryl group of R³², the alkyl group and the aryl group the same as those cited for R³¹ can be cited.

As R³², a cyano group, an alkyl group having 1 to 8 carbon atoms and no substituent or a fluorinated alkyl group having 1 to 8 carbon atoms is particularly preferable.

More preferable examples of the oxime sulfonate acid generator include the compounds represented by a formula (XVII) or (XVIII).

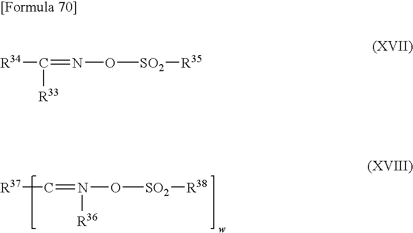

In the formula (XVII), R³³ represents a cyano group, an alkyl group having no substituent or a halogenated alkyl group. R³⁴ represents an aryl group. R³⁵ represents an alkyl group having no substituent or a halogenated alkyl group.

In the formula (XVIII), R³⁶ represents a cyano group, an alkyl group having no substituent or a halogenated alkyl group. R³⁷ represents a divalent or trivalent aromatic hydrocarbon group. R³⁸ represents an alkyl group having no substituent or a halogenated alkyl group. w represents 2 or 3 and preferably 2.

In the formula (XVII), an alkyl group having no substituent or a halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group in R³³ is fluorinated preferably 50% or more of the hydrogen atoms thereof, more preferably 70% or more, and still more preferably 90% or more. A completely fluorinated alkyl group where hydrogen atoms are 100% substituted by fluorine atoms is most preferable because the strength of the generated acid is heightened.

Examples of the aryl group of R³⁴ include groups obtained by removing one hydrogen atom from an aromatic hydrocarbon ring such as a phenyl group, a biphenyl group, a fluorenyl group, a naphthyl group, an anthracyl group, or a phenanthryl group; and heteroaryl groups obtained by partially substituting carbon atoms constituting the ring of the groups with a hetero atom such as an oxygen atom, a sulfur atom, or a nitrogen atom. Among these, a fluorenyl group is preferable.

The aryl group of R³⁴ may have a substituent such as an alkyl group having 1 to 10 carbon atoms, a halogenated alkyl group, or an alkoxy group. The alkyl group or halogenated alkyl group in the substituent preferably has 1 to 8 carbon atoms, and more preferably 1 to 4 carbon atoms. Furthermore, the halogenated alkyl group is preferably a fluorinated alkyl group.

As the alkyl group having no substituent or the halogenated alkyl group of R³⁵, the same as those cited for R³³ are illustrated.

In the formula (XVIII), as an alkyl group having no substituent or a halogenated alkyl group of R³⁶, the same as those for R³³ are cited.

As a divalent or trivalent aromatic hydrocarbon group of R³⁷, a group obtained by further removing one or two hydrogen atoms from an aryl group of the R³⁴ can be cited.

As an alkyl group having no substituent or a halogenated alkyl group of R³⁸, the same as those cited for the R³⁵ are cited.

Specific examples of an oxime sulfonate acid generator include the compounds disclosed in a paragraph [0122] of Japanese Patent Laid-Open No. 2007-286161, the oxime sulfonate acid generators disclosed in [Formula 18] to [Formula 19] of paragraphs [0012] to [0014] in Japanese Patent Laid-Open No. 9-208554 and the oxime sulfonate acid generators disclosed in Examples 1 to 40 on pages 65 to 85 of WO 2004/074242A2.

Furthermore, as preferable examples, the following can be used.

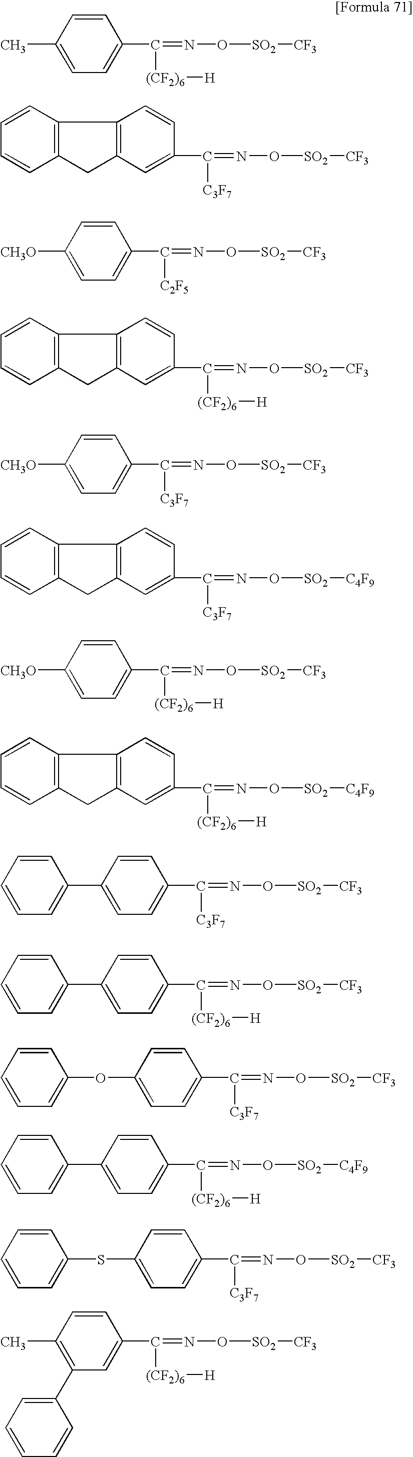

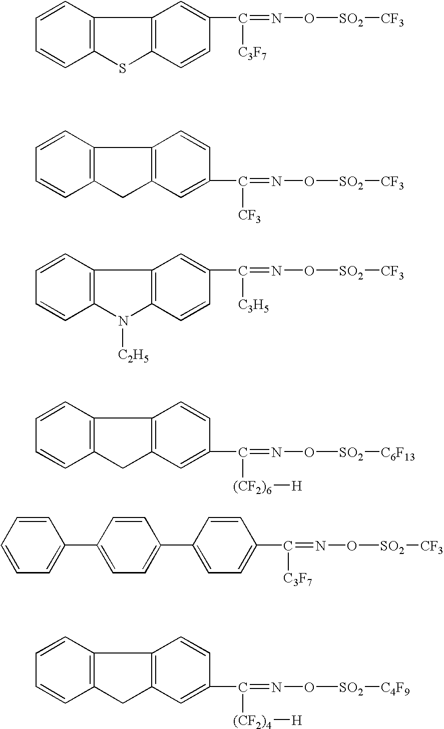

Among the diazomethane acid generators, specific examples of bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane and bis(2,4-dimethylphenylsulfonyl)diazomethane.

Furthermore, the diazomethane acid generators disclosed in Japanese Patent Laid-Open No. 11-035551, Japanese Patent Laid-Open No. 11-035552 and Japanese Patent Laid-Open No. 11-035573 can also be preferably used.

Examples of poly(bis-sulfonyl)diazomethanes include those disclosed in Japanese Patent Laid-Open No. 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane.

Among those mentioned above, an onium salt in which, as an (A2) component, a fluorinated alkyl sulfonic acid ion is an anion is preferably used.

In the present invention, photoacid generators may be used alone or in a combination of two or more kinds thereof.

In the resist composition used in the present invention, it is preferable that, based on the total solid content, the resin (B) is contained in the range of about 70 to 99.9% by weight and the photoacid generator is contained in the range of about 0.1 to 30% by weight, about 0.1 to 20% by weight and about 1 to 10% by weight. When the range is adopted, a pattern can be sufficiently formed, a homogeneous solution is obtained, and storage stability becomes excellent.

A crosslinking agent (C) is not particularly restricted and can be used by appropriately selecting from crosslinking agents used in the art.

Specific examples thereof include compounds obtained by reacting formaldehyde or formaldehyde and lower alcohol with an amino group-containing compound such as acetoguanamine, benzoguanamine, urea, ethylene urea, propylene urea, or glycoluril to replace a hydrogen atom of the amino group by a hydroxymethyl group or a lower alkoxymethyl group; and aliphatic hydrocarbons having two or more ethylene oxide moieties. Among these, in particular, a crosslinking agent that uses urea is called a urea crosslinking agent, a crosslinking agent that uses alkylene urea such as ethylene urea and propylene urea is called an alkylene urea crosslinking agent and a crosslinking agent that uses glycoluril is called a glycoluril crosslinking agent. Among these, a urea crosslinking agent, an alkylene urea crosslinking agent and a glycoluril crosslinking agent are preferable and a glycoluril crosslinking agent is more preferable.

Examples of the urea crosslinking agent include a compound obtained by reacting urea and formaldehyde, followed by substituting a hydrogen atom of an amino group with a hydroxymethyl group; and a compound obtained by reacting urea, formaldehyde and lower alcohol, followed by substituting a hydrogen atom of an amino group with a lower alkoxymethyl group. Specific examples thereof include bismethoxymethyl urea, bisethoxymethyl urea, bispropoxymethyl urea and bisbutoxymethyl urea. Among these, bismethoxymethyl urea is preferable.

As the alkylene urea crosslinking agent, the compounds represented by a formula (XIX) can be cited.

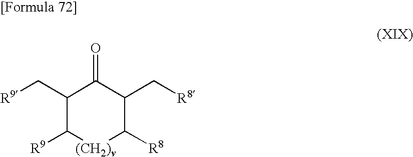

(In the formula (XIX), R⁸ and R⁹, respectively and independently, represent a hydroxyl group or a lower alkoxy group. R^{8′} and R^{9′}, respectively and independently, represent a hydrogen atom, a hydroxyl group or a lower alkoxy group. v is an integer of 0 to 2.)

When R⁸ and R⁹ each are a lower alkoxy group, the alkoxy group preferably has 1 to 4 carbon atoms and may be either a straight chain or a branched chain. Furthermore, R⁸ and R⁹ may be the same with each other or different from each other. R⁸ and R⁹ are more preferable to be the same with each other.

When R^{8′} and R^{9′} each are a lower alkoxy group, the alkoxy group preferably has 1 to 4 carbon atoms and may be either a straight chain or a branched chain. Furthermore, R^{8′} and R^{9′} may be the same with each other or different from each other. R^{8′} and R^{9′} are more preferable to be the same with each other.

v is an integer of 0 to 2 and preferably 0 or 1.

As the alkylene urea crosslinking agent, a compound where v is zero (ethylene urea crosslinking agent) and/or a compound where v is 1 (propylene urea crosslinking agent) are particularly preferable.

A compound represented by a formula (XIII) can be obtained by condensating alkylene urea and formalin, or by reacting the product thereof with lower alcohol.

Specific examples of the alkylene urea crosslinking agent include: urea crosslinking agents including mono- and/or dihydroxymethylated ethylene urea, mono- and/or dimethoxymethylated ethylene urea, mono- and/or diethoxymethylated ethylene urea, mono- and/or dipropoxymethylated ethylene urea and mono- and/or dibutoxymethylated ethylene urea; propylene urea crosslinking agents including mono- and/or dihydroxymethylated propylene urea, mono- and/or dimethoxymethylated propylene urea, mono- and/or diethoxymethylated propylene urea, mono- and/or dipropoxymethylated propylene urea and mono- and/or dibutoxymethylated propylene urea; 1,3-di(methoxymethyl)-4,5-dihydroxy-2-imidazolidinone and 1,3-di(methoxymethyl)-4,5-dimethoxy-2-imidazolydinone.

As the glycoluril crosslinking agent, a glycoluril derivative of which N positions are substituted by one or both of a hydroxyalkyl group and an alkoxyalkyl group having 1 to 4 carbon atoms is cited. The glycoluril derivative can be obtained by condensating glycoluril and formalin or by reacting a product thereof and lower alcohol.

Examples of the glycoluril crosslinking agent include mono-, di-, tri- and/or tetra-hydroxymethylated glycoluril, mono-, di-, tri- and/or tetra-methoxymethylated glycoluril, mono-, di-, tri- and/or tetra-ethoxymethylated glycoluril, mono-, di-, tri- and/or tetra-propoxymethylated glycoluril, and mono-, di-, tri- and/or tetra-butoxymethylated glycoluril.

The crosslinking agents (C) may be used alone or in a combination of two or more kinds thereof.

The content of the crosslinking agent (C) is, based on 100 parts by weight of the resin (B) component, preferably 0.5 to 35 parts by weight, more preferably 0.5 to 30 parts by weight and most preferably 1 to 25 parts by weight. When the range is adopted, crosslinking is sufficiently forwarded and thereby an excellent resist pattern can be obtained. Furthermore, storage stability of the resist coating solution becomes excellent and thereby time-lapse deterioration of the sensitivity can be suppressed.

Furthermore, a resist composition used in the present invention is preferable to contain a thermal acid generator (D). Here, the thermal acid generator means a compound that is stable at a temperature lower than a hard bake temperature (described later) of a resist where the thermal acid generator is used and is decomposed at a temperature equal to or higher than the hard bake temperature to generate an acid. On the other hand, a photoacid generator is a compound that is stable at a pre-bake temperature (described later) and a post-exposure bake temperature (described later) and generates an acid by exposure. The distinction therebetween may depend on a usage mode of the present invention. That is, in some cases, in the same resist, an acid generator works, depending on a process temperature applied, as both of the thermal acid generator and the photoacid generator or only as a photoacid generator. Furthermore, in some cases, an acid generator does not work as a thermal acid generator in some resists but works as a thermal acid generator in other resists.

Examples of thermal acid generator include various well-known thermal acid generators such as benzoin tosylate, nitrobenzyl tosylate (particularly, 4-nitrobenzyl tosylate), and alkyl esters of other organic sulfonic acid.

The content of the thermal acid generator (D) is, based on 100 parts by weight of the resin (B), preferably 0.5 to 30 parts by weight, more preferably 0.5 to 15 parts by weight and most preferably 1 to 10 parts by weight.

The resist composition used in the present invention preferably contains a basic compound, preferably, a basic nitrogen-containing compound, and, particularly, amine or an ammonium salt. When a basic compound is added, the basic compound works as a quencher to be able to inhibit performance from deteriorating owing to deactivation of an acid accompanied by a post-exposure time delay. When a basic compound is used, the basic compound is preferably contained in the range of about 0.01 to 1% by weight on the basis of the total solid content of the resist composition.

As an example of such basic compound, the basic compounds represented by the respective formulas shown below can be cited.

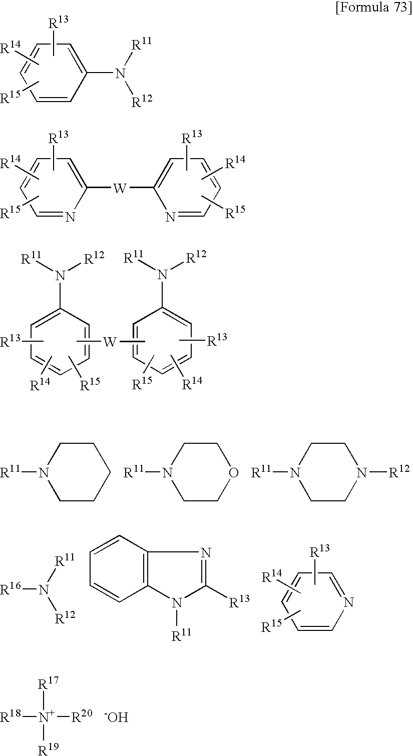

In the formula, R¹¹ and R¹², respectively and independently, represent a hydrogen atom, an alkyl group, a cycloalkyl group or an aryl group. The alkyl group preferably has about 1 to 6 carbon atoms, the cycloalkyl group preferably has about 5 to 10 carbon atoms and the aryl group preferably has about 6 to 10 carbon atoms.

R¹³, R¹⁴ and R¹⁵, respectively and independently, represent a hydrogen atom, an alkyl group, a cycloalkyl group, an aryl group or an alkoxy group. As the alkyl group, cycloalkyl group and aryl group, groups the same as those of R¹¹ and R¹² are illustrated. The alkoxy group preferably has 1 to 6 carbon atoms.

R¹⁶ represents an alkyl group or a cycloalkyl group. As the alkyl group and cycloalkyl group, groups the same as those of R¹¹ and R¹² are illustrated.

R¹⁷, R¹⁸, R¹⁹ and R²⁰, respectively and independently, represent an alkyl group, a cycloalkyl group or an aryl group. As the alkyl group, cycloalkyl group and aryl group, groups the same as those of R¹¹, R¹² and R¹⁷ are illustrated.

Furthermore, at least one of hydrogen atoms on the alkyl group, cycloalkyl group or alkoxy group, respectively and independently, may be substituted by a hydroxyl group, an amino group or an alkoxy group having about 1 to 6 carbon atoms. At least one of hydrogen atoms on the amino group may be substituted by an alkyl group having 1 to 4 carbon atoms.

W represents an alkylene group, a carbonyl group, an imino group, a sulfide group or a disulfide group. The alkylene group preferably has about 2 to 6 carbon atoms.

In R¹¹ to R²⁰, what can take both of the straight chain structure and the branched chain structure may take any one thereof.

Specific examples of such compounds include the compounds illustrated in Japanese Patent Laid-Open No. 2006-257078.

A hindered amine compound having a piperidine skeleton, which is disclosed in Japanese Patent Laid-Open No. 11-52575, can be used as a quencher.

The resist composition used in the present invention, as required, may further contain various additives known in the art, such as a sensitizer, a dissolution inhibitor, other resin, a surfactant, a stabilizer or a dye.

A resist composition used in the present invention is usually used as a resist solution composition in a state where the respective components mentioned above are dissolved in a solvent.

Any one of the solvents may be used as long as it can dissolve the respective components, has an appropriate drying speed and can form a uniform and homogeneous coated film after evaporation of the solvent. Usually, a solvent generally used in the art is suitable.

Examples of the solvent include: glycol ether esters such as ethyl cellosolve acetate, methyl cellosolve acetate and propylene glycol monomethyl ether acetate; glycol ethers such as propylene glycol monomethyl ether; esters such as ethyl lactate, butyl acetate, amyl acetate and ethyl pyruvate; ketones such as acetone, methyl isobutyl ketone, 2-heptanone and cyclohexanone; and cyclic esters such as γ-butyrolactone. These solvents may be used alone or in a combination of two kinds or more thereof.

### EXAMPLES

In the next place, the present invention will be further specifically described with reference to Examples. In Examples, % and parts that represent the content or a usage amount are based on the weight unless clearly stated. Furthermore, a weight average molecular weight is a value obtained by gel permeation chromatography in terms of standard polystyrene. Measurement conditions are as shown below.

Column: TSKgel Multipore H_{XL}-M three columns+guard column (produced by Tosoh Corporation)

Eluent: tetrahydrofuran

Flow rate: 1.0 mL/min

Detector: RI detector

Column temperature: 40° C.

Injection amount: 100 μL

Molecular weight standard: standard polystyrene (manufactured by Tosoh Corporation)

### Photoacid Generator A

### Synthesis Example 1

### Synthesis of Acid Generator (A1)

In the beginning, in 100 parts of methyl difluoro(fluorosulfonyl)acetate and 150 parts of ion-exchange water, 230 parts of a 30% sodium hydroxide aqueous solution were dropped under an ice bath. The solution was refluxed at 100° C. for 3 hr, then cooled, and neutralized with 88 parts of concentrated hydrochloric acid. A resulting solution was concentrated and thereby 164.4 parts of sodium salt of difluorosulfoacetate (including inorganic salt, purity: 62.7%) were obtained. Then, in 1.9 parts of the resulting sodium salt of difluorosulfoacetate (purity: 62.7%) and 9.5 parts of N,N-dimethylformamide, 1.0 part of 1,1′-carbonyldiimidazole was added and stirred for 2 hr, and thereby a mixture was obtained.

On the other hand, in 1.1 parts of 3-hydroxyadamantyl methanol and 5.5 parts of N,N-dimethylformamide, 0.2 parts of sodium hydride were added, followed by stirring for 2 hr, and thereby a solution was prepared. To the solution, the mixture was added. After a resulting mixture was stirred for 15 hr, a solution containing the resulting sodium salt of 3-hydroxy-1-adamantylmethyl difluorosulfoacetate was used as it is in the following reaction. In a solution containing the resulting sodium salt of 3-hydroxy-1-adamantylmethyl difluorosulfoacetate, 17.2 parts of chloroform and 2.9 parts of a 14.8% triphenylsulfonium chloride aqueous solution were added. After stirring for 15 hr, an organic layer was recovered by separation. Then, a remaining aqueous layer was extracted with 6.5 parts of chloroform and thereby an organic layer was recovered. After the respective organic layers were combined, followed by washing with ion-exchange water, thereafter, the resulting organic layer was concentrated. To the concentrate, 5.0 parts of tent-butylmethyl ether were added, followed by stirring, further followed by filtering, and thereby 0.2 parts of triphenylsulfonium 1-((3-hydroxyadamantyl)methoxycarbonyl)difluoromethane sulfonate (A1) (purity: 100%) were obtained.

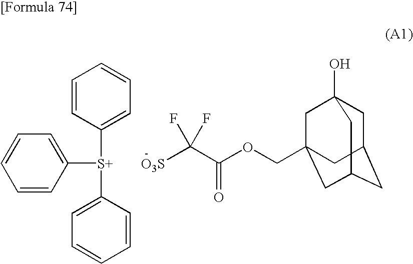

### Synthesis Example 2

### Synthesis of Acid Generator (A2)

In the beginning, in 100 parts of methyl difluoro(fluorosulfonyl)acetate and 250 parts of ion-exchange water, under ice bath, 230 parts of a 30% sodium hydroxide aqueous solution were dropped. The resulting mixture was refluxed at 100° C. for 3 hr, after cooling, followed by neutralizing the solution with 88 parts of concentrated hydrochloric acid. The resulting solution was concentrated and thereby 164.8 parts of sodium salt of difluorosulfoacetate (including inorganic salt, purity: 62.6%) were obtained. Then, in 5.0 parts of resulting sodium salt of difluorosulfoacetate (purity: 62.6%) and 2.6 parts of 4-oxo-1-adamantanol and 100 parts of ethyl benzene, 0.8 parts of concentrated sulfuric acid were added, followed by refluxing under heating for 30 hr. After the resulting mixture was cooled, a filtration residue was recovered by filtration, and a recovered filtration residue was washed with tert-butyl methyl ether, and thereby 5.5 parts of a sodium salt of 4-oxo-1-adamantyl difluorosulfoacetate were obtained. As a result of purity analysis by ¹H-NMR, the purity thereof was 35.6%. In 5.4 parts of the resulting sodium salt of 4-oxo-1-adamantyl difluorosulfoacetate (purity: 35.6%), 16 parts of acetonitrile and 16 parts of ion-exchange water were added. In the resulting mixture, 1.7 parts of triphenylsulfonium chloride, 5 parts of acetonitrile and 5 parts of ion-exchange water were added. The resulting mixture was stirred for 15 hr, followed by concentrating, further followed by extracting the resulting mixture with 142 parts of chloroform, and thereby an organic layer was recovered. After the recovered organic layer was washed with ion-exchange water, the resulting organic layer was concentrated. The concentrate was repulped with 24 parts of tent-butyl methyl ether, and thereby 1.7 parts of triphenylsulfonium 4-oxo-1-adamantyloxycarbonyl difluoromethane sulfonate (A2) (purity: 100%) were obtained as a white solid.

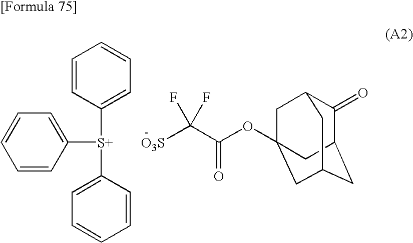

<Resin (B)>

Monomers used in synthesis of resin are shown below.

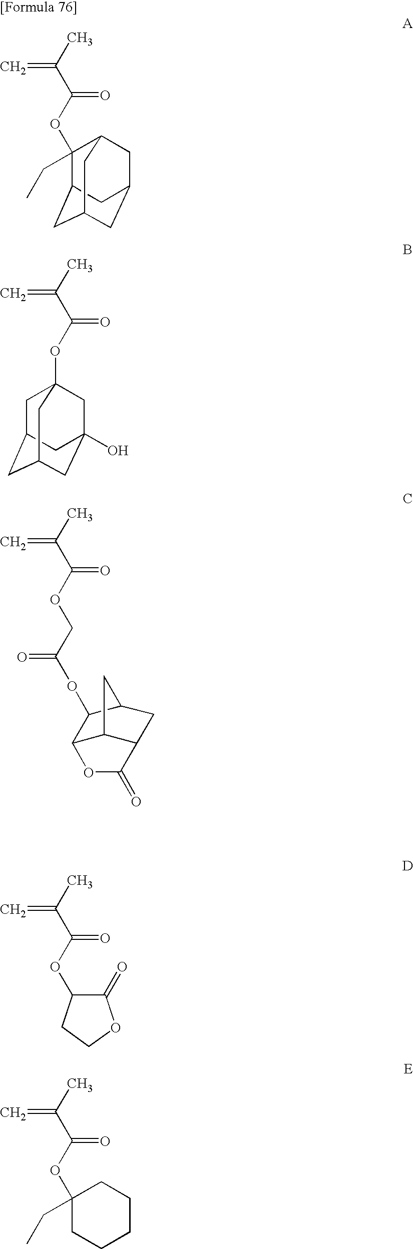

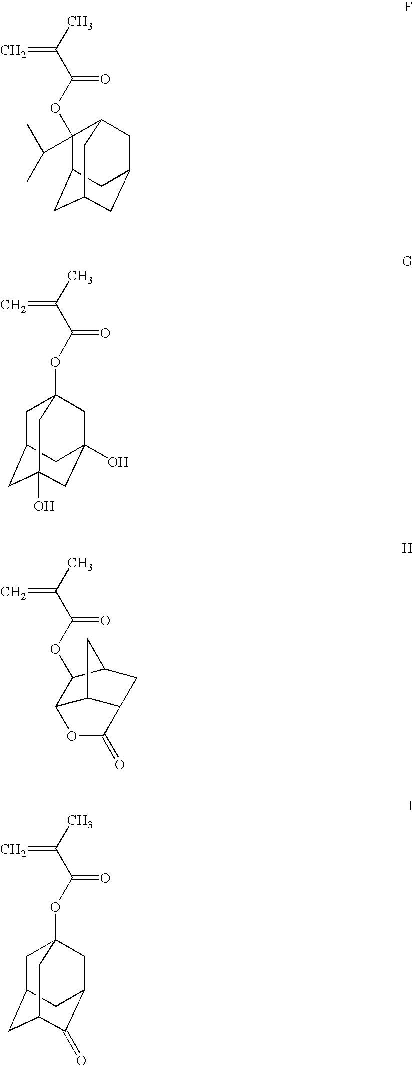

[Synthesis of Resin (B1)]

Monomer A, monomer B and monomer D were charged at a molar ratio of 50:25:25, followed by adding dioxane of 1.5 times weight of the total weight of all monomers. In the resulting mixture, as a polymerization initiator, azobisisobutylonitrile and azobis(2,4-dimethylvalelonitrile), respectively, were added at the rates of 1 mol % and 3 mol % to the total number of moles of the total monomer, and the mixture was heated at 77° C. for about 5 hr. Thereafter, the reaction solution was purified by repeating three times an operation of pouring the reaction solution in a mixed solvent of much methanol and water to precipitate, and thereby a copolymer having a weight average molecular weight of about 8,000 and Tg of 169° C. was obtained at a yield of 60%. The copolymer has structural units derived from the respective monomers represented by the following formulas and this was named as resin B1.

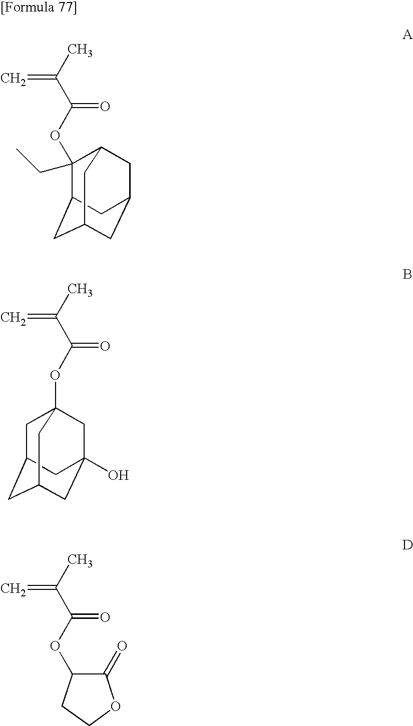

[Synthesis of Resin B2]

Monomer F, monomer E, monomer B, monomer C and monomer D were charged at a molar ratio of 40:5:10:15:30, followed by adding dioxane of 1.5 times weight of the total weight of all monomers. In the resulting mixture, as a polymerization initiator, azobisisobutylonitrile and azobis(2,4-dimethylvalelonitrile), respectively, were added at the rates of 1 mol % and 3 mol % to the total number of moles of the total monomer, and the mixture was heated at 73° C. for about 5 hr. Thereafter, the reaction solution was purified by repeating three times an operation of pouring the reaction solution in a mixed solvent of much methanol and water to precipitate, and thereby a copolymer having a weight average molecular weight of about 8400 and Tg of 151° C. was obtained at a yield of 75%. The resulting copolymer has structural units derived from the respective monomers represented by the following formulas and this was named as resin B2.

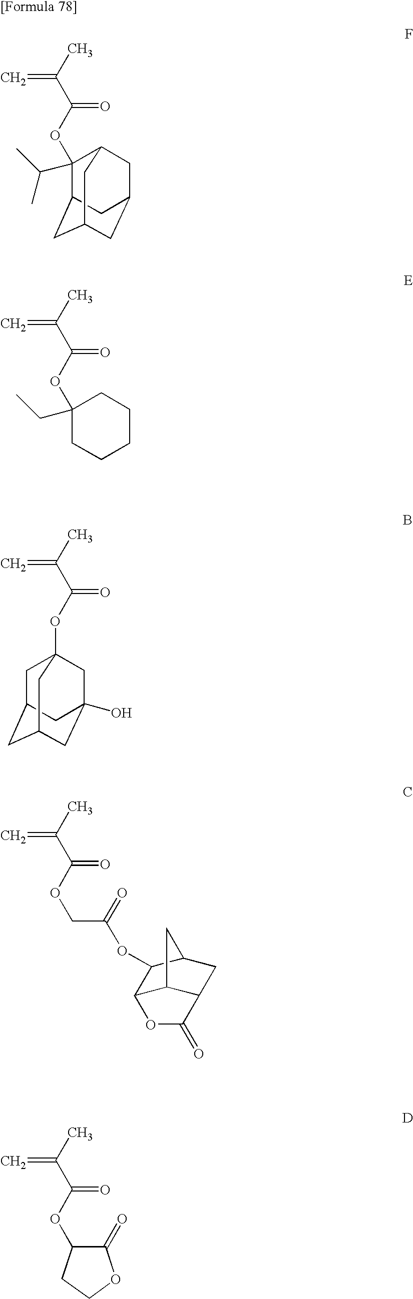

[Synthesis of Resin B3]

Monomer F, monomer E, monomer G and monomer H were charged at a molar ratio of 40:10:10:40, followed by adding dioxane of 1.5 times weight of the total weight of all monomers. In the resulting mixture, as a polymerization initiator, azobisisobutylonitrile and azobis(2,4-dimethylvalelonitrile), respectively, were added at the rates of 0.8 mol % and 2.4 mol % to the total number of moles of the total monomer, and the mixture was heated at 65° C. for about 5 hr. Thereafter, the reaction solution was purified by repeating three times an operation of charging the reaction solution in a mixed solvent of much methanol and water to precipitate, and thereby a copolymer having a weight average molecular weight of about 9800 and Tg of 163° C. was obtained at a yield of 72%. The resulting copolymer has structural units derived from the respective monomers represented by the following formulas and this was named as resin B3.

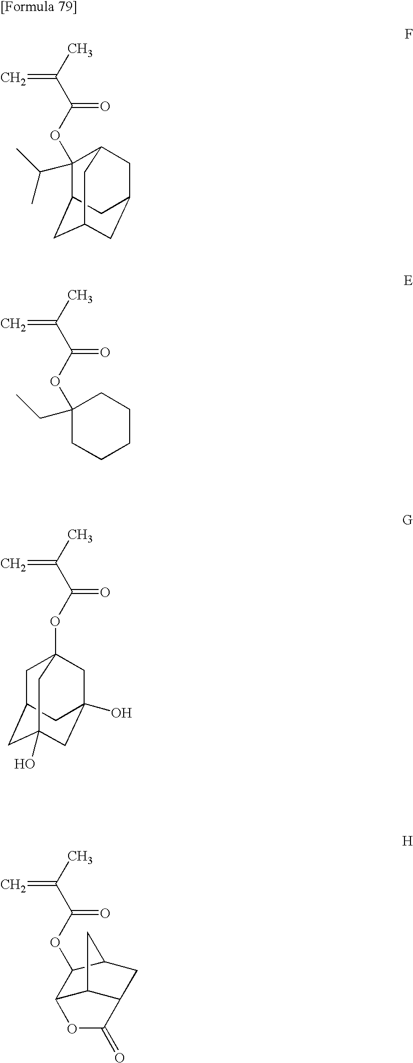

[Synthesis of Resin B4]

Monomer F, monomer B and monomer H were charged at a molar ratio of 40:30:30, followed by adding dioxane of 1.5 times weight of the total weight of all monomers. In the resulting mixture, as a polymerization initiator, azobisisobutylonitrile and azobis(2,4-dimethylvalelonitrile), respectively, were added at the rates of 1.2 mol % and 3.6 mol % to the total number of moles of the total monomer, and the mixture was heated at 75° C. for about 5 hr. Thereafter, the reaction solution was purified by repeating three times an operation of charging the reaction solution in a mixed solvent of much methanol and water to precipitate, and thereby a copolymer having a weight average molecular weight of about 7,000 and Tg of 176° C. was obtained at a yield of 70%. The resulting copolymer has structural units derived from the respective monomers represented by the following formulas and this was named as resin B4.

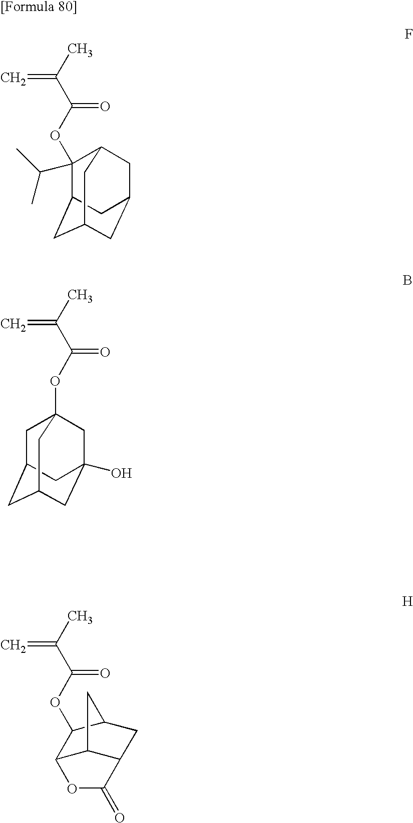

[Synthesis of Resin B5]

Monomer F, monomer E, monomer B, monomer C and monomer D were charged at a molar ratio of 40:5:10:15:30, followed by adding dioxane of 1.5 times weight of the total weight of all monomers. In the resulting mixture, as a polymerization initiator, azobisisobutylonitrile and azobis(2,4-dimethylvalelonitrile), respectively, were added at the rates of 1.5 mol % and 4.5 mol % to the total number of moles of the total monomer, and the mixture was heated at 80° C. for about 5 hr. Thereafter, the reaction solution was purified by repeating three times an operation of charging the reaction solution in a mixed solvent of much methanol and water to precipitate, and thereby a copolymer having a weight average molecular weight of about 6500 and Tg of 149° C. was obtained at a yield of 68%. The resulting copolymer has structural units derived from the respective monomers represented by the following formulas and this was named as resin B5.

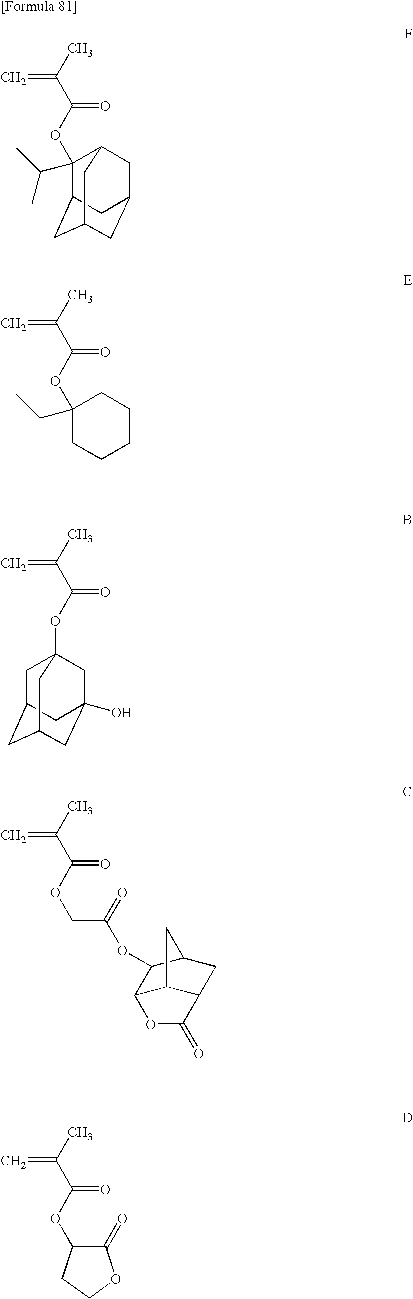

[Synthesis of Resin B6]

Monomer F, monomer E, monomer B, monomer C and monomer D were charged at a molar ratio of 40:5:10:15:30, followed by adding dioxane of 1.5 times weight of the total weight of the all monomers. In the resulting mixture, as a polymerization initiator, azobisisobutylonitrile and azobis(2,4-dimethylvalelonitrile), respectively, were added at the rates of 0.6 mol % and 1.8 mol % to the total number of moles of the total monomer, and the mixture was heated at 65° C. for about 5 hr. Thereafter, the reaction solution was purified by repeating three times an operation of charging the reaction solution in a mixed solvent of much methanol and water to precipitate, and thereby a copolymer having a weight average molecular weight of about 24500 and Tg of 155° C. was obtained at a yield of 68%. The resulting copolymer has structural units derived from the respective monomers represented by the following formulas and this was named as resin B6.

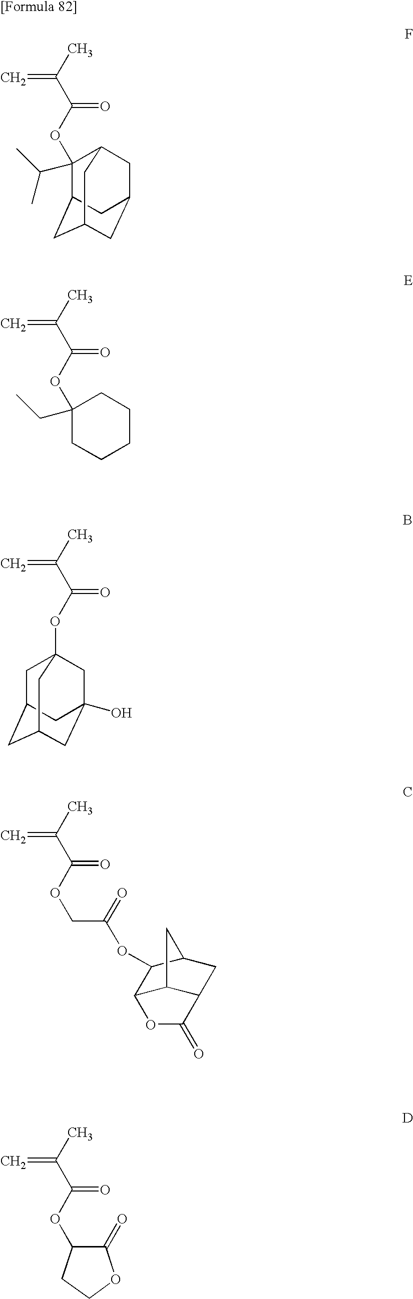

[Synthesis of Resin B7]

Monomer A, monomer G, monomer I and monomer D were charged at a molar ratio of 35:23:19:23, followed by adding dioxane of 1.5 times weight of the total weight of all monomers. In the resulting mixture, as a polymerization initiator, azobisisobutylonitrile and azobis(2,4-dimethylvalelonitrile), respectively, were added at the rates of 1 mol % and 3 mol % to the total number of moles of the total monomer, and the mixture was heated at 80° C. for about 5 hr. Thereafter, the reaction solution was purified by repeating three times an operation of charging the reaction solution in a mixed solvent of much methanol and water to precipitate, and thereby a copolymer having a weight average molecular weight of about 9,000 and Tg of 200° C. was obtained at a yield of 28%. The resulting copolymer has structural units derived from the respective monomers represented by the following formulas and this was named as resin B7.

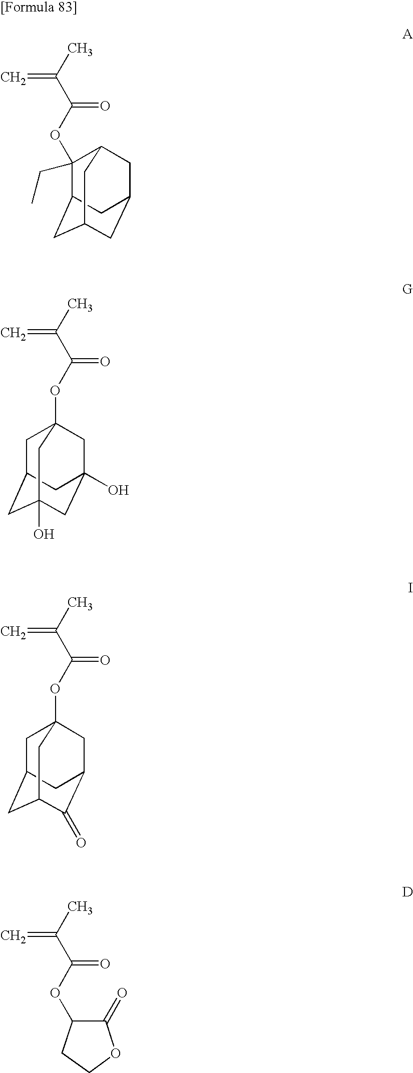

[Synthesis of Resin B8]

Monomer F, monomer E, monomer B, monomer I and monomer D were charged at a molar ratio of 28:14:6:21:31, followed by adding dioxane of 1.5 times weight of the total weight of all monomers. In the resulting mixture, as a polymerization initiator, azobisisobutylonitrile and azobis(2,4-dimethylvalelonitrile), respectively, were added at the rates of 1 mol % and 3 mol % to the total number of moles of the total monomer, and the mixture was heated at 73° C. for about 5 hr. Thereafter, the reaction solution was purified by repeating three times an operation of charging the reaction solution in a mixed solvent of much methanol and water to precipitate, and thereby a copolymer having a weight average molecular weight of about 8,700 and Tg of 160° C. was obtained at a yield of 75%. The resulting copolymer has structural units derived from the respective monomers represented by the following formulas and this was named as resin B8.

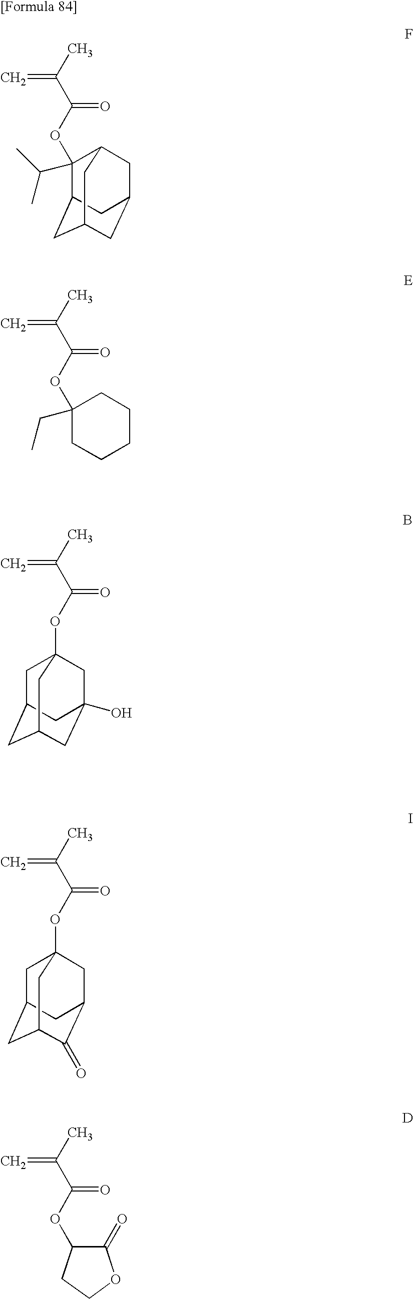

### Examples 1 to 15 and Comparative Examples 1 to 5

The mixtures obtained by mixing and dissolving the following respective components shown in Tables 1 and 2 were filtered with a 0.2 μm fluororesin filter and thereby chemically amplified photoresist compositions (first resist composition and second resist composition) were prepared.

<Acid Generator>

References A1 to 2 of the acid generator synthesis examples

<Resin>

References B1 to 8 of the acid generator synthesis example

<Quencher>

Q1: tetrabutyl ammonium hydride
Q2: 2,6-diisopropylaniline
Q3: lutidine

<Crosslinking Agent (C)>

### C1 and C2:

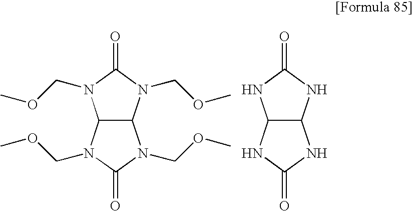

### C3 and C4:

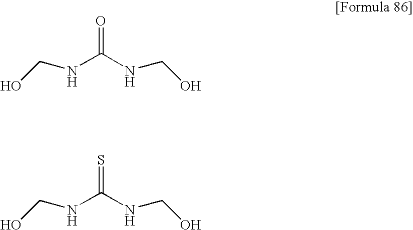

<Thermal Acid Generator>

### D1

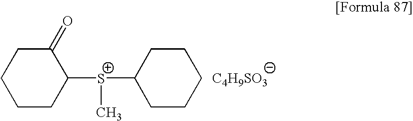

<Solvent>

### Solvent 1:

| | | |
|---|---|---|
| Propylene glycol monomethyl ether | 145 | parts |
| 2-heptanone | 20.0 | parts |
| Propylene glycol monomethyl ether acetate | 20.0 | parts |
| γ-butyrolactone | 3.5 | parts |

A composition for organic antireflection films (trade name: ARC-29A-8, manufactured by Brewer Inc.) was coated on a silicon wafer and baked under conditions of 205° C. for 60 sec, and thereby an organic antireflection film having a thickness of 780 Å was formed. Then, on the organic antireflection film, a first resist composition was spin coated so that the dried dry film thickness thereof may be 80 nm. The coated resist composition was pre-baked on a direct hot plate at 100° C. for 60 sec. The resist film obtained like this was pattern-exposed, with an ArF excimer stepper [trade name: FPA5000-AS3: manufactured by Canon Inc., NA=0.75, ⅔ Annular] and a mask having a 1:1 line and space pattern having a line width: 100 nm, at an exposure amount (30 to 40 mJ/cm²) by which a line width of a line pattern after post-bake described later may be 100 nm. After exposure, on a hot plate, a post-exposure bake was performed at 100° C. for 60 sec. Furthermore, a paddle development was performed for 60 sec in a 2.38% by weight tetramethyl ammonium hydroxide aqueous solution and a patterned first resist film was formed. Thereafter, the patterned first resist film was hard-baked at 170° C. for 60 sec.

<Shape Evaluation a>

The first resist film after hard bake was observed with a scanning electron microscope (trade name: S-4100, manufactured by Hitachi Ltd.) and, with Comparative Example 1 as a reference (represented by B), a first resist film having a shape closer to a rectangle than that of the reference was judged as A, a first resist film having a shape equal to that of the reference was judged as B and a first resist film having a pattern having a round top or a tail in comparison with the reference was judged as C. The evaluation results are shown in Table 3.

Subsequently, a resist composition (second resist composition) prepared by dissolving the components shown in Table 2 in the solvent was coated on the patterned first resist film so that the dried film thickness thereof may be 80 nm. The coated resist composition was pre-baked on a direct hot plate at 100° C. for 60 sec and thereby a second resist film was formed. The second resist film was exposed at an exposure amount of 29 mJ/cm² on each of the wafers, with an ArF excimer stepper [trade name: FPA5000-AS3: manufactured by Canon Inc., NA=0.75, ⅔ Annular] and with a pattern rotated by 90° so that a second line and space pattern may be orthogonal to the first line and space pattern. After exposure, on a hot plate, a post-exposure bake was performed at 100° C. for 60 sec. Furthermore, a paddle development was performed for 60 sec in a 2.38% by weight tetramethyl ammonium hydroxide aqueous solution and thereby a patterned second resist film was formed. According to the operation mentioned above, a lattice resist pattern constituted of the first and second resist films was formed.

<Shape Evaluation b>

The resulting patterned first and second resist films were observed with a scanning electron microscope (trade name: S-4100, manufactured by Hitachi Ltd.) and, with Comparative Example 1 as a reference (represented by B), a second resist film having a shape closer to a rectangle than that of the reference in a good condition was judged as A, a second resist film having a shape equal to that of the reference was judged as B and a second resist film having a shape having a round top or a tail in comparison with that of the reference was judged as C. The evaluation results are shown in Table 3.

<Shape Evaluation c>

The patterned first and second resist films were observed with a scanning electron microscope (trade name: S-4100, manufactured by Hitachi Ltd.) and, with Comparative Example 1 as a reference (represented by B), a first resist film was compared therewith, a first resist film maintaining a shape thereof was judged as A, and a first resist film having a large dissolved portion was judged as C. The evaluation results are shown in Table 3.

A composition for organic antireflection film (trade name: ARC-29A-8, manufactured by Brewer Inc.) was coated on a silicon wafer and baked under conditions of 205° C. and 60 sec, and thereby an organic antireflection film having a thickness of 780 Å was formed. Then, on the organic antireflection film, the first resist composition was spin coated so that the dried dry film thickness thereof may be 80 nm. A coated resist composition was pre-baked on a direct hot plate at 100° C. for 60 sec. Thus-obtained resist film was pattern-exposed on each of the wafers with an ArF excimer stepper [trade name: FPA5000-AS3: manufactured by Canon Inc., NA=0.75, ⅔ Annular] and with a mask having a 1:3 line and space pattern having a line width: 100 nm at an exposure amount (30 to 40 mJ/cm²) by which a line width of a line pattern after post-bake described later may be 100 nm. After exposure, on a hot plate, a post-exposure bake was performed at 100° C. for 60 sec. Furthermore, a paddle development was performed for 60 sec in a 2.38% by weight tetramethyl ammonium hydroxide aqueous solution and a patterned first resist film was formed. Thereafter, the patterned first resist film was hard-baked at a temperature of 170° C. for 60 sec.

Subsequently, a resist composition (second resist composition) prepared by dissolving the components shown in Table 2 in the solvent 1 was coated on the resulting first resist film so that the dried film thickness thereof may be 80 nm. The coated resist composition was pre-baked (PB) on a direct hot plate at 100° C. for 60 sec. Thus-obtained second resist film was pattern-exposed with an ArF excimer stepper [trade name: FPA5000-AS3: manufactured by Canon Inc., NA=0.75, ⅔ Annular] and with a mask having a 1:3 line and space pattern having a line width: 100 nm, at an exposure amount (30 to 40 mJ/cm²) at which a line width of a second line and space pattern becomes 100 nm After exposure, on a hot plate, a post-exposure bake (PEB) was performed at 100° C. for 60 sec. Furthermore, a paddle development was performed for 60 sec in a 2.38% by weight tetramethyl ammonium hydroxide aqueous solution and thereby a second resist film constituted of lines disposed between lines of the first resist film was formed. According to the operation mentioned above, two line patterns were formed. A fine line and space pattern (resist pattern) having a pitch one half of the respective lines was formed.

<Shape Evaluation d>

The resulting resist patterns were observed with a scanning electron microscope and, with Comparative Example 1 as a reference (represented by B), a first resist film was compared therewith, a first resist film maintaining a shape thereof more than that of the reference was judged as A, a first resist film having a pitch between lines not equal to one half or a large dissolved portion of the resist film in comparison with the reference was judged as C, and a first resist film having a shape the same as that of the reference was judged as B. The evaluation results are shown in Table 3.

TABLE 1
First resist composition

| | | | Photoacid | | Crosslinking | | Thermal acid | | | |
|---|---|---|---|---|---|---|---|---|---|---|
| | Resin (B) | | generator (A) | | agent (C) | | generator (D) | | Quencher | |
| | | Parts by | | Parts by | | Parts by | | Parts by | | Parts by |
| Example | Kind | mass | Kind | mass | Kind | mass | Kind | mass | Kind | mass |
| Ex. 1 | B1 | 10 | A1 | 0.6 | C1 | 0.2 | — | — | Q2 | 0.055 |
| Ex. 2 | B1 | 10 | A2 | 0.6 | C1 | 0.2 | — | — | Q2 | 0.055 |
| Ex. 3 | B1 | 10 | A1 | 0.6 | C1 | 0.2 | D1 | 0.6 | Q1 | 0.01 |
| | | | | | | | | | Q3 | 0.1 |
| Ex. 4 | B2 | 10 | A1 | 0.6 | C1 | 0.2 | — | — | Q2 | 0.055 |
| Ex. 5 | B3 | 10 | A1 | 0.6 | C1 | 0.2 | — | — | Q2 | 0.055 |
| Ex. 6 | B4 | 10 | A1 | 0.6 | C1 | 0.2 | — | — | Q2 | 0.055 |
| Ex. 7 | B2 | 10 | A1 | 0.6 | C2 | 0.15 | — | — | Q2 | 0.055 |
| Ex. 8 | B2 | 10 | A1 | 0.6 | C3 | 0.09 | — | — | Q2 | 0.055 |
| Ex. 9 | B2 | 10 | A1 | 0.6 | C4 | 0.17 | — | — | Q2 | 0.055 |
| Ex. 10 | B7 | 10 | A1 | 0.6 | C1 | 0.2 | — | — | Q2 | 0.055 |
| Ex. 11 | B7 | 10 | A1 | 0.6 | C1 | 0.2 | — | — | Q2 | 0.055 |
| Ex. 12 | B3 | 10 | A1 | 0.6 | C2 | 0.15 | — | — | Q2 | 0.055 |
| Ex. 13 | B3 | 10 | A1 | 0.6 | C3 | 0.09 | — | — | Q2 | 0.055 |
| Ex. 14 | B3 | 10 | A1 | 0.6 | C4 | 0.17 | — | — | Q2 | 0.055 |
| Ex. 15 | B8 | 10 | A1 | 0.6 | C1 | 0.2 | — | — | Q2 | 0.055 |
| Com. Ex. 1 | B1 | 10 | A1 | 0.27 | — | — | — | — | Q2 | 0.055 |
| Com. Ex. 2 | B5 | 10 | A1 | 0.6 | — | — | — | — | Q2 | 0.055 |
| Com. Ex. 3 | B6 | 10 | A1 | 0.6 | — | — | — | — | Q2 | 0.055 |
| Com. Ex. 4 | B5 | 10 | A1 | 0.6 | C1 | 0.2 | — | — | Q2 | 0.055 |
| Com. Ex. 5 | B6 | 10 | A1 | 0.6 | C1 | 0.2 | — | — | Q2 | 0.055 |

TABLE 2
Second resist composition

| | | | Photoacid | | Crosslinking | | Thermal acid | | | |
|---|---|---|---|---|---|---|---|---|---|---|
| | Resin (B) | | generator (A) | | agent (C) | | generator (D) | | Quencher | |
| | | Parts by | | Parts by | | Parts by | | Parts by | | Parts by |
| Example | Kind | mass | Kind | mass | Kind | mass | Kind | mass | Kind | mass |
| Ex. 1 | B1 | 10 | A1 | 0.6 | — | — | — | — | Q2 | 0.055 |
| Ex. 2 | B1 | 10 | A1 | 0.6 | C1 | 0.2 | — | — | Q2 | 0.055 |
| Ex. 3 | B1 | 10 | A1 | 0.6 | C1 | 0.2 | D1 | 0.6 | Q1 | 0.01 |
| | | | | | | | | | Q3 | 0.1 |
| Ex. 4 | B2 | 10 | A1 | 0.6 | — | — | — | — | Q2 | 0.055 |
| Ex. 5 | B2 | 10 | A1 | 0.6 | — | — | — | — | Q2 | 0.055 |
| Ex. 6 | B2 | 10 | A1 | 0.6 | — | — | — | — | Q2 | 0.055 |
| Ex. 7 | B2 | 10 | A1 | 0.6 | — | — | — | — | Q2 | 0.055 |
| Ex. 8 | B2 | 10 | A1 | 0.6 | — | — | — | — | Q2 | 0.055 |
| Ex. 9 | B2 | 10 | A1 | 0.6 | — | — | — | — | Q2 | 0.055 |
| Ex. 10 | B2 | 10 | A1 | 0.6 | C1 | 0.2 | — | — | Q2 | 0.055 |
| Ex. 11 | B2 | 10 | A1 | 0.6 | — | — | — | — | 02 | 0.055 |
| Ex. 12 | B2 | 10 | A1 | 0.6 | — | — | — | — | Q2 | 0.055 |
| Ex. 13 | B2 | 10 | A1 | 0.6 | — | — | — | — | Q2 | 0.055 |
| Ex. 14 | B2 | 10 | A1 | 0.6 | — | — | — | — | Q2 | 0.055 |
| Ex. 15 | B2 | 10 | A1 | 0.6 | — | — | — | — | Q2 | 0.055 |
| Com. Ex. 1 | B1 | 10 | A1 | 0.27 | — | — | — | — | Q2 | 0.055 |
| Com. Ex. 2 | B5 | 10 | A1 | 0.6 | — | — | — | — | Q2 | 0.055 |
| Com. Ex. 3 | B6 | 10 | A1 | 0.6 | — | — | — | — | Q2 | 0.055 |
| Com. Ex. 4 | B5 | 10 | A1 | 0.6 | — | — | — | — | Q2 | 0.055 |
| Com. Ex. 5 | B6 | 10 | A1 | 0.6 | — | — | — | — | Q2 | 0.055 |

TABLE 3

| | | | | | First resist | | Second resist | |
|---|---|---|---|---|---|---|---|---|
| | Shape | Shape | Shape | Shape | PB | PEB | PB | PEB |
| Example | a | b | c | d | temperature | temperature | temperature | temperature |
| Ex. 1 | A | A | A | A | 100° C. | 100° C. | 100° C. | 100° C. |
| Ex. 2 | A | A | A | A | 100° C. | 100° C. | 100° C. | 100° C. |
| Ex. 3 | A | A | A | A | 100° C. | 100° C. | 100° C. | 100° C. |
| Ex. 4 | A | A | A | A | 100° C. | 100° C. | 100° C. | 100° C. |
| Ex. 5 | A | A | A | A | 100° C. | 100° C. | 100° C. | 100° C. |
| Ex. 6 | A | A | A | A | 100° C. | 100° C. | 100° C. | 100° C. |
| Ex. 7 | A | A | A | A | 100° C. | 100° C. | 100° C. | 100° C. |
| Ex. 8 | A | A | A | A | 100° C. | 100° C. | 100° C. | 100° C. |
| Ex. 9 | A | A | A | A | 100° C. | 100° C. | 100° C. | 100° C. |
| Ex. 10 | A | A | A | A | 100° C. | 100° C. | 100° C. | 100° C. |
| Ex. 11 | A | A | A | A | 100° C. | 100° C. | 100° C. | 100° C. |
| Ex. 12 | A | A | A | A | 100° C. | 100° C. | 100° C. | 100° C. |
| Ex. 13 | A | A | A | A | 100° C. | 100° C. | 100° C. | 100° C. |
| Ex. 14 | A | A | A | A | 100° C. | 100° C. | 100° C. | 100° C. |
| Ex. 15 | A | A | A | A | 100° C. | 100° C. | 100° C. | 100° C. |
| Com. Ex. 1 | B | B | B | B | 130° C. | 130° C. | 130° C. | 130° C. |
| Com. Ex. 2 | C | C | C | C | 100° C. | 100° C. | 100° C. | 100° C. |
| Com. Ex. 3 | C | C | C | C | 100° C. | 100° C. | 100° C. | 100° C. |
| Com. Ex. 4 | C | C | B | B | 100° C. | 100° C. | 100° C. | 100° C. |
| Com. Ex. 5 | C | C | A | A | 100° C. | 100° C. | 100° C. | 100° C. |

What is claimed is:

1. A method for producing a resist pattern, by repeating a process of forming a patterned resist film comprising, in this order, the following steps (1), (2) and (3):
(1) forming a resist film and exposing the formed resist film,
(2) heating the exposed resist film, and
(3) patterning the resist film by an alkali development,
wherein the process is repeated by n cycles (n is an integer of 2 or more) to obtain a resist pattern,
wherein in at least from the first cycle to the (n−1)th cycle of the n cycles of the process of forming a patterned resist film, after the step (3), the step (4):
(4) heating the patterned resist film
is further performed; and
wherein the resist film exposed in the step (1) in at least one cycle of the n cycles of the process of forming a patterned resist film is a film formed by layering a resist composition containing a resin (B) that becomes soluble in an alkali aqueous solution by an action of an acid and has a weight-average molecular weight of 7,000 to 10,000 and a glass transition temperature of 150 to 200° C., a photoacid generator (A) and a crosslinking agent (C).

2. The method according to claim 1, wherein, also in the n-th process of forming a patterned resist film, the step (4) is further performed after the step (3).

3. The method according to claim 1, wherein the resist film exposed in the step (1) in at least one cycle selected from the first cycle to the (n−1)th cycle of the n cycles of the process of forming a patterned resist film is a film formed by layering the resist composition.

4. The method according to claim 1, wherein the resist film exposed in the step (1) in the n-th cycle of the process of forming a patterned resist film is a film formed by layering the resist composition.

5. The method according to claim 1, wherein n is 2.

6. The method according to claim 1, wherein n is 3 or more.

7. The method according to claim 1, wherein n is 3.

8. The method according to claim 1, wherein the resist film exposed in the step (1) in all of the first cycle to the (n−1)th of the n cycles of the process of Banning a patterned resist film is a film formed by layering the resist composition.

9. The method according to claim 1, wherein the crosslinking agent (C) is at least one selected from the group consisting of a urea crosslinking agent, an alkylene urea crosslinking agent and a glycoluril crosslinking agent.

10. The method according to claim 1, wherein the resist composition contains 0.5 to 35 parts by weight of the crosslinking agent (C) with respect to 100 parts by weight of the resin (B).

11. The method according to claim 1, wherein the resist composition further contains a thermal acid generator (D).

12. The method according to claim 1, wherein the resin (B) has an alkyl ester group and a carbon atom adjacent to an oxy group in the alkyl ester group is a tertiary carbon atom.

13. A resist composition, comprising:
a resin (B) that becomes soluble in an alkali aqueous solution by an action of an acid and has a weight average molecular weight of 7,000 to 10,000 and a glass transition temperature of 150 to 200° C.;
a photoacid generator (A); and
a crosslinking agent (C),
wherein the resist composition is used, in a method for producing a resist pattern, by repeating a process of forming a patterned resist film comprising, in this order, the following steps (1), (2) and (3):
(1) forming a resist film and exposing the formed resist film,
(2) heating the exposed resist film, and
(3) patterning the resist film by an alkali development,
wherein the process is repeated by n cycles (n is an integer of 2 or more) to obtain a resist pattern,
wherein in at least from the first cycle to the (n−1)th cycle of the n cycles of the process of forming a patterned resist film, after the step (3), the step (4):
(4) heating the patterned resist film
is further performed,
for forming a resist film exposed in the step (1) in at least one cycle of the n cycles of the process of forming a patterned resist film.

14. A resist pattern obtainable by the method according to claim 1.

15. A wiring board comprising:
a wiring formed by etching a metal layer with the resist pattern according to claim 14 as a mask.
